(19) United States
(12) Patent Application Publication
(10) Pub. No.: US 2014/0167003 A1
(43) Pub. Date: Jun. 19, 2014

(54) ORGANIC ELECTROLUMINESCENCE DEVICE

(71) Applicant: Idemitsu Kosan Co., Ltd., Chiyoda-ku (JP)

(72) Inventors: Tomoki KATO, Sodegaura-shi (JP); Takayasu Sado, Sodegaura-shi (JP)

(73) Assignee: Idemitsu Kosan Co., Ltd., Chiyoda-ku (JP)

(21) Appl. No.: 14/011,093

(22) Filed: Aug. 27, 2013

Related U.S. Application Data
(60) Provisional application No. 61/695,503, filed on Aug. 31, 2012.

(30) Foreign Application Priority Data
Aug. 30, 2012 (JP) 2012-190023

(51) Int. Cl. H01L 51/50; H01L 51/00

(52) U.S. Cl. CPC H01L 51/5056; H01L 51/0056
USPC 257/40

(57) ABSTRACT

Problem to Be Solved:

To provide a highly efficient, long lifetime organic EL device that is capable of driving at low voltage.

Solution

An organic electroluminescence device including an organic layer which includes a hole transporting layer and a light emitting layer between an anode and a cathode in this order from the anode side, in which the organic layer includes an acceptor material and the hole transporting layer includes a compound represented by formula (1):

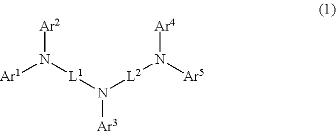

wherein each of L¹ and L² is independently represented by formula (1-2) or (1-3) and each of Ar¹ to Ar⁵ is independently represented by any one of formulae (1-4) to (1-9):

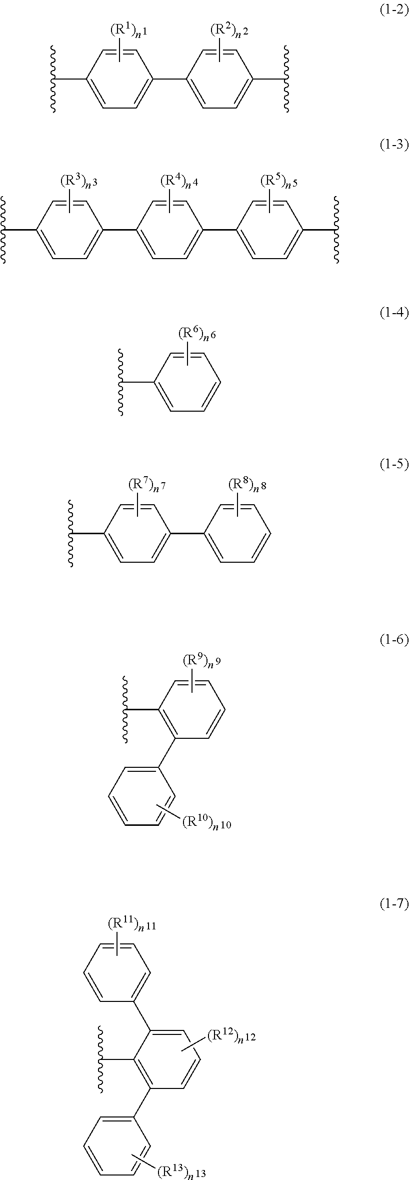

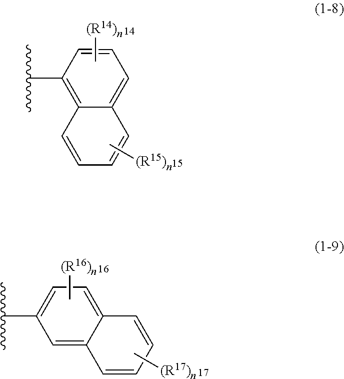

wherein:
each of R¹ to R¹⁷ independently represents a substituted or unsubstituted alkyl group, a halogen atom, a substituted or unsubstituted fluoroalkyl group, a substituted or unsubstituted alkoxy group, a substituted or unsubstituted fluoroalkoxy group, or a cyano group;
each of n¹ to n⁵, n⁷, n⁹, n¹⁵, and n¹⁷ independently represents an integer of 0 to 4;
each of n⁶, n⁸, n¹⁰, n¹¹, and n¹³ independently represents an integer of 0 to 5;
each of n¹², n¹⁴ and n¹⁶ independently represents an integer of 0 to 3;
R⁶ to R¹⁷ may be bonded to each other to form a ring; and
each of wavy lines indicates a bonding site.

### TECHNICAL FIELD

The present invention relates to organic electroluminescence devices (organic EL devices).

### BACKGROUND ART

An organic EL device is a spontaneous light emitting device which is based on the principle that holes injected from an anode and electrons injected from a cathode are recombined in response to the applied electric field and the recombination energy causes the light emission from a fluorescent substance. Since a laminate-type organic EL device capable of driving at low electric voltage has been reported by C. W. Tang et al. of Eastman Kodak Company (C. W. Tang and S. A. Vanslyke, Applied Physics Letters, vol. 51, 913, 1987, or the like), many studies have been made on an organic EL device including an organic material.

For example, Patent Documents 1 to 4 disclose diamine compounds having a fluorene skeleton between two nitrogen atoms. It has been reported that by using the diamine compound in the hole transporting layer “adjacent to the light emitting layer,” the crystallization of the hole transporting material due to the heat generated by the emission in the light emitting layer can be prevented and an organic EL device excellent in stability and durability can be obtained as compared with the case wherein a diamine compound having a biphenylene group between two nitrogen atoms or a monoamine compound having a fluorene skeleton is used.

Patent Document 5 discloses that a long-lifetime organic EL device with a low driving voltage is produced by using a diamine compound wherein two nitrogen atoms are bonded to each other via a biphenylene group in the first hole transporting layer and using an aromatic amine derivative having a dibenzofuran structure and a carbazole structure in the second hole transporting layer adjacent to the light emitting layer. Patent Documents 6 and 7 disclose organic EL devices wherein the emission efficiency and the device lifetime are improved by using an aromatic triamine compound in the hole transporting layer “adjacent to the light emitting layer.”

Thus, the device performance of organic EL devices, particularly phosphorescent devices has been improved by making a hole transporting layer into two-layered structure of a first hole transporting layer and a second hole transporting layer and using a higher performance material in the second hole transporting layer “adjacent to the light emitting layer.”

It has been known that the second hole transporting layer is required to have (i) a high triplet energy (preferably 2.6 eV or more) to prevent the diffusion of excitation energy from the phosphorescent emitting layer, (ii) an electron resistance because the layer is adjacent to the light emitting layer, (iii) a small affinity (preferably 2.4 eV or less) to prevent the leak of electrons from the light emitting layer; and (iv) a large ionization potential (preferably 5.5 eV or more) to facilitate the hole injection into the light emitting layer. As the material satisfying these requirements, a compound having a highly electron-resistant molecular skeleton wherein a heteroaryl ring, such as carbazole and dibenzofuran, is bonded to a triphenylamine skeleton has been preferably used.

On the other hand, the first hole transporting layer is generally required to be excellent in the hole injection ability into the second hole transporting layer.

To improve the hole injection ability, it has been studied to use a compound having p-type semiconducting properties (also referred to as “acceptor material”) in the hole injecting layer (Patent Documents 8 and 9).

As the progress in research and development in organic EL devices, it has become inevitably needed for commercial devices to efficiently extract lights emitted in an organic EL device to the outside of the device for every color. To extract emitted light efficiently, it is required to adjust the optical path length of whole device by controlling the thickness of the hole transporting layer having a carrier transporting ability higher than those of other organic layers. Therefore, it is recently needed to develop a hole transporting material having a high mobility enough to prevent the driving voltage from increasing even when the hole transporting layer is made thicker. It is also needed to develop a hole transporting material for use in the first hole transporting layer, which can generate carriers in a large amount by the interaction with the acceptor material.

### PRIOR ART

### Patent Documents

Patent Document 1: JP 3813003B
Patent Document 2: JP 3801330B
Patent Document 3: JP 3792029B
Patent Document 4: JP 3835917B
Patent Document 5: WO 2010/114017
Patent Document 6: JP 10-77252A
Patent Document 7: WO 2006/114921
Patent Document 8: WO 01/49806 (JP 2003-519432A)
Patent Document 9: WO 2011/090149

### SUMMARY OF THE INVENTION

### Problem to be Solved by the Invention

The present invention has been made to solve the above problems and an object is to provide an organic EL device capable of driving at low voltage and having a high efficiency and a long lifetime.

### Means for Solving Problem

As a result of extensive research in view of developing an organic EL device capable of driving at low voltage and having a high efficiency and a long lifetime, the inventors have found that the above problems can be solved by using a compound represented by formula (1), i.e., a specific aromatic triamine compound as the hole transporting material, particularly in a hole transporting layer not adjacent to the light emitting layer. The present invention is based on this finding.

The present invention provides an organic electroluminescence device comprising an organic layer which comprises a hole transporting layer and a light emitting layer between an anode and a cathode in this order from the anode side,

wherein the organic layer comprises an acceptor material and the hole transporting layer comprises a compound represented by formula (1):

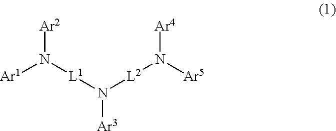

wherein each of L¹ and L² is independently represented by formula (1-2) or (1-3):

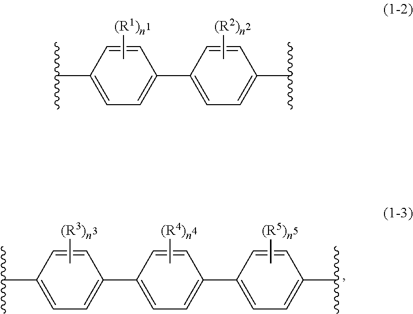

and
each of Ar¹ to Ar⁵ is independently represented by any one of formulae (1-4) to (1-9):

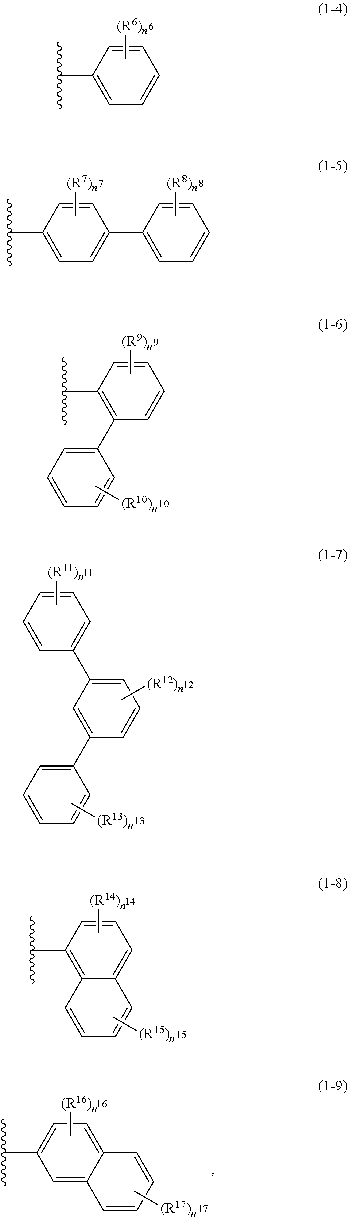

in formulae (1-2) to (1-9):

each of R¹ to R¹⁷ independently represents a substituted or unsubstituted alkyl group having 1 to 20 carbon atom, a halogen atom, a substituted or unsubstituted fluoroalkyl group having 1 to 20 carbon atoms, a substituted or unsubstituted alkoxy group having 1 to 20 carbon atoms, a substituted or unsubstituted fluoroalkoxy group having 1 to 20 carbon atoms, or a cyano group;

each of n¹ to n⁵, n⁷, n⁹, n¹⁵, and n¹⁷ independently represents an integer of 0 to 4;

each of n⁶, n⁸, n¹⁰, n¹¹, and n¹³ independently represents an integer of 0 to 5;

each of n¹², n¹⁴, and n¹⁶ independently represents an integer of 0 to 3;

R⁶ to R¹⁷ may be bonded to each other to form a ring; and

each of wavy lines in formulae (1-2) to (1-9) indicates a bonding site.

### Effect of the Invention

The compound used in the present invention is a hole transporting material having a high mobility enough to prevent the increase in the driving voltage even when the thickness of a hole transporting layer in organic EL device is increased, and therefore, makes it easy to adjust the optical path length of organic EL device and is capable of providing an organic EL device with a high efficiency and a long lifetime.

In particular, when the compound is used as a hole transporting material for an organic EL device wherein an acceptor layer is bonded to an anode, the amount of hole injection from the acceptor layer to the hole transporting layer is increased because of a high compatibility of the compound with the acceptor material, thereby enhancing the above effect.

### MODE FOR CARRYING OUT THE INVENTION

### Organic Electroluminescence Device

The structure of the organic electroluminescence device (organic EL device) of the invention is described below.

The organic EL device of the invention comprises an organic layer which comprises a hole transporting layer and a light emitting layer between an anode and a cathode in this order from the anode side. The organic layer comprises an acceptor material and the hole transporting layer comprises a compound represented by formula (1) which is described below.

In a particularly preferred embodiment of the invention, the hole transporting layer comprises two or more layers comprising one or more first hole transporting layers disposed on the anode side and a second hole transporting layer adjacent to the light emitting layer, and at least one layer of the first hole transporting layers comprises the compound represented by formula (1). The “one or more first hole transporting layers” disposed on the anode side is more preferably a single layer.

Thus, the hole transporting layer is made into two or more layers and a first hole transporting layer not adjacent to the light emitting layer comprises the compound represented by formula (1) having a high mobility as the hole transporting material. By this configuration, the driving voltage is prevented from increasing even when the hole transporting layer is thicker to make it easy to adjust the optical path length of organic EL device, and a high efficiency and a long lifetime can be achieved. In addition, since the compound represented by formula (1) is well compatible with the acceptor material having a high hole injecting ability, the amount of generated carrier is increased and more holes are transported and injected into the light emitting layer. This would result in a high efficiency of a device.

The organic EL device of the invention may be any of a single color emitting fluorescent or phosphorescent device, a white-emitting fluorescent/phosphorescent hybrid device, a simple emitting device having a single emission unit, and a tandem emitting device having two or more emission units. The “emission unit” referred to herein is the smallest unit for emitting light by the recombination of injected holes and injected electrons, which comprises one or more organic layers wherein at least one layer is a light emitting layer.

The device structure of the organic EL device of the invention is described below.

### (I) Structure of Organic EL Device

Representative device structures of organic EL device of the invention are:

(1) anode/acceptor material-containing layer (acceptor layer)/first hole transporting layer/second hole transporting layer/light emitting layer/cathode;
(2) anode/acceptor material-containing layer (acceptor layer)/first hole transporting layer/second hole transporting layer/light emitting layer/electron injecting layer/cathode;
(3) anode/acceptor material-containing layer (acceptor layer)/first hole transporting layer/second hole transporting layer/light emitting layer/electron transporting layer/electron injecting layer/cathode;
(4) anode/first hole transporting layer/second hole transporting layer/light emitting layer/electron injecting layer/cathode; and
(5) anode/first hole transporting layer/second hole transporting layer/light emitting layer/electron transporting layer/electron injecting layer/cathode.

An electron blocking layer or an exciton blocking layer may be disposed between the light emitting layer and the hole transporting layer. The hole transporting layer (second hole transporting layer) in contact with the light emitting layer may work as an electron blocking layer or an exciton blocking layer.

In a preferred organic EL device of the invention, an acceptor layer comprising an acceptor material as the organic layer is disposed between the anode and the first hole transporting layer.

In another preferred organic EL device of the invention, the hole transporting layer comprising the compound represented by formula (1) further comprises an acceptor material.

The compound represented by formula (A), (B) or (C) having a highly planar skeleton is preferably used as the acceptor material, because the acceptor layer is well boned to the hole transporting layer comprising the compound represented by formula (1) so that a further improvement of device performance is expected.

### Acceptor Material (A)

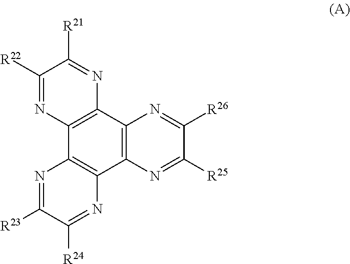

wherein:

each of R²¹ to R²⁶ independently represents a cyano group, —CONH₂, a carboxyl group, or —COOR²⁷, wherein R²⁷ represents an alkyl group having 1 to 20 carbon atoms; and R²¹ and R²², R²³ and R²⁴, and R²⁵ and R²⁶ may be bonded to each other to form a group represented by —CO—O—CO—.

Examples of the alkyl group for R²⁷ include a methyl group, an ethyl group, a n-propyl group, an isopropyl group, a n-butyl group, an isobutyl group, a tert-butyl group, a cyclopentyl group, and a cyclohexyl group, with an alkyl group having 1 to 10 carbon atoms being preferred and an alkyl group having 1 to 5 carbon atoms being more preferred.

### Acceptor Material (B)

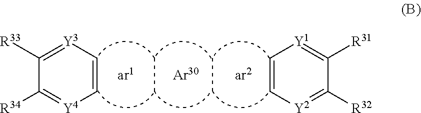

wherein:

each of R³¹ to R³⁴ independently represents a hydrogen atom, a substituted or unsubstituted alkyl group having 1 to 20 carbon atoms, a substituted or unsubstituted aryl group having 6 to 50 ring carbon atoms, a substituted or unsubstituted heterocyclic group having 5 to 50 ring atoms, a halogen atom, a substituted or unsubstituted alkoxy group having 1 to 20 carbon atoms, a substituted or unsubstituted aryloxy group having 6 to 50 ring carbon atoms, or a cyano group, provided that R³¹ and R³² may be bonded to each other to form a ring, and R³³ and R³⁴ may be bonded to each other to form a ring;

each of Y¹ to Y⁴ independently represents —N═, —CH═, or —C(R³⁵)═, wherein R³⁵ represents a substituted or unsubstituted alkyl group having 1 to 20 carbon atoms, a substituted or unsubstituted aryl group having 6 to 50 ring carbon atoms, a substituted or unsubstituted heterocyclic group having 5 to 50 ring atoms, a halogen atom, a substituted or unsubstituted alkoxy group having 1 to 20 carbon atoms, a substituted or unsubstituted aryloxy group having 6 to 50 ring carbon atoms, or a cyano group;

Ar³⁰ represents a fused ring having 6 to 24 ring carbon atoms or a heteroring having 6 to 24 ring atoms; and

each of ar¹ and ar² independently represents a ring represented by formula (i) or (ii):

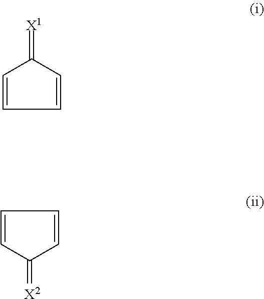

wherein each of X¹ and X² independently represents a divalent group represented by any one of formulae (a) to (g):

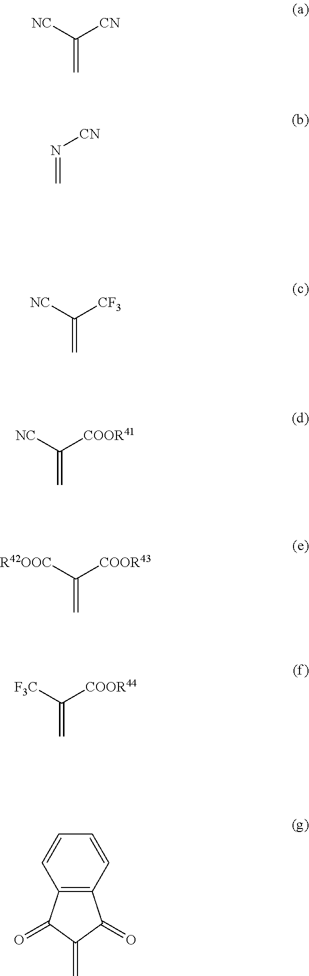

wherein R⁴¹ to R⁴⁴ may be the same or different and each represents a hydrogen atom, a substituted or unsubstituted alkyl group having 1 to 20 carbon atoms, a substituted or unsubstituted aryl group having 6 to 50 ring carbon atoms, or a substituted or unsubstituted heterocyclic group having 5 to 50 ring atoms, provided that R⁴² and R⁴³ may be bonded to each other to form a ring.

Examples of the groups for R³¹ to R³⁵ and R⁴¹ to R⁴⁴ are described below.

The alkyl group may include a methyl group, an ethyl group, a n-propyl group, an isopropyl group, a n-butyl group, an isobutyl group, a tert-butyl group, a cyclopentyl group, and a cyclohexyl group, with an alkyl group having 1 to 10 carbon atoms being preferred and an alkyl group having 1 to 5 carbon atoms being more preferred.

The aryl group may include a phenyl group, a biphenyl group, and a naphthyl group, with an aryl group having 6 to 30 ring carbon atoms being preferred, an aryl group having 6 to 20 ring carbon atoms being more preferred, and an aryl group having 6 to 14 ring carbon atoms being still more preferred.

The heterocyclic group may include residues of pyridine, pyrazine, furan, imidazole, benzimidazole, and thiophene, with a heterocyclic group having 5 to 30 ring atoms being preferred, a heterocyclic group having 5 to 20 ring atoms being more preferred, and a heterocyclic group having 5 to 14 ring atoms being still more preferred.

The halogen atom may include a fluorine atom, a chlorine atom, a bromine atom, and an iodine atom, with a fluorine atom being preferred.

The alkoxy group may include a methoxy group and an ethoxy group, with an alkoxy group having 1 to 10 carbon atoms being preferred and an alkoxy group having 1 to 5 carbon atoms being more preferred.

The aryloxy group may include a phenyloxy group, with an aryloxy group having 6 to 30 ring carbon atoms being preferred and an aryloxy group having 6 to 20 ring carbon atoms being more preferred.

The above groups may be substituted. The substituted aryl group may include a haloaryl group, such as a monofluorophenyl group and a trifluoromethylphenyl group, and an aryl group substituted with an alkyl group having 1 to 10, preferably 1 to 5 carbon atoms, such as a tolyl group and a 4-t-butylphenyl group. The substituted alkyl group may include a trifluoromethyl group, a pentafluoroethyl group, a perfluorocyclohexyl group, perfluoroadamantyl group, and a haloalkyl group. The substituted aryloxy group may include an aryloxy group substituted with a halogen atom or a haloalkyl group having 1 to 5 carbon atoms, such as a 4-trifluoromethylphenyloxy group and a pentafluorophenyloxy group, and an aryloxy group substituted with an alkyl group having 1 to 10, preferably 1 to 5 carbon atoms, such as a 4-t-butylphenoxy group.

R³¹ and R³², or R³³ and R³⁴ may be bonded to each other to form a ring, such as a benzene ring, a naphthalene ring, a pyrazine ring, a pyridine ring, and a furan ring.

### Acceptor Material (C)

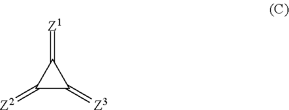

wherein each of Z¹ to Z³ independently represents a divalent group represented by formula (h):

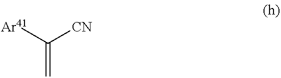

wherein Ar⁴¹ represents a substituted or unsubstituted aryl group having 6 to 50 ring carbon atoms or a substituted or unsubstituted heteroaryl group having 5 to 50 ring atoms.

The aryl group may include a phenyl group and a naphthyl group.

The heteroaryl group may include a pyridine, a pyrazine, a pyrimidine, a quinoline, and an isoquinoline.

The substituent for these groups may include an electron-withdrawing group, such as a cyano group, a fluorine atom, a trifluoromethyl group, a chlorine atom, and a bromine atom.

### (2) Light-Transmissive Substrate

The organic EL device of the invention is formed on a light-transmissive substrate. The light-transmissive substrate serves as a support for the organic EL device and preferably a flat substrate having a transmittance of 50% or more to 400 to 700 nm visible light.

Examples of the substrate include a glass plate and a polymer plate. The glass plate may include a plate made of soda-lime glass, barium-strontium-containing glass, lead glass, aluminosilicate glass, borosilicate glass, barium borosilicate glass, or quartz. The polymer plate may include a plate made of polycarbonate, acryl, polyethylene terephthalate, polyether sulfide, or polysulfone.

### (3) Anode

The anode of the organic EL device injects holes to the hole transporting layer or the light emitting layer, and an anode having a work function of 4.5 eV or more is effective. Examples of material for anode include indium tin oxide alloy (ITO), tin oxide (NESA), indium-zinc oxide alloy (IZO), gold, silver, platinum, and cupper.

The anode is formed by making the electrode material into a thin film by a method, such as a vapor deposition method or a sputtering method.

When getting the light emitted from the light emitting layer through the anode, the transmittance of anode to visible light is preferably 10% or more. The sheet resistance of anode is preferably several hundreds Ω/□ or less. The film thickness of anode depends upon the kind of material and generally 10 nm to 1 μm, preferably 10 to 200 nm.

### (4) Hole Transporting Layer

As described above, the organic EL device in more preferred embodiment of the invention comprises two or more hole transporting layers. The preferred embodiment of the invention is described below in more detail.

The hole transporting layer (first hole transporting layer) not adjacent to the light emitting layer is often made thicker for the optical adjustment. To ensure a low driving voltage even when the thickness is made greater, the first hole transporting layer is needed to have a high hole mobility. In addition, the first hole transporting layer is often laminated with an acceptor layer for efficient generation of carriers, and therefore, is needed to have a large interaction with the acceptor layer.

The compound represented by formula (1) has a high hole mobility and is capable of transporting and injecting more holes into the light emitting layer, because a large amount of carriers is generated by a large interaction between the compound and the highly planar acceptor material. Namely, the compound represented by formula (1) highly satisfies the properties required for the hole transporting layer (first hole transporting layer) not adjacent to the light emitting layer, and therefore, is preferably used as the material for the hole transporting layer not adjacent to the light emitting layer.

The thickness of the first hole transporting layer is preferably 10 to 200 nm. A thicker layer is needed for adjusting the optical path length of whole device. In view of this, the lower limit is preferably 30 nm, more preferably 50 nm, and particularly preferably 55 nm. Generally, the upper limit is preferably 170 nm, more preferably 160 nm, still more preferably 120 nm, and particularly preferably 90 nm, although depends on the device structure. The thickness range may be any combination of the above lower limit and the above upper limit.

Material for first hole transporting layer not adjacent to light emitting layer (first hole transporting material) represented by formula (1):

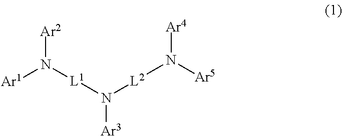

wherein:

each of L¹ and L² is independently represented by formula (1-2) or (1-3); and

each of Ar¹ to Ar⁵ is independently represented by any one of formulae (1-4) to (1-9):

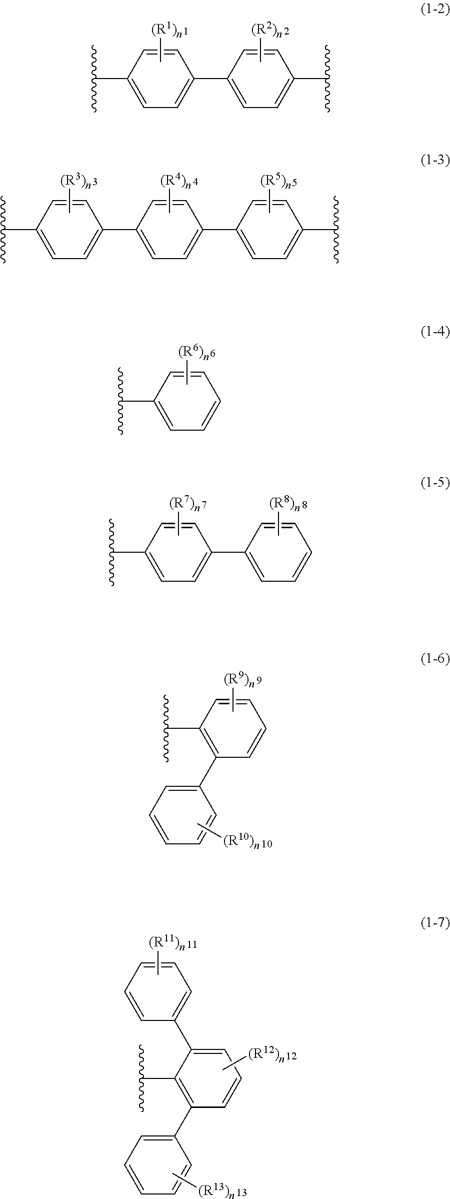

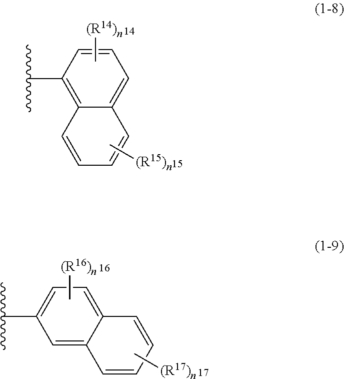

in formulae (1-2) to (1-9):

each of R¹ to R¹⁷ independently represents a substituted or unsubstituted alkyl group having 1 to 20 carbon atoms, a halogen atom, a substituted or unsubstituted fluoroalkyl group having 1 to 20 carbon atoms, a substituted or unsubstituted alkoxy group having 1 to 20 carbon atoms, a substituted or unsubstituted fluoroalkoxy group having 1 to 20 carbon atoms, or a cyano group;

each of n¹ to n⁵, n⁷, n⁹, n¹⁵, and n¹⁷ independently represents an integer of 0 to 4;

each of n⁶, n⁸, n¹⁰, n¹¹, and n¹³ independently represents an integer of 0 to 5;

each of n¹², n¹⁴, and n¹⁶ independently represents an integer of 0 to 3;

R⁶ to R¹⁷ may be bonded to each other to form a ring; and

each of wavy lines in formulae (1-2) to (1-9) indicates a bonding site.

As described above, each of L¹ and L² independently represents a group represented by formula (1-2) or (1-3), i.e., a group having a biphenylene skeleton or a terphenylene skeleton. A compound wherein L¹ and/or L² represent a phenylene group is not included in the compound represented by formula (1). This is because that the driving voltage is increased and the emission efficiency and the device lifetime are reduced when using such a compound in the first hole transporting material, as compared with the case of using the compound wherein each of L¹ and L² independently represents a group represented by formula (1-2) or (1-3).

Each of L¹ and L² is preferably represented by formula (1-2).

The alkyl group having 1 to 20 carbon atoms for R¹ to R⁵ is preferably an alkyl group having 1 to 10 carbon atoms and more preferably an alkyl group having 1 to 5 carbon atoms. The halogen atom may include a fluorine atom, a chlorine atom, a bromine atom, and an iodine atom, with a fluorine atom being preferred. The fluoroalkyl group having 1 to 20 carbon atoms is preferably a fluoroalkyl group having 1 to 10 carbon atoms and more preferably a fluoroalkyl group having 1 to 5 carbon atoms. The alkoxy group having 1 to 20 carbon atoms is preferably an alkoxy group having 1 to 10 carbon atoms and more preferably an alkoxy group having 1 to 5 carbon atoms. The fluoroalkoxy group having 1 to 20 carbon atoms is preferably a fluoroalkoxy group having 1 to 10 carbon atoms and more preferably a fluoroalkoxy group having 1 to 5 carbon atoms.

The alkyl group, the fluoroalkyl group, the alkoxy group, and the fluoroalkoxy group mentioned above may be substituted, for example, with at least one substituent selected from a hydroxyl group, a halogen atom other than fluorine atom, a cyano group, a nitro group, and an amino group.

Each of n¹ to n⁵ is preferably 0 or 1 and more preferably 0.

Each of Ar¹ to Ar⁵ may be any one of the groups represented by formulae (1-4) to (1-9) and Ar¹ to Ar⁵ may be any combination of these groups. Each of Ar¹, Ar², Ar⁴, and Ar⁵ is preferably a group represented by formula (1-4) and Ara is preferably a group represented by formula (1-5) or (1-6) and more preferably a group represented by formula (1-5).

Of the groups R⁶ to R¹⁷, the groups represented by the same symbol (for example, R⁶ groups when n⁶ is 2 or more) and the groups represented by different symbols (for example, R⁷ and R⁸) may be bonded to each other to form a ring.

Examples of the rings to be optionally formed, for example, in formulae (1-5) and (1-6) are shown below.

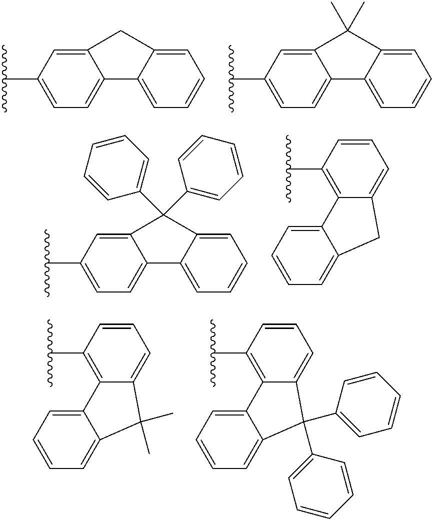

It is preferable for R⁷ and R⁸, and R⁹ and R¹⁰ to be bonded to each other to form a ring or not to be bonded to each other. For R⁶ and R¹¹ and R¹⁷, however, it is preferable not to be bonded to each other thereby failing to form a ring.

The alkyl group having 1 to 20 carbon atoms, the halogen atom, the fluoroalkyl group having 1 to 20 carbon atoms, the alkoxy group having 1 to 20 carbon atoms, and the fluoroalkoxy group having 1 to 20 carbon atoms for R⁶ to R¹⁷ and the optional substituent are as described above with respect to R¹ to R⁵.

Each of n⁶ and n¹¹ to n¹⁷ is preferably 0 or 1 and more preferably 0. Each of n⁷ to n¹⁰ is preferably 0 or 1.

The compound represented by formula (1) is preferably a compound represented by formula (1′) in view of reducing the driving voltage and improving the emission efficiency and device lifetime of an organic EL device wherein the compound is used as the first hole transporting material. Ar¹ to Ar⁵ of formula (1′) and their preferred embodiments are as defined above with respect to formula (1).

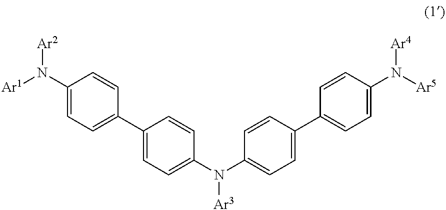

In formula (1), preferred groups may be arbitrarily combined.

Examples of the compound represented by formula (1) are shown below, although not limited to the following compounds.

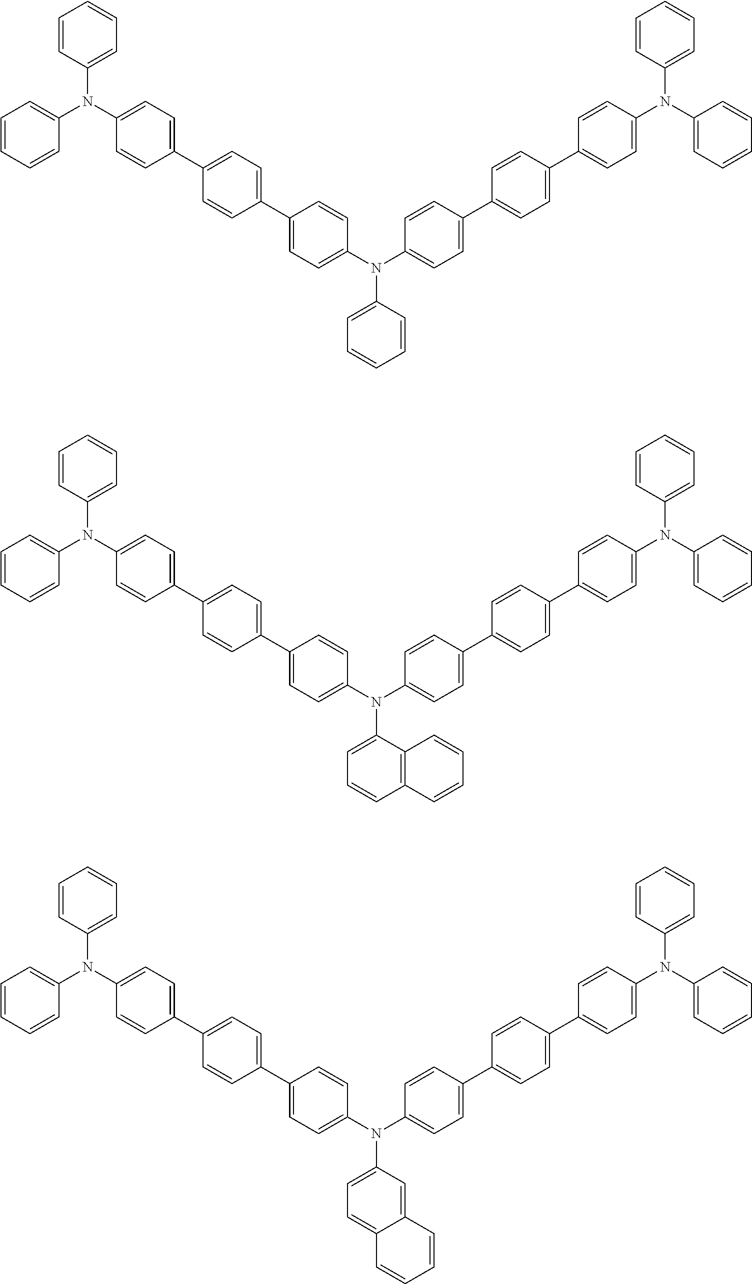 [SMILES: c1ccc(N(c2ccccc2)c2ccc(-c3ccc(-c4ccc(N(c5ccccc5)c5ccc(-c6ccc(-c7ccc(N(c8ccccc8)c8ccccc8)cc7)cc6)cc5)cc4)cc3)cc2)cc1 ; c1ccc(N(c2ccccc2)c2ccc(-c3ccc(-c4ccc(N(c5ccc(-c6ccc(-c7ccc(N(c8ccccc8)c8ccccc8)cc7)cc6)cc5)c5cccc6ccccc56)cc4)cc3)cc2)cc1 ; c1ccc(N(c2ccccc2)c2ccc(-c3ccc(-c4ccc(N(c5ccc(-c6ccc(-c7ccc(N(c8ccccc8)c8ccccc8)cc7)cc6)cc5)c5ccc6ccccc6c5)cc4)cc3)cc2)cc1]

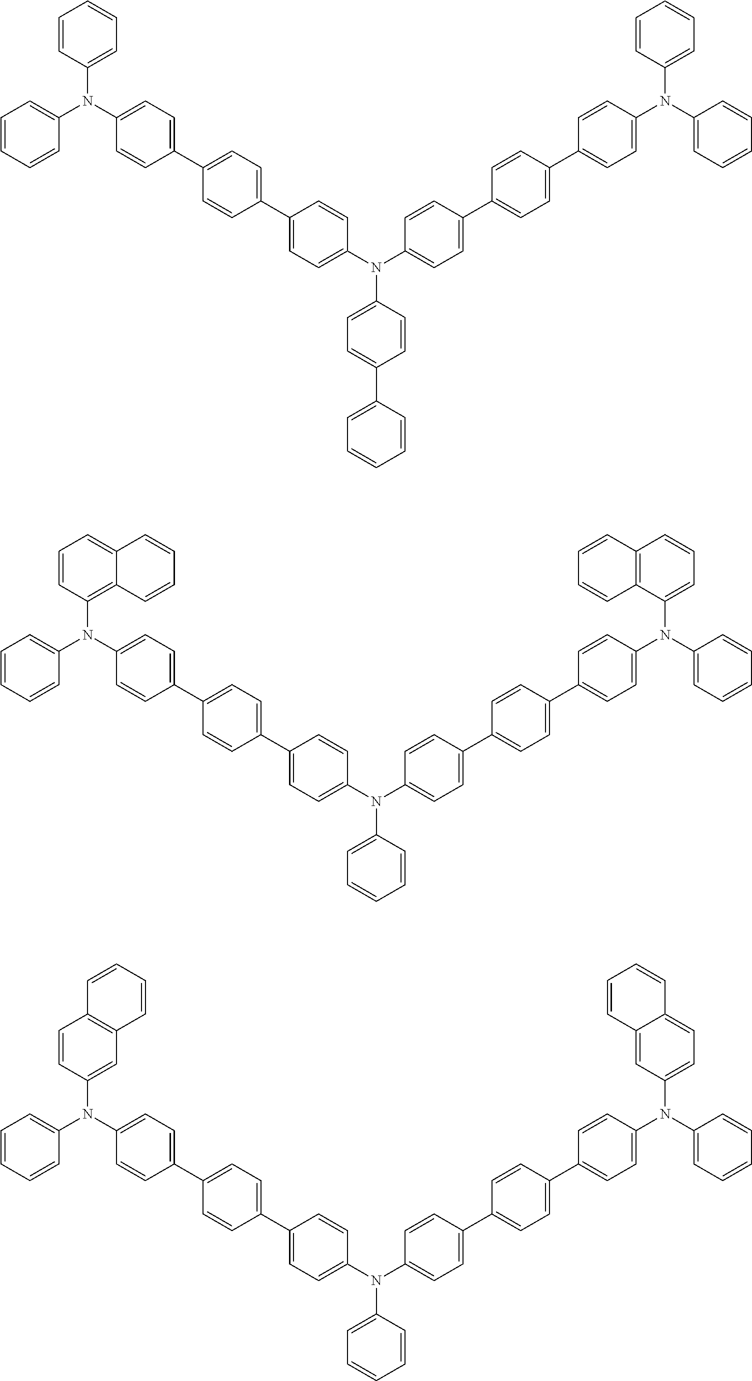 [SMILES: c1ccc(-c2ccc(N(c3ccc(-c4ccc(-c5ccc(N(c6ccccc6)c6ccccc6)cc5)cc4)cc3)c3ccc(-c4ccc(-c5ccc(N(c6ccccc6)c6ccccc6)cc5)cc4)cc3)cc2)cc1 ; c1ccc(N(c2ccc(-c3ccc(-c4ccc(N(c5ccccc5)c5cccc6ccccc56)cc4)cc3)cc2)c2ccc(-c3ccc(-c4ccc(N(c5ccccc5)c5cccc6ccccc56)cc4)cc3)cc2)cc1 ; c1ccc(N(c2ccc(-c3ccc(-c4ccc(N(c5ccccc5)c5ccc6ccccc6c5)cc4)cc3)cc2)c2ccc(-c3ccc(-c4ccc(N(c5ccccc5)c5ccc6ccccc6c5)cc4)cc3)cc2)cc1]

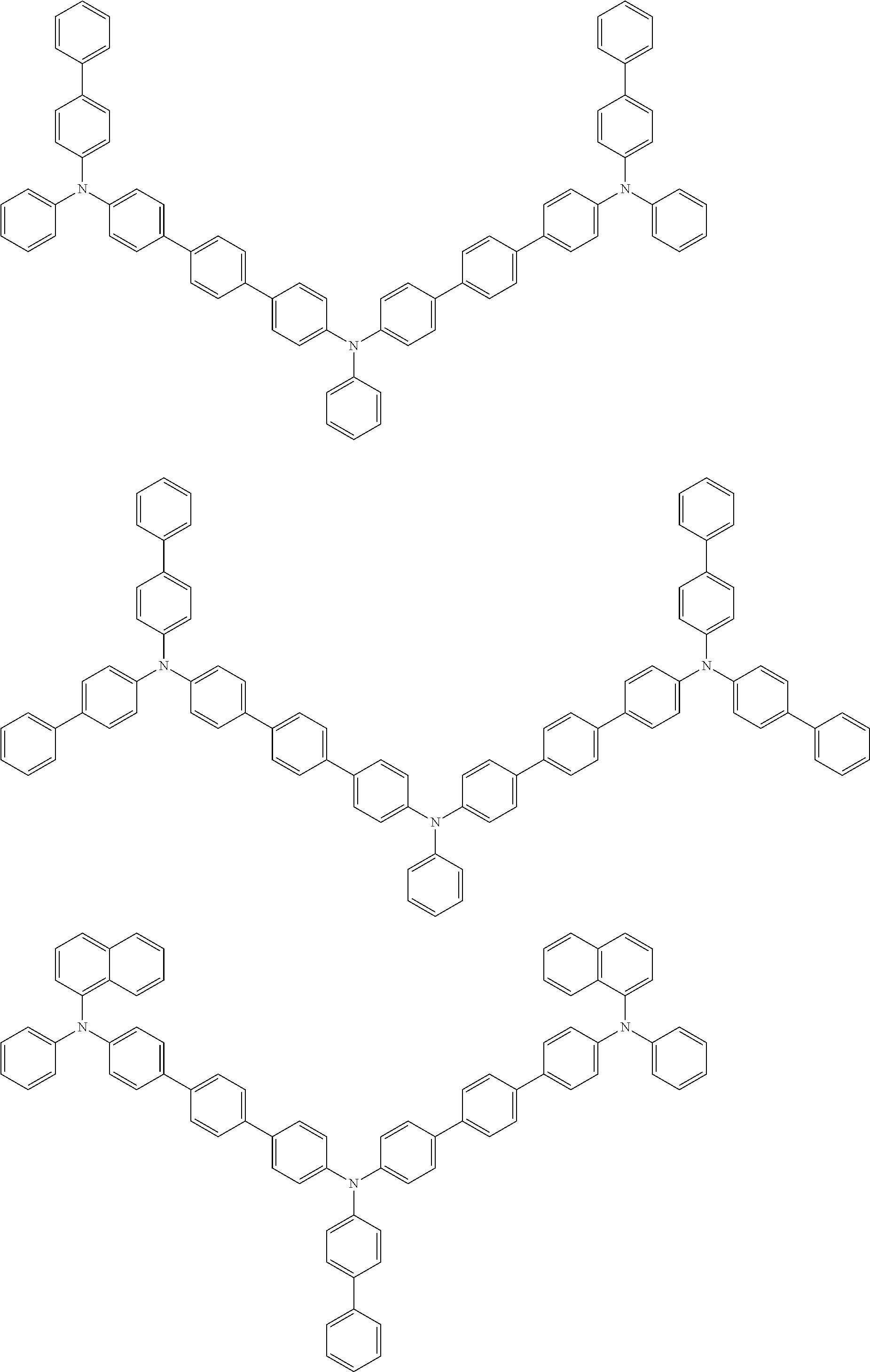 [SMILES: c1ccc(-c2ccc(N(c3ccccc3)c3ccc(-c4ccc(-c5ccc(N(c6ccccc6)c6ccc(-c7ccc(-c8ccc(N(c9ccccc9)c9ccc(-c%10ccccc%10)cc9)cc8)cc7)cc6)cc5)cc4)cc3)cc2)cc1 ; c1ccc(-c2ccc(N(c3ccc(-c4ccccc4)cc3)c3ccc(-c4ccc(-c5ccc(N(c6ccccc6)c6ccc(-c7ccc(-c8ccc(N(c9ccc(-c%10ccccc%10)cc9)c9ccc(-c%10ccccc%10)cc9)cc8)cc7)cc6)cc5)cc4)cc3)cc2)cc1 ; c1ccc(-c2ccc(N(c3ccc(-c4ccc(-c5ccc(N(c6ccccc6)c6cccc7ccccc67)cc5)cc4)cc3)c3ccc(-c4ccc(-c5ccc(N(c6ccccc6)c6cccc7ccccc67)cc5)cc4)cc3)cc2)cc1]

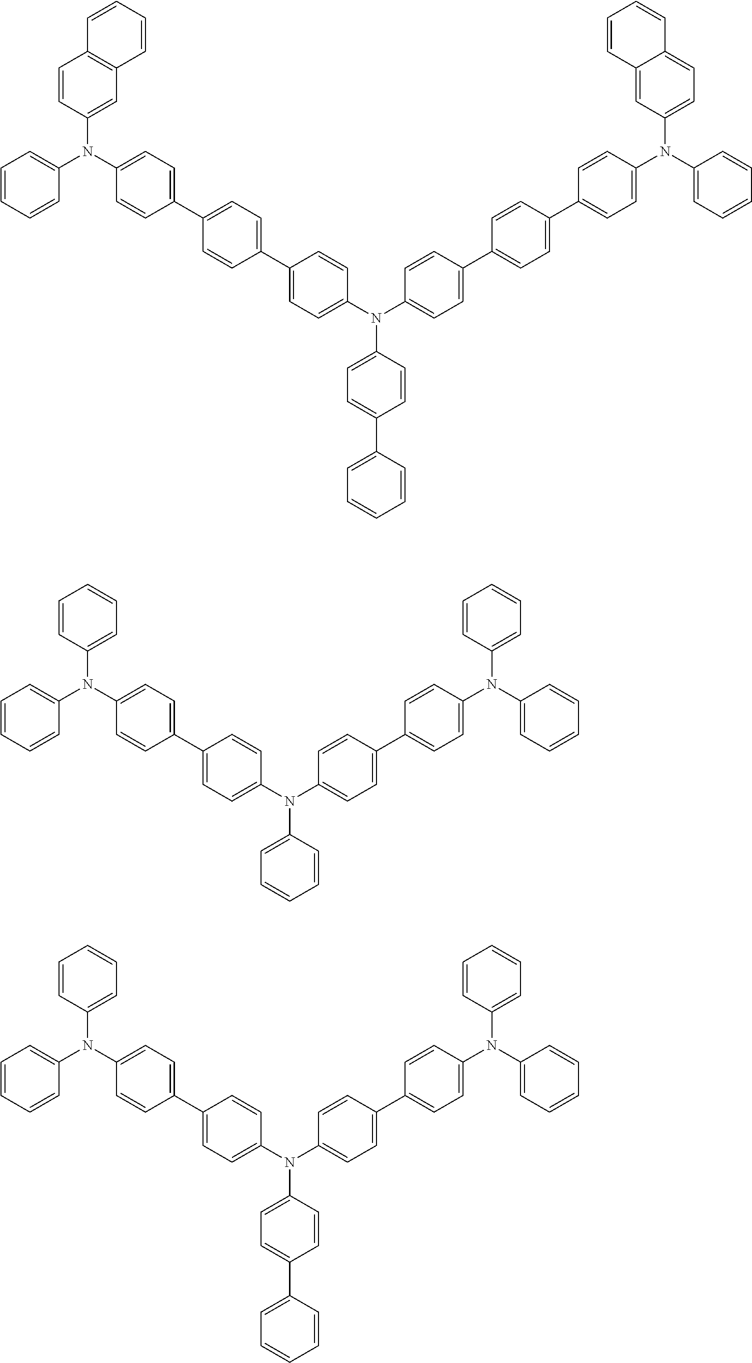 [SMILES: c1ccc(-c2ccc(N(c3ccc(-c4ccc(-c5ccc(N(c6ccccc6)c6ccc7ccccc7c6)cc5)cc4)cc3)c3ccc(-c4ccc(-c5ccc(N(c6ccccc6)c6ccc7ccccc7c6)cc5)cc4)cc3)cc2)cc1 ; c1ccc(N(c2ccccc2)c2ccc(-c3ccc(N(c4ccccc4)c4ccc(-c5ccc(N(c6ccccc6)c6ccccc6)cc5)cc4)cc3)cc2)cc1 ; c1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1]

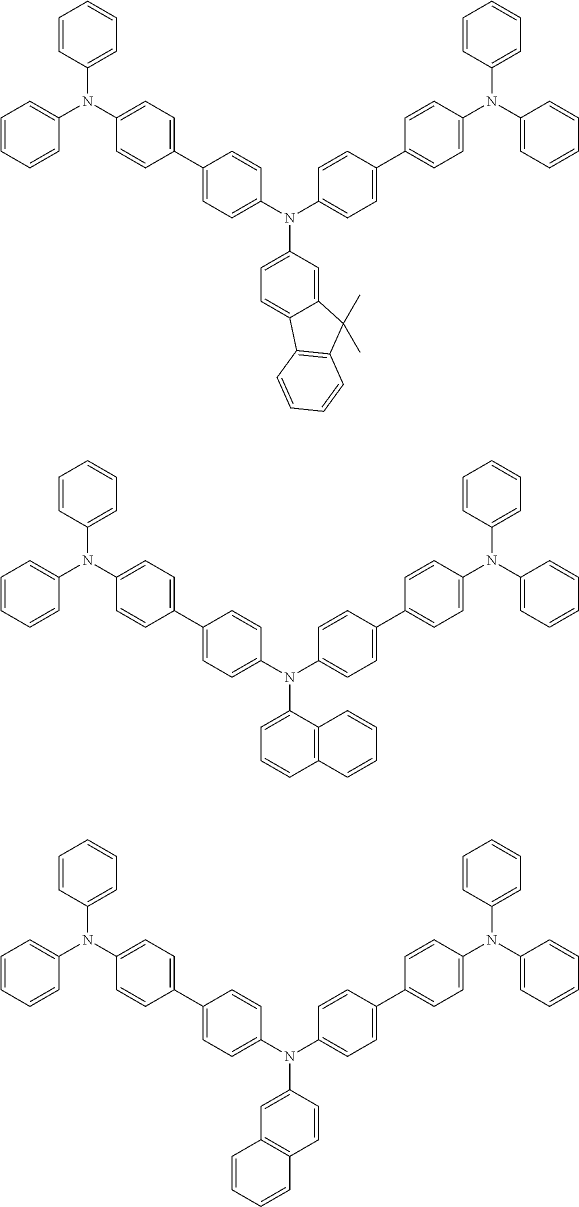 [SMILES: CC1(C)c2ccccc2-c2ccc(N(c3ccc(-c4ccc(N(c5ccccc5)c5ccccc5)cc4)cc3)c3ccc(-c4ccc(N(c5ccccc5)c5ccccc5)cc4)cc3)cc21 ; c1ccc(N(c2ccccc2)c2ccc(-c3ccc(N(c4ccc(-c5ccc(N(c6ccccc6)c6ccccc6)cc5)cc4)c4cccc5ccccc45)cc3)cc2)cc1 ; c1ccc(N(c2ccccc2)c2ccc(-c3ccc(N(c4ccc(-c5ccc(N(c6ccccc6)c6ccccc6)cc5)cc4)c4ccc5ccccc5c4)cc3)cc2)cc1]

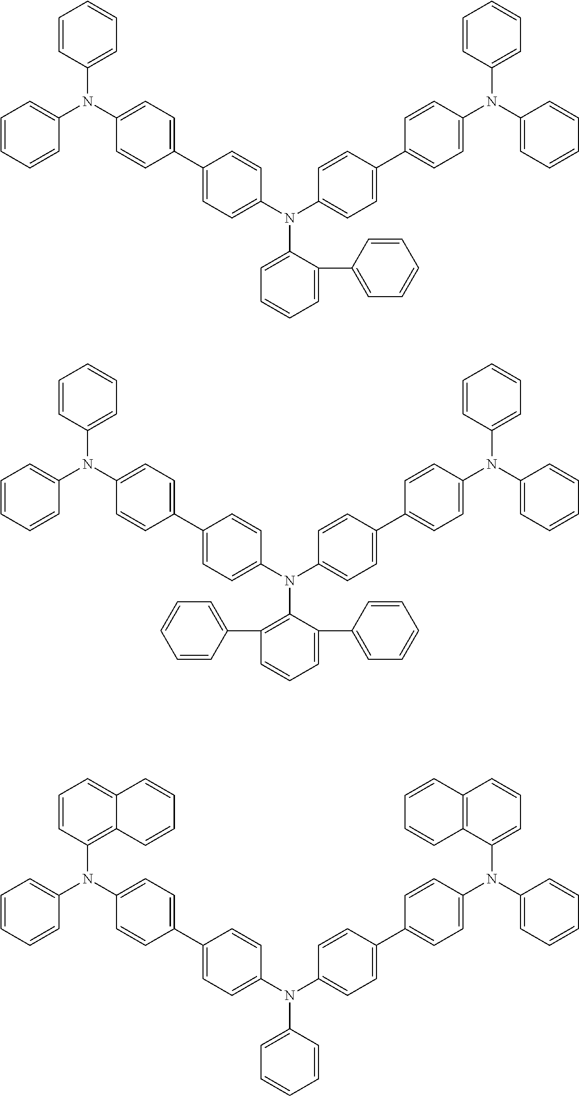 [SMILES: c1ccc(-c2ccccc2N(c2ccc(-c3ccc(N(c4ccccc4)c4ccccc4)cc3)cc2)c2ccc(-c3ccc(N(c4ccccc4)c4ccccc4)cc3)cc2)cc1 ; c1ccc(-c2cccc(-c3ccccc3)c2N(c2ccc(-c3ccc(N(c4ccccc4)c4ccccc4)cc3)cc2)c2ccc(-c3ccc(N(c4ccccc4)c4ccccc4)cc3)cc2)cc1 ; c1ccc(N(c2ccc(-c3ccc(N(c4ccccc4)c4cccc5ccccc45)cc3)cc2)c2ccc(-c3ccc(N(c4ccccc4)c4cccc5ccccc45)cc3)cc2)cc1]

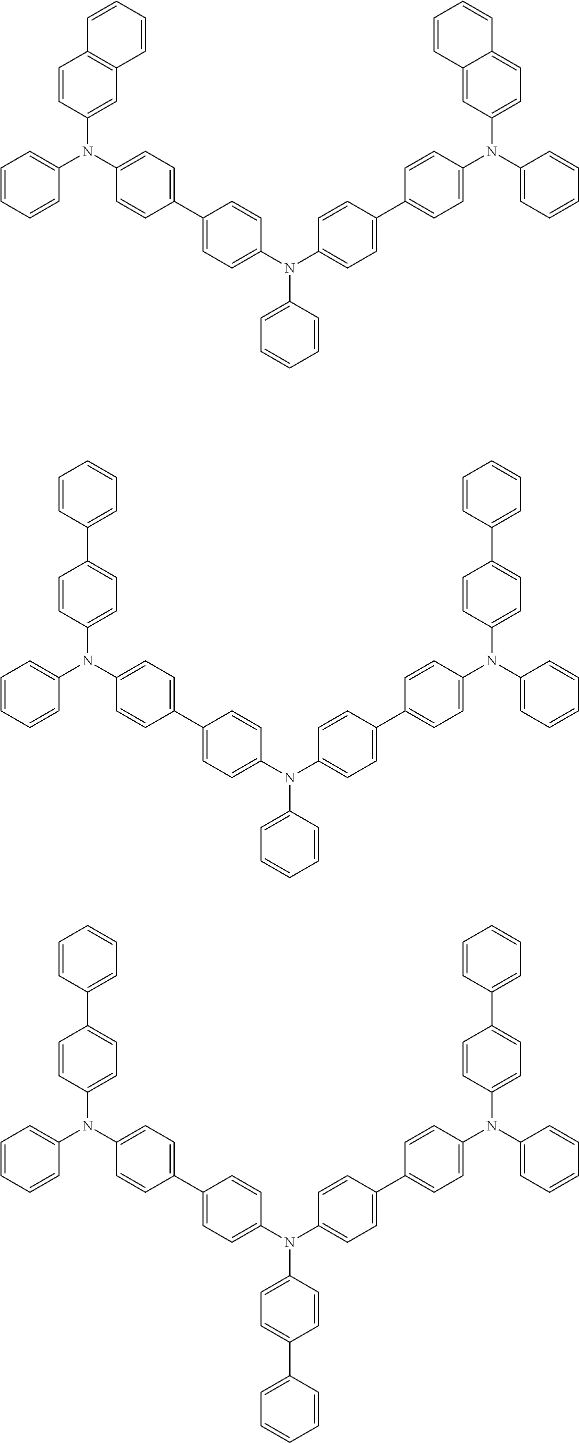 [SMILES: c1ccc(N(c2ccc(-c3ccc(N(c4ccccc4)c4ccc5ccccc5c4)cc3)cc2)c2ccc(-c3ccc(N(c4ccccc4)c4ccc5ccccc5c4)cc3)cc2)cc1 ; c1ccc(-c2ccc(N(c3ccccc3)c3ccc(-c4ccc(N(c5ccccc5)c5ccc(-c6ccc(N(c7ccccc7)c7ccc(-c8ccccc8)cc7)cc6)cc5)cc4)cc3)cc2)cc1 ; c1ccc(-c2ccc(N(c3ccccc3)c3ccc(-c4ccc(N(c5ccc(-c6ccccc6)cc5)c5ccc(-c6ccc(N(c7ccccc7)c7ccc(-c8ccccc8)cc7)cc6)cc5)cc4)cc3)cc2)cc1]

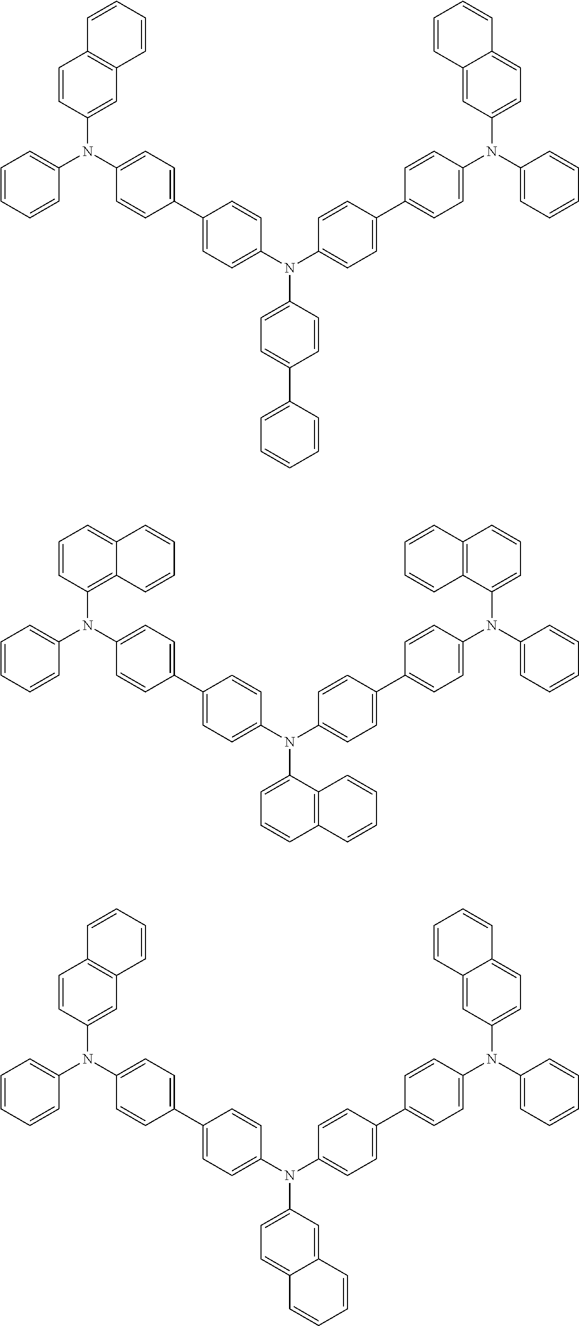 [SMILES: c1ccc(-c2ccc(N(c3ccc(-c4ccc(N(c5ccccc5)c5ccc6ccccc6c5)cc4)cc3)c3ccc(-c4ccc(N(c5ccccc5)c5ccc6ccccc6c5)cc4)cc3)cc2)cc1 ; c1ccc(N(c2ccc(-c3ccc(N(c4ccc(-c5ccc(N(c6ccccc6)c6cccc7ccccc67)cc5)cc4)c4cccc5ccccc45)cc3)cc2)c2cccc3ccccc23)cc1 ; c1ccc(N(c2ccc(-c3ccc(N(c4ccc(-c5ccc(N(c6ccccc6)c6ccc7ccccc7c6)cc5)cc4)c4ccc5ccccc5c4)cc3)cc2)c2ccc3ccccc3c2)cc1]

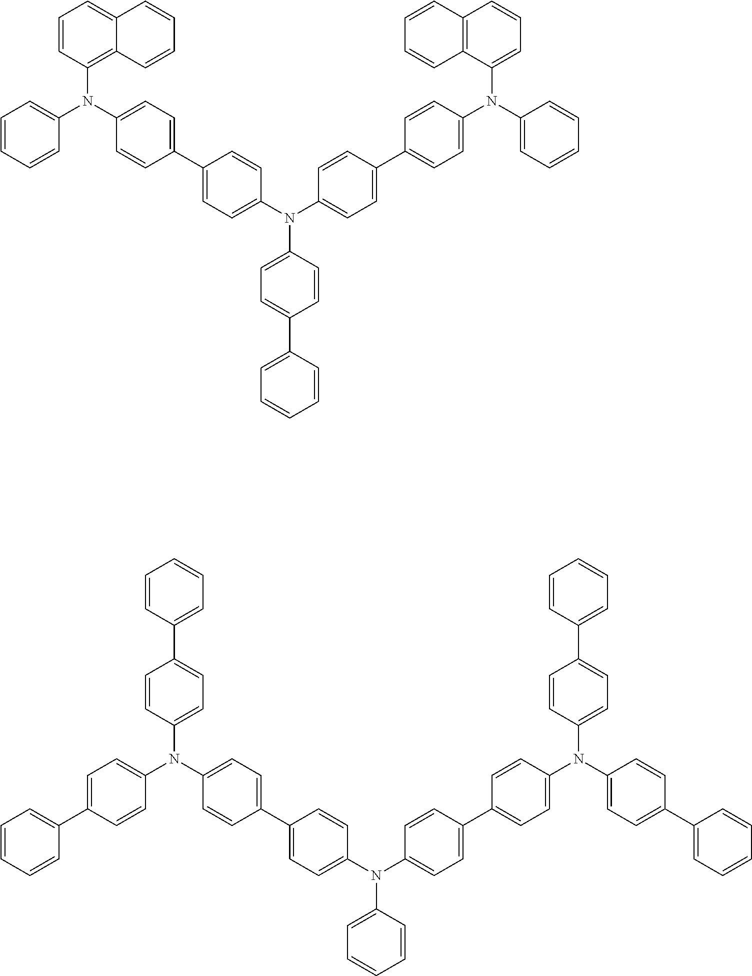 [SMILES: c1ccc(-c2ccc(N(c3ccc(-c4ccc(N(c5ccccc5)c5cccc6ccccc56)cc4)cc3)c3ccc(-c4ccc(N(c5ccccc5)c5cccc6ccccc56)cc4)cc3)cc2)cc1 ; c1ccc(-c2ccc(N(c3ccc(-c4ccccc4)cc3)c3ccc(-c4ccc(N(c5ccccc5)c5ccc(-c6ccc(N(c7ccc(-c8ccccc8)cc7)c7ccc(-c8ccccc8)cc7)cc6)cc5)cc4)cc3)cc2)cc1]

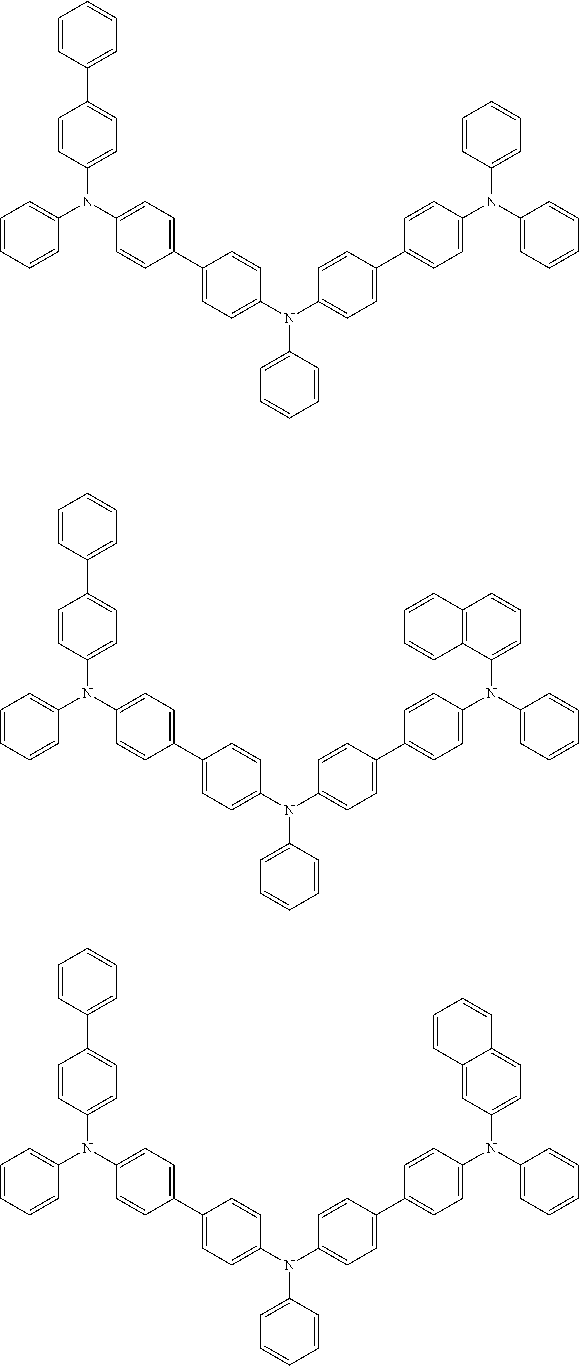 [SMILES: c1ccc(-c2ccc(N(c3ccccc3)c3ccc(-c4ccc(N(c5ccccc5)c5ccc(-c6ccc(N(c7ccccc7)c7ccccc7)cc6)cc5)cc4)cc3)cc2)cc1 ; c1ccc(-c2ccc(N(c3ccccc3)c3ccc(-c4ccc(N(c5ccccc5)c5ccc(-c6ccc(N(c7ccccc7)c7cccc8ccccc78)cc6)cc5)cc4)cc3)cc2)cc1 ; c1ccc(-c2ccc(N(c3ccccc3)c3ccc(-c4ccc(N(c5ccccc5)c5ccc(-c6ccc(N(c7ccccc7)c7ccc8ccccc8c7)cc6)cc5)cc4)cc3)cc2)cc1]

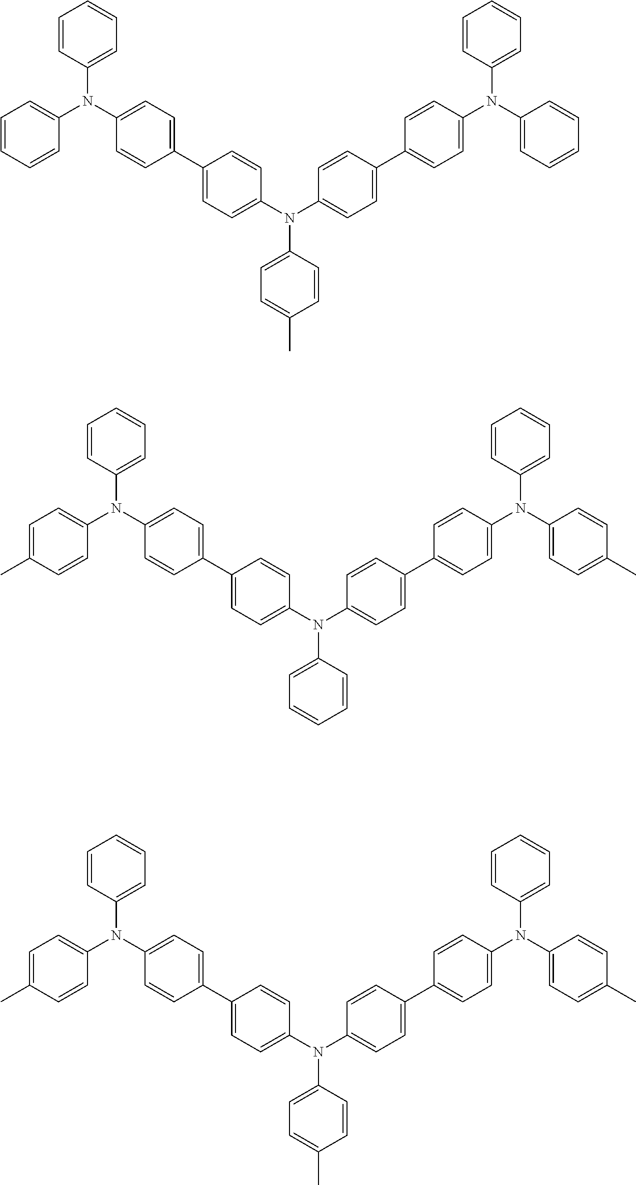

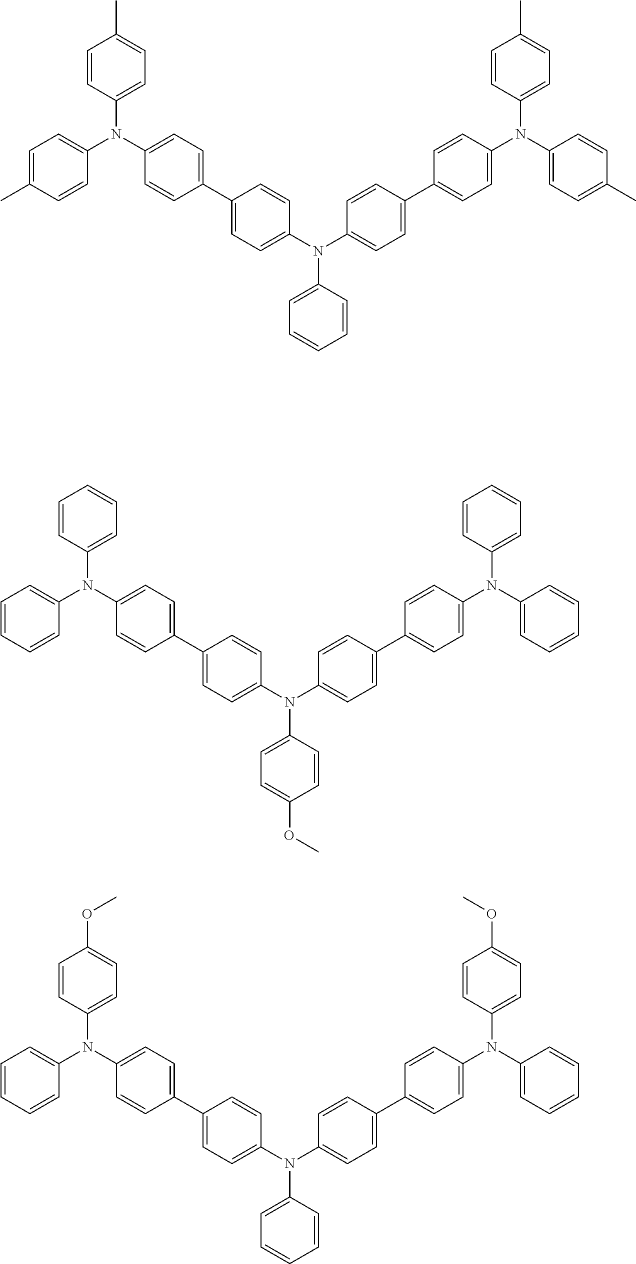

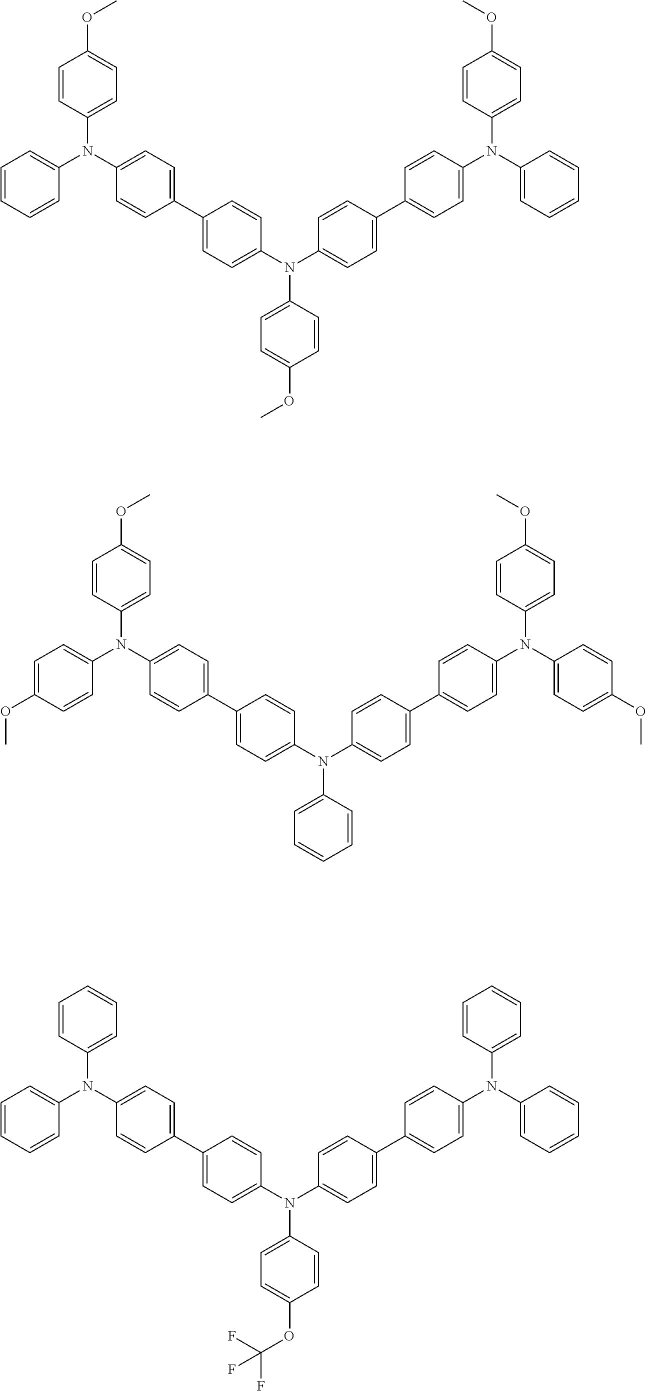 [SMILES: COc1ccc(N(c2ccccc2)c2ccc(-c3ccc(N(c4ccc(OC)cc4)c4ccc(-c5ccc(N(c6ccccc6)c6ccc(OC)cc6)cc5)cc4)cc3)cc2)cc1 ; COc1ccc(N(c2ccc(OC)cc2)c2ccc(-c3ccc(N(c4ccccc4)c4ccc(-c5ccc(N(c6ccc(OC)cc6)c6ccc(OC)cc6)cc5)cc4)cc3)cc2)cc1 ; FC(F)(F)Oc1ccc(N(c2ccc(-c3ccc(N(c4ccccc4)c4ccccc4)cc3)cc2)c2ccc(-c3ccc(N(c4ccccc4)c4ccccc4)cc3)cc2)cc1]

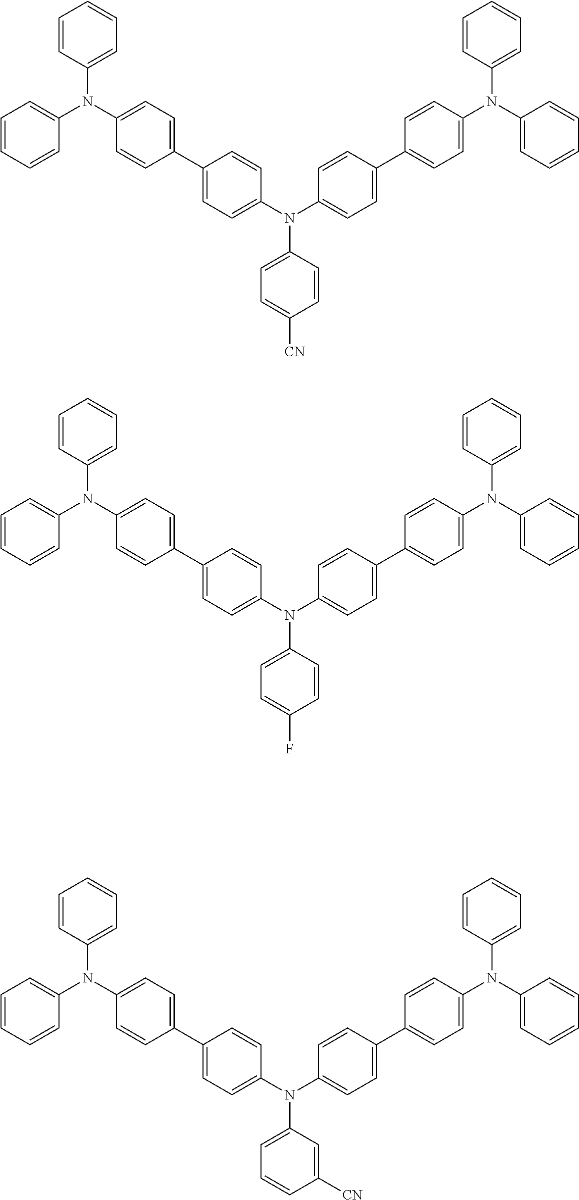 [SMILES: N#Cc1ccc(N(c2ccc(-c3ccc(N(c4ccccc4)c4ccccc4)cc3)cc2)c2ccc(-c3ccc(N(c4ccccc4)c4ccccc4)cc3)cc2)cc1 ; Fc1ccc(N(c2ccc(-c3ccc(N(c4ccccc4)c4ccccc4)cc3)cc2)c2ccc(-c3ccc(N(c4ccccc4)c4ccccc4)cc3)cc2)cc1 ; N#Cc1cccc(N(c2ccc(-c3ccc(N(c4ccccc4)c4ccccc4)cc3)cc2)c2ccc(-c3ccc(N(c4ccccc4)c4ccccc4)cc3)cc2)c1]

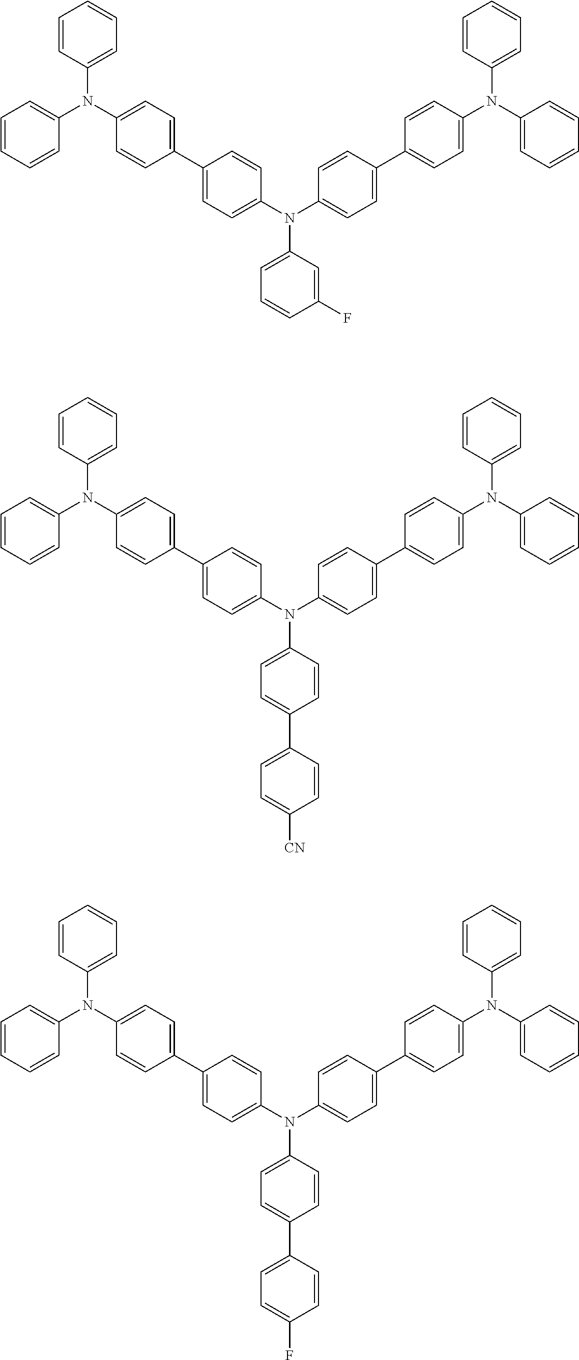 [SMILES: Fc1cccc(N(c2ccc(-c3ccc(N(c4ccccc4)c4ccccc4)cc3)cc2)c2ccc(-c3ccc(N(c4ccccc4)c4ccccc4)cc3)cc2)c1 ; N#Cc1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1 ; Fc1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1]

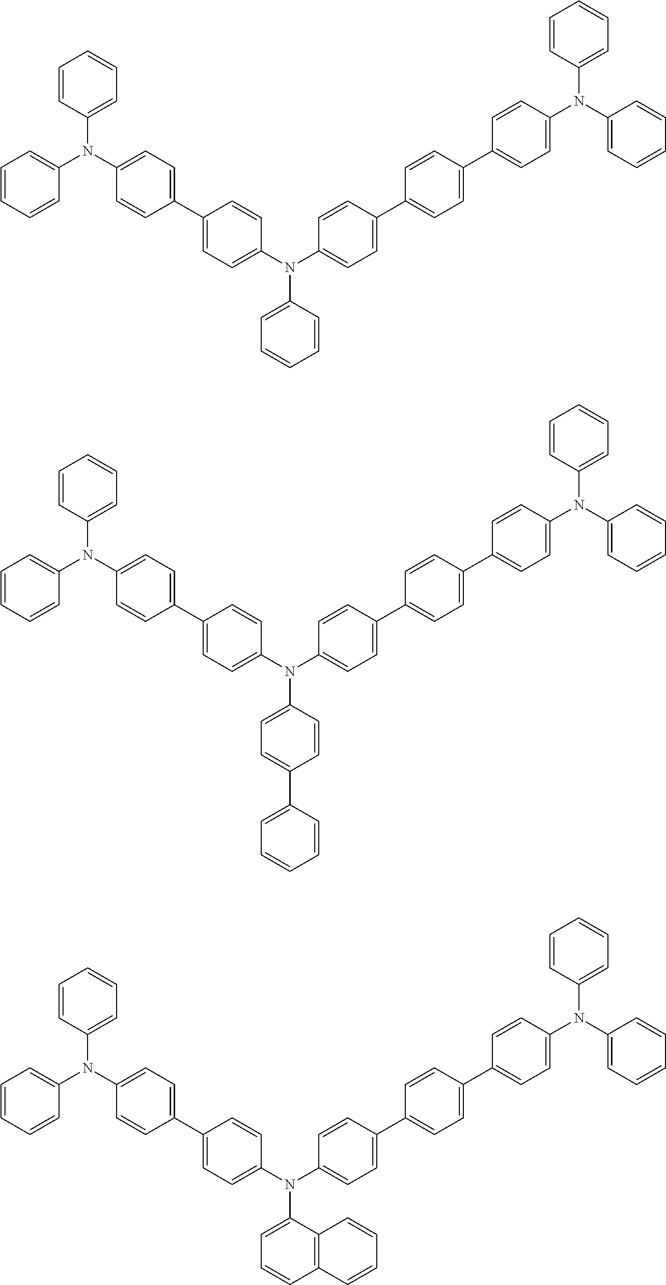 [SMILES: c1ccc(N(c2ccccc2)c2ccc(-c3ccc(-c4ccc(N(c5ccccc5)c5ccc(-c6ccc(N(c7ccccc7)c7ccccc7)cc6)cc5)cc4)cc3)cc2)cc1 ; c1ccc(-c2ccc(N(c3ccc(-c4ccc(-c5ccc(N(c6ccccc6)c6ccccc6)cc5)cc4)cc3)c3ccc(-c4ccc(N(c5ccccc5)c5ccccc5)cc4)cc3)cc2)cc1 ; c1ccc(N(c2ccccc2)c2ccc(-c3ccc(-c4ccc(N(c5ccc(-c6ccc(N(c7ccccc7)c7ccccc7)cc6)cc5)c5cccc6ccccc56)cc4)cc3)cc2)cc1]

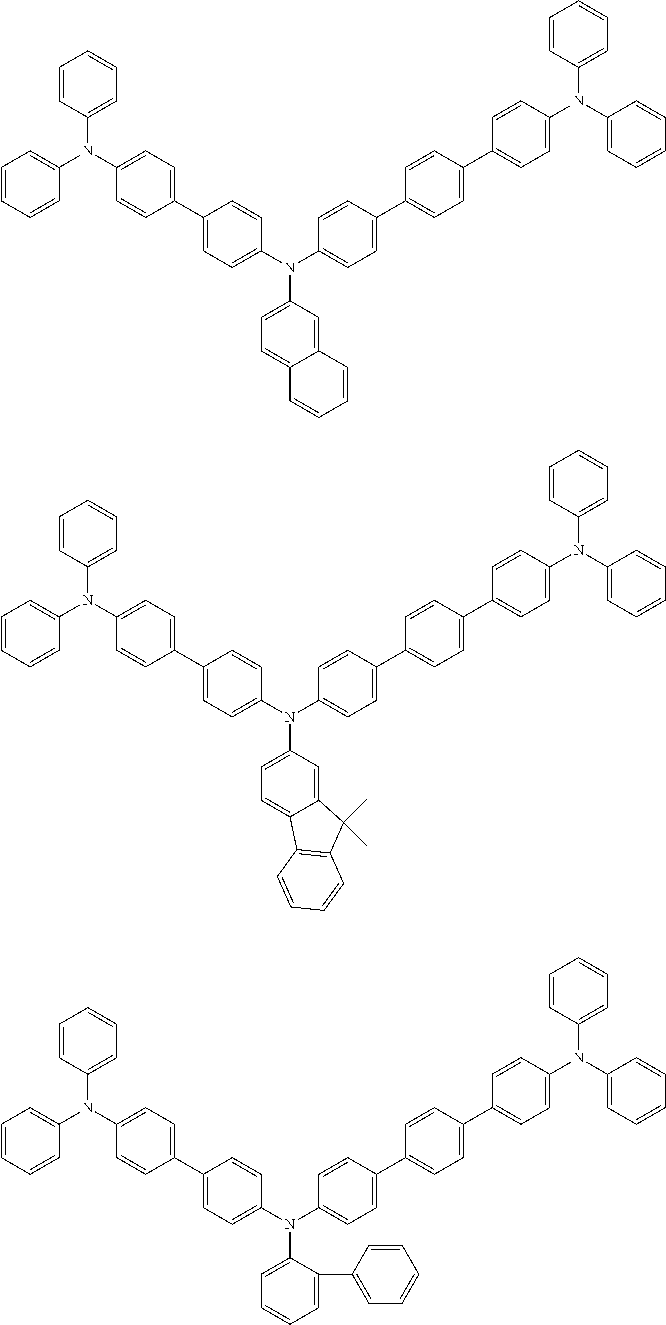 [SMILES: c1ccc(N(c2ccccc2)c2ccc(-c3ccc(-c4ccc(N(c5ccc(-c6ccc(N(c7ccccc7)c7ccccc7)cc6)cc5)c5ccc6ccccc6c5)cc4)cc3)cc2)cc1 ; CC1(C)c2ccccc2-c2ccc(N(c3ccc(-c4ccc(-c5ccc(N(c6ccccc6)c6ccccc6)cc5)cc4)cc3)c3ccc(-c4ccc(N(c5ccccc5)c5ccccc5)cc4)cc3)cc21 ; c1ccc(-c2ccccc2N(c2ccc(-c3ccc(-c4ccc(N(c5ccccc5)c5ccccc5)cc4)cc3)cc2)c2ccc(-c3ccc(N(c4ccccc4)c4ccccc4)cc3)cc2)cc1]

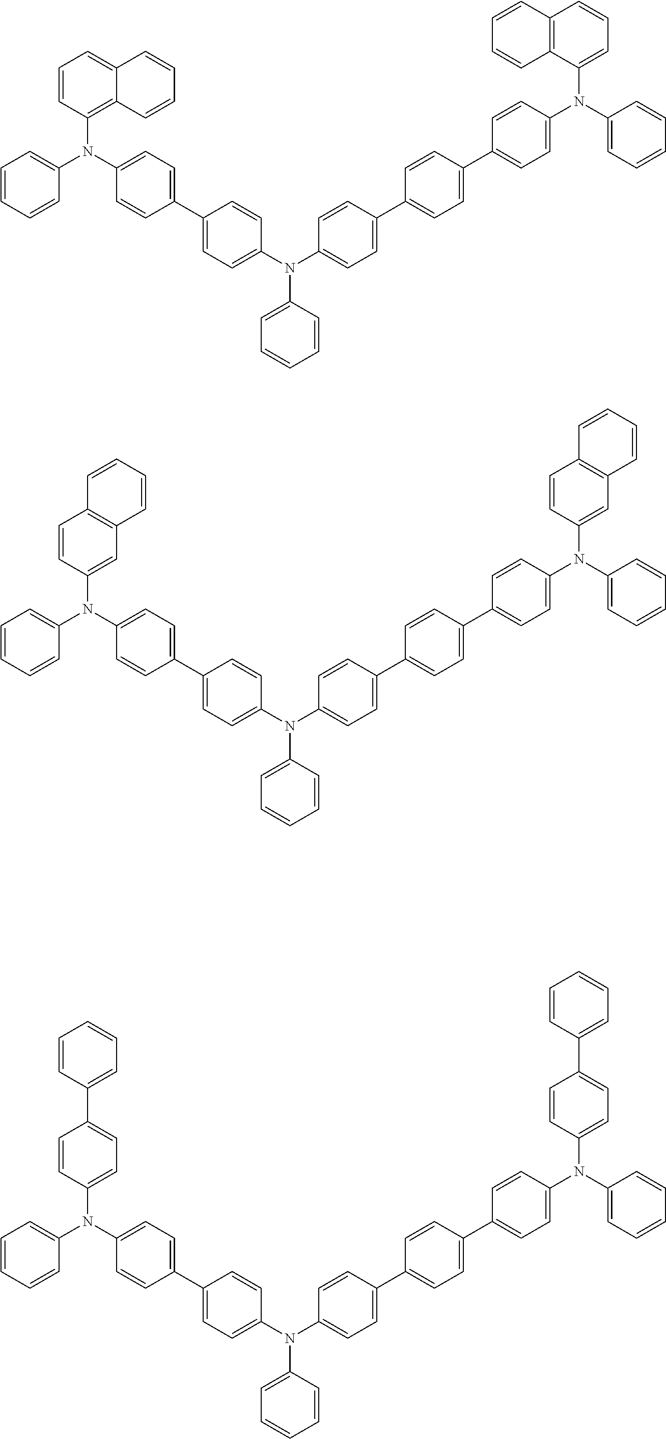 [SMILES: c1ccc(N(c2ccc(-c3ccc(-c4ccc(N(c5ccccc5)c5cccc6ccccc56)cc4)cc3)cc2)c2ccc(-c3ccc(N(c4ccccc4)c4cccc5ccccc45)cc3)cc2)cc1 ; c1ccc(N(c2ccc(-c3ccc(-c4ccc(N(c5ccccc5)c5ccc6ccccc6c5)cc4)cc3)cc2)c2ccc(-c3ccc(N(c4ccccc4)c4ccc5ccccc5c4)cc3)cc2)cc1 ; c1ccc(-c2ccc(N(c3ccccc3)c3ccc(-c4ccc(-c5ccc(N(c6ccccc6)c6ccc(-c7ccc(N(c8ccccc8)c8ccc(-c9ccccc9)cc8)cc7)cc6)cc5)cc4)cc3)cc2)cc1]

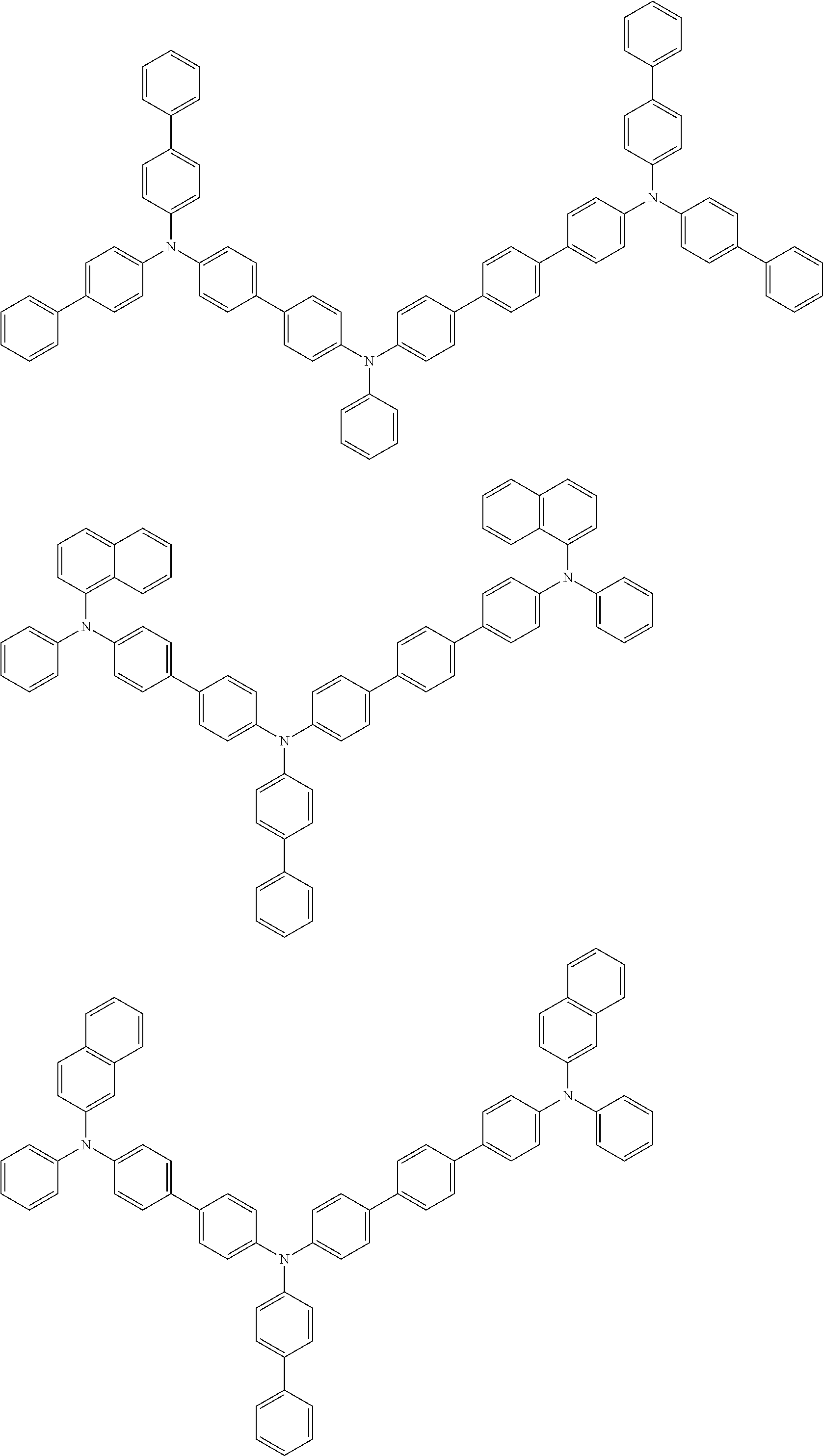 [SMILES: c1ccc(-c2ccc(N(c3ccc(-c4ccccc4)cc3)c3ccc(-c4ccc(-c5ccc(N(c6ccccc6)c6ccc(-c7ccc(N(c8ccc(-c9ccccc9)cc8)c8ccc(-c9ccccc9)cc8)cc7)cc6)cc5)cc4)cc3)cc2)cc1 ; c1ccc(-c2ccc(N(c3ccc(-c4ccc(-c5ccc(N(c6ccccc6)c6cccc7ccccc67)cc5)cc4)cc3)c3ccc(-c4ccc(N(c5ccccc5)c5cccc6ccccc56)cc4)cc3)cc2)cc1 ; c1ccc(-c2ccc(N(c3ccc(-c4ccc(-c5ccc(N(c6ccccc6)c6ccc7ccccc7c6)cc5)cc4)cc3)c3ccc(-c4ccc(N(c5ccccc5)c5ccc6ccccc6c5)cc4)cc3)cc2)cc1]

It has been known that the hole transporting layer (second hole transporting layer) adjacent to the light emitting layer is required to have (i) a high triplet energy (preferably 2.6 eV or more) to prevent the diffusion of excitation energy from the phosphorescent emitting layer, (ii) an electron resistance to because the layer is adjacent to the light emitting layer, (iii) a small affinity (preferably 2.4 eV or less) to prevent the leak of electrons from the light emitting layer; and (iv) a large ionization potential (preferably 5.5 eV or more) to facilitate the hole injection into the light emitting layer. Preferred example of a material meeting these properties include a heteroaryl-substituted amine derivative, more preferably a compound represented by any of formulae (4) to (8) in view of obtaining an excellent phosphorescent organic EL device.

The thickness of the second hole transporting layer is preferably 1 to 50 nm. Generally the lower limit is more preferably 5 nm and the upper limit is more preferably 40 nm, still more preferably 30 nm, and particularly preferably 20 nm. The thickness range may be any combination of the above lower limit and the above upper limit.

The thickness of whole hole transporting layer can be adjusted by arbitrarily combining the thickness range of the second hole transporting layer and the thickness range of the first hole transporting layer.

Material for hole transporting layer adjacent to light emitting layer (second hole transporting material) represented by formula (4):

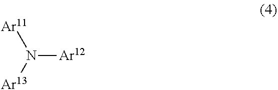

wherein each of Ar¹¹ to Ar¹³ represents a group represented by any one of formulae (4-2) to (4-4) or a substituted or unsubstituted aryl group having 6 to 40 ring carbon atoms, and at least one of Ar¹¹ to Ar¹³ represents a group represented by formula (4-2) or (4-3);

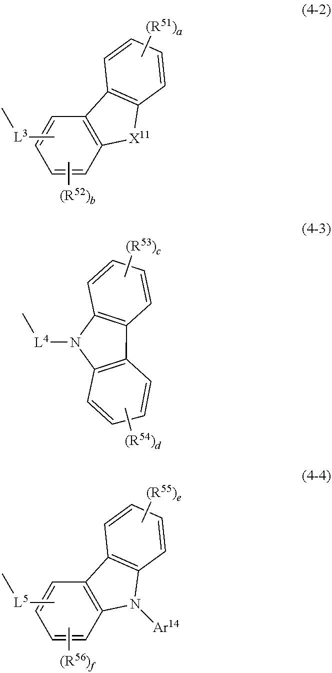

wherein:

X¹¹ represents an oxygen atom or a sulfur atom;

each of L³ to L⁵ independently represents a single bond or a substituted or unsubstituted arylene group having 6 to 50 ring carbon atoms;

an optional substituent of L³ to L⁵ is selected from a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms wherein the alkyl portion has 1 to 5 carbon atoms and the aryl portion has 6 to 14 ring carbon atoms, an aryl group having 6 to 50 ring carbon atoms, a halogen atom, and a cyano group;

Ar¹⁴ represents a substituted or unsubstituted aryl group having 6 to 50 ring carbon atoms;

an optional substituent of Ar¹⁴ is selected from a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms wherein the alkyl portion has 1 to 5 carbon atoms and the aryl portion has 6 to 14 ring carbon atoms, an aryl group having 6 to 50 ring carbon atoms, a halogen atom, and a cyano group;

each of R⁵¹ to R⁵⁶ independently represents a substituted or unsubstituted, linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, a substituted or unsubstituted alkylarylsilyl group having 8 to 15 carbon atoms wherein the alkyl portion has 1 to 5 carbon atoms and the aryl portion has 6 to 14 ring carbon atoms, a substituted or unsubstituted aryl group having 6 to 50 ring carbon atoms, a halogen atom, and a cyano group;

adjacent groups of R⁵¹ to R⁵⁶ may be bonded to each other to form a ring;

b and f independently represents an integer of 0 to 3; and

a, c, d, and e independently represents an integer of 0 to 4.

Examples of the arylene group for L³ to L⁵ include a phenylene group, a naphthylene group, a biphenylene group, an anthrylene group, an acenaphthylenylene group, an anthranylene group, a phenanthrenylene group, a phenalenylene group, a quinolylene group, an isoquinolylene group, a s-indacenylene group, an as-indacenylene group, and a chrysenylene group, with an arylene group having 6 to 30 ring carbon atoms being preferred, an arylene group having 6 to 20 ring carbon atoms being more preferred, and an arylene group having 6 to 12 ring carbon atoms. Each of L³ and L⁵ is particularly preferably a phenylene group.

The other groups are described below, in which the groups having the same name are defined in the same manner.

Examples of the alkyl group include a methyl group, an ethyl group, a n-propyl group, an isopropyl group, n-butyl group, an isobutyl group, t-butyl group, and n-hexyl group, with an alkyl group having 1 to 5 carbon atoms being preferred and an alkyl group having 1 to 3 carbon atoms being more preferred.

The alkyl group in the trialkylsilyl group and its preferred examples are as defined above. Examples of the aryl group for the triarylsilyl group include a phenyl group, a naphthyl group, and a biphenylyl group.

Examples of the alkylarylsilyl group include a dialkylmonoarylsilyl group. The alkyl group has 1 to 5, preferably 1 to 3 carbon atoms. The aryl group has 6 to 14, preferably 6 to 10 ring carbon atoms.

Examples of the aryl group having 6 to 50 ring carbon atoms include a phenyl group, a naphthyl group, a biphenylyl group, an anthryl group, a phenanthryl group, and a terphenylyl group, with an aryl group having 6 to 30 ring carbon atoms being preferred, an aryl group having 6 to 20 ring carbon atoms being more preferred, and an aryl group having 6 to 12 ring carbon atoms being still more preferred.

Examples of the halogen atom include a fluorine atom, a chlorine atom, and an iodine atom.

Each of a to f is preferably 0 or 1 and more preferably 0.

The group represented by formula (4-2) is preferably represented by formula (4-2′) or (4-2″), wherein each variable is as defined above:

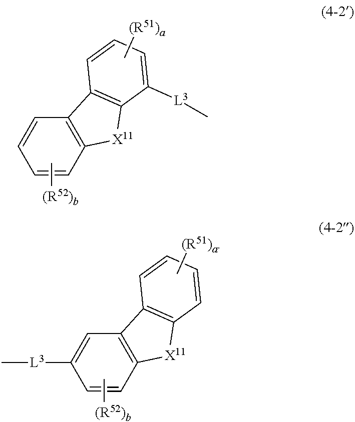

The group represented by formula (4-4) is preferably represented by formula (4-4′), wherein each variable is as defined above:

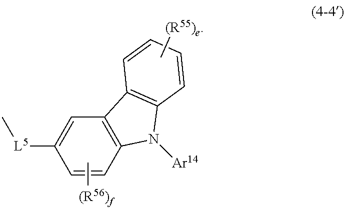

In a preferred embodiment, two of Ar¹¹ to Ar¹³ are groups represented by formula (4-2). In another preferred embodiment, one of Ar¹¹ to Ar¹³ is a group represented by formula (4-2) and each of the remaining two groups is a substituted or unsubstituted aryl group having 6 to 40 ring carbon atoms. In still another preferred embodiment, one of Ar¹¹ to Ar¹³ is a group represented by formula (4-3) and each of the remaining two groups is a substituted or unsubstituted aryl group having 6 to 40 ring carbon atoms.

X¹¹ in formula (4-2) preferably represents an oxygen atom.

When L³ of formula (4-2) is an arylene group or L⁴ of formula (4-3) is an arylene group, the increase in the electron density of the compound represented by formula (4) is prevented to increase Ip, therefore, the hole injection into the light emitting layer is promoted to reduce the driving voltage of the device. In addition, when a dibenzofuran structure or a carbazole structure is bonded to a nitrogen atom via an arylene group, the amine is made resistant to oxidation and stable in many cases to make it easy to prolong the lifetime of the device. When L⁵ of formula (4-4) is an arylene group, the compound is made stable and its synthesis is easy. Each of the arylene groups mentioned above is particularly preferably a phenylene group.

In formula (4), any of Ar¹¹ to Ar¹³ which represents a group other than formulae (4-2) to (4-4) represents a substituted or unsubstituted aryl group having 6 to 40 ring carbon atoms which is preferably represented by any one of formulae (4-5) to (4-7):

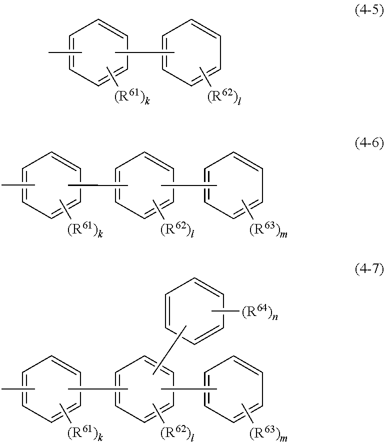

wherein:

each of R⁶¹ to R⁶⁴ independently represents a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms wherein the aryl portion has 6 to 14 ring carbon atoms, an aryl group having 6 to 50 ring carbon atoms, a halogen atom, or a cyano group;

adjacent groups of R⁶¹ to R⁶⁴ may be bonded to each other to form a ring; and

each of k, l, m, and n independently represents an integer of 0 to 4, provided that l in formula (4-7) represents an integer of 0 to 3.

The groups for R⁶¹ to R⁶⁴ and examples thereof are as defined above with respect to the groups for R⁵¹. Each of k, l, m, and n is preferably an integer of 0 to 2 and more preferably 0 or 1.

Each of formulae (4-5) to (4-7) is preferably represented by formulae (4-5′) to (4-7′), respectively, wherein the groups and preferred examples thereof are as defined above.

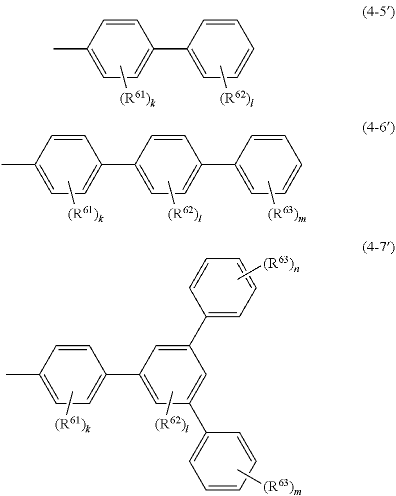

The group represented by formula (4-5′) includes the following groups:

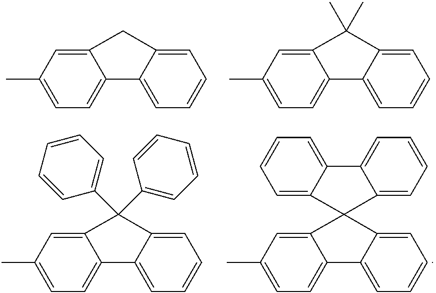

In formula (4), preferred groups may be arbitrarily combined.

Examples of the compound represented by formula (4) are shown below, although not limited to the following compounds.

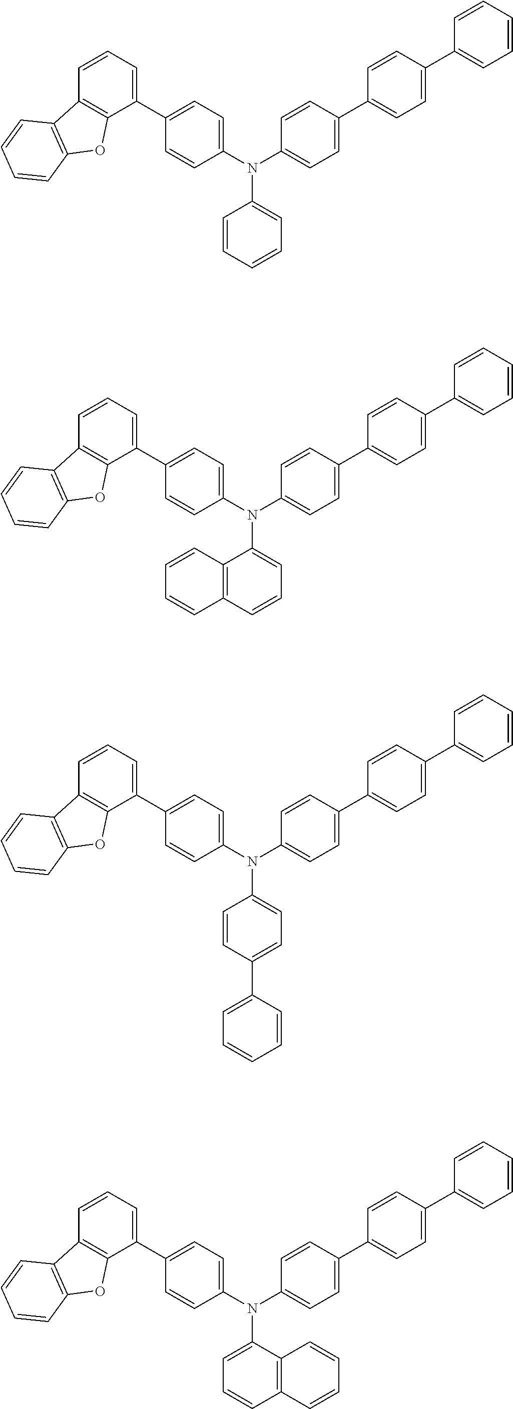 [SMILES: c1ccc(-c2ccc(-c3ccc(N(c4ccccc4)c4ccc(-c5cccc6c5oc5ccccc56)cc4)cc3)cc2)cc1 ; c1ccc(-c2ccc(-c3ccc(N(c4ccc(-c5cccc6c5oc5ccccc56)cc4)c4cccc5ccccc45)cc3)cc2)cc1 ; c1ccc(-c2ccc(-c3ccc(N(c4ccc(-c5ccccc5)cc4)c4ccc(-c5cccc6c5oc5ccccc56)cc4)cc3)cc2)cc1 ; c1ccc(-c2ccc(-c3ccc(N(c4ccc(-c5cccc6c5oc5ccccc56)cc4)c4cccc5ccccc45)cc3)cc2)cc1]

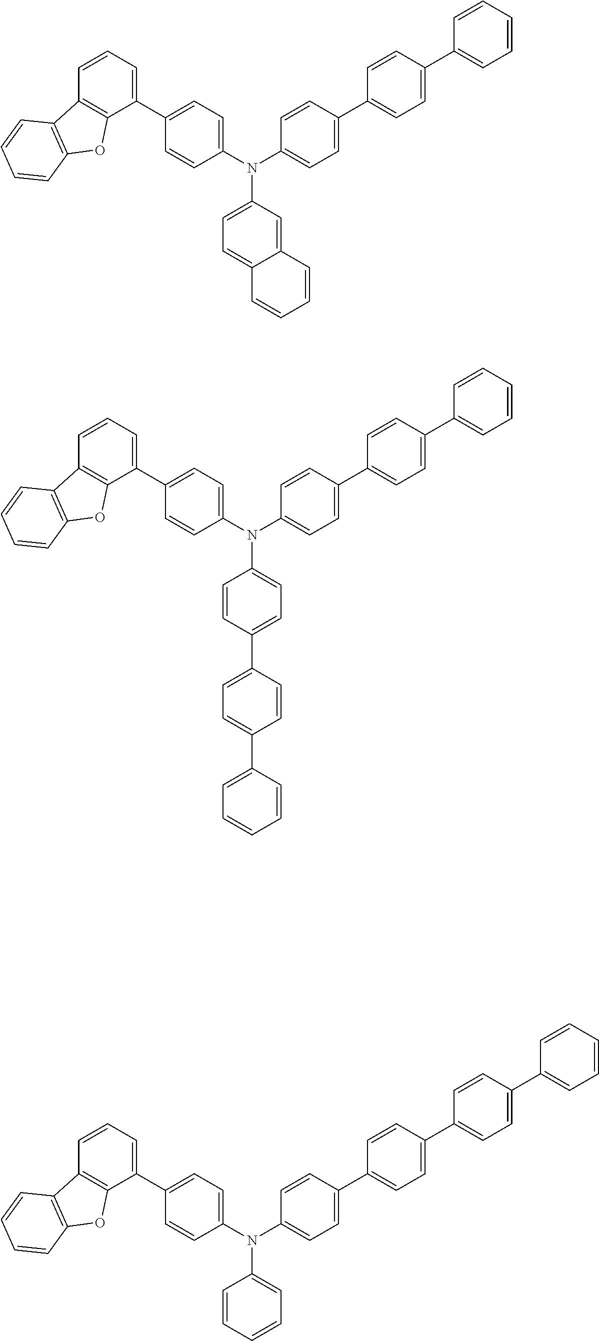 [SMILES: c1ccc(-c2ccc(-c3ccc(N(c4ccc(-c5cccc6c5oc5ccccc56)cc4)c4ccc5ccccc5c4)cc3)cc2)cc1 ; c1ccc(-c2ccc(-c3ccc(N(c4ccc(-c5ccc(-c6ccccc6)cc5)cc4)c4ccc(-c5cccc6c5oc5ccccc56)cc4)cc3)cc2)cc1 ; c1ccc(-c2ccc(-c3ccc(-c4ccc(N(c5ccccc5)c5ccc(-c6cccc7c6oc6ccccc67)cc5)cc4)cc3)cc2)cc1]

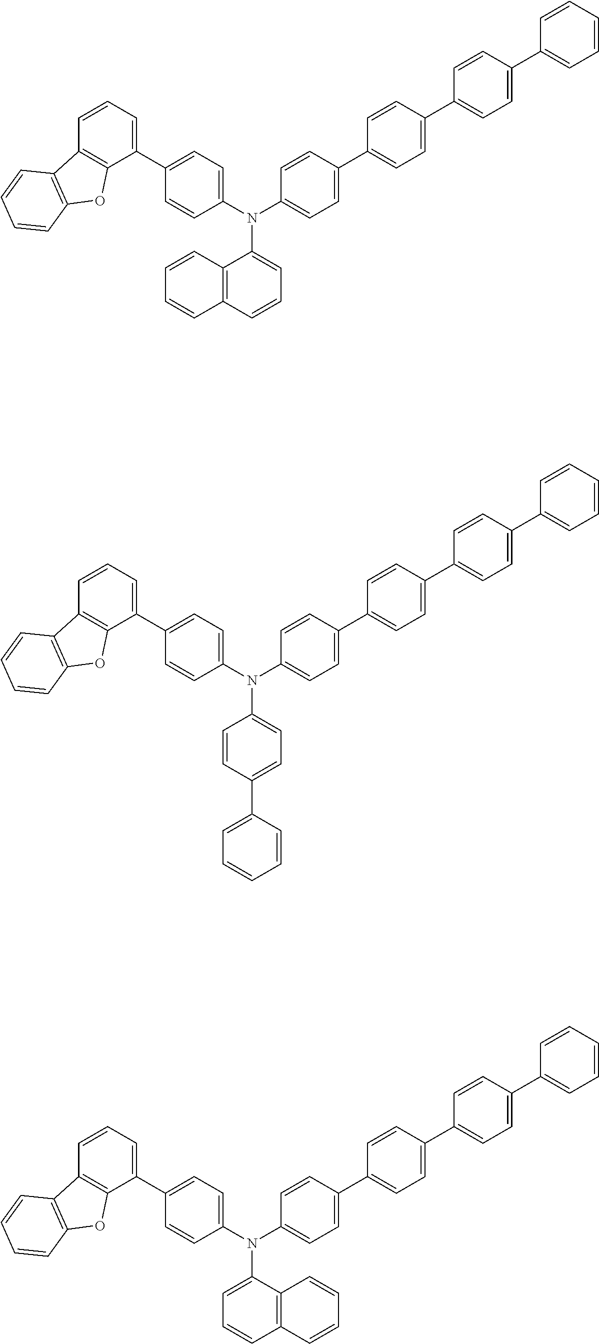 [SMILES: c1ccc(-c2ccc(-c3ccc(-c4ccc(N(c5ccc(-c6cccc7c6oc6ccccc67)cc5)c5cccc6ccccc56)cc4)cc3)cc2)cc1 ; c1ccc(-c2ccc(-c3ccc(-c4ccc(N(c5ccc(-c6ccccc6)cc5)c5ccc(-c6cccc7c6oc6ccccc67)cc5)cc4)cc3)cc2)cc1 ; c1ccc(-c2ccc(-c3ccc(-c4ccc(N(c5ccc(-c6cccc7c6oc6ccccc67)cc5)c5cccc6ccccc56)cc4)cc3)cc2)cc1]

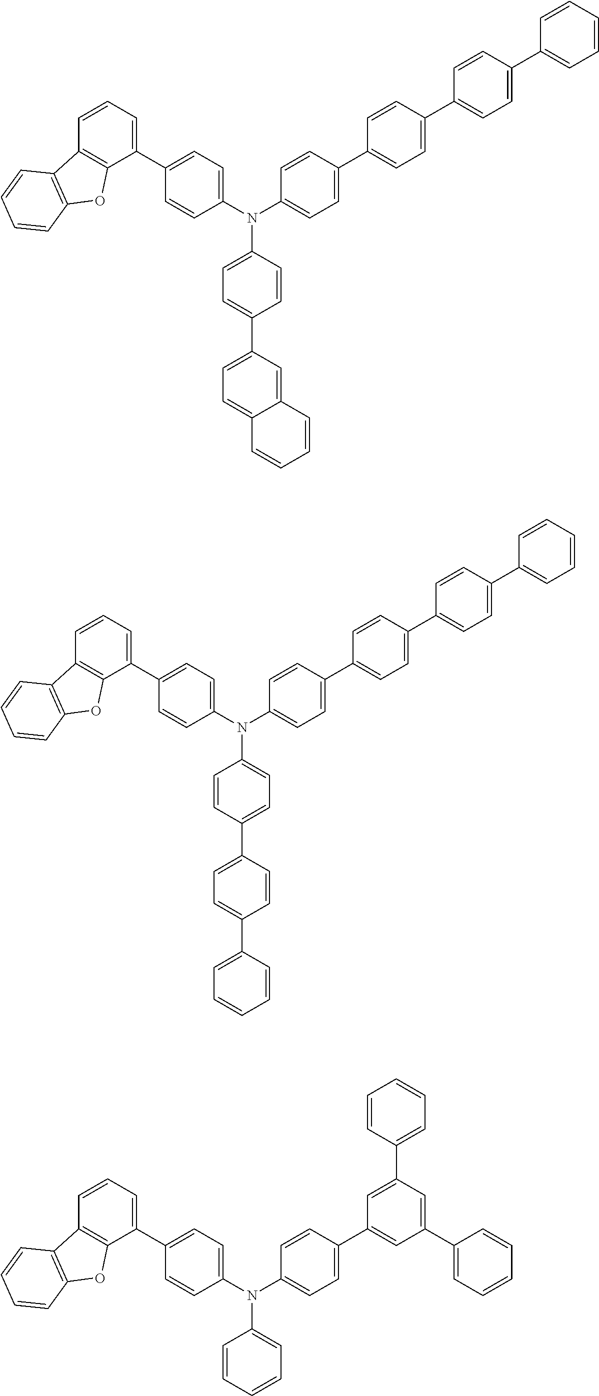 [SMILES: c1ccc(-c2ccc(-c3ccc(-c4ccc(N(c5ccc(-c6ccc7ccccc7c6)cc5)c5ccc(-c6cccc7c6oc6ccccc67)cc5)cc4)cc3)cc2)cc1 ; c1ccc(-c2ccc(-c3ccc(-c4ccc(N(c5ccc(-c6ccc(-c7ccccc7)cc6)cc5)c5ccc(-c6cccc7c6oc6ccccc67)cc5)cc4)cc3)cc2)cc1 ; c1ccc(-c2cc(-c3ccccc3)cc(-c3ccc(N(c4ccccc4)c4ccc(-c5cccc6c5oc5ccccc56)cc4)cc3)c2)cc1]

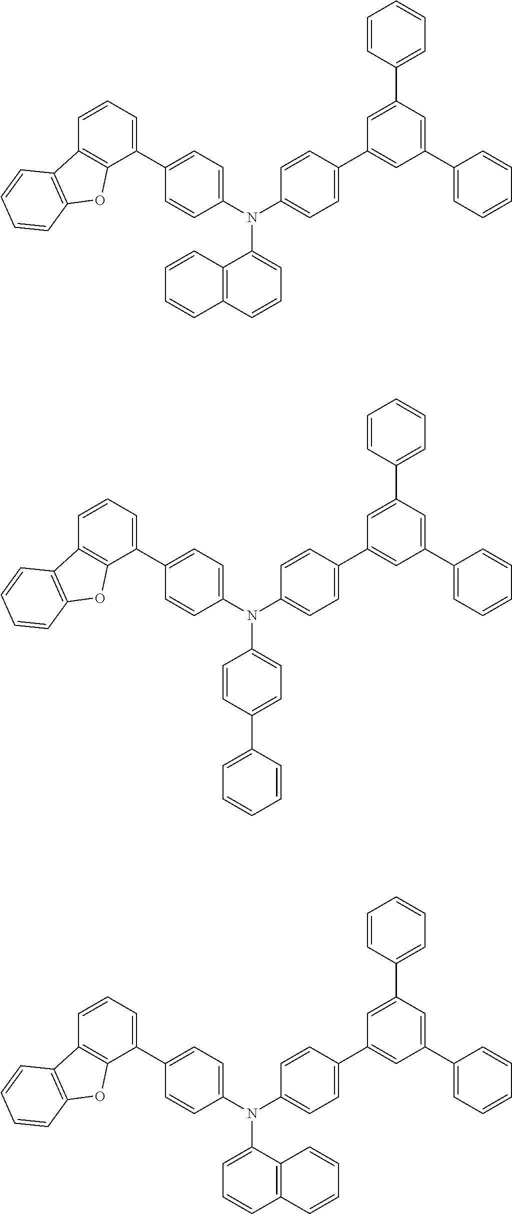 [SMILES: c1ccc(-c2cc(-c3ccccc3)cc(-c3ccc(N(c4ccc(-c5cccc6c5oc5ccccc56)cc4)c4cccc5ccccc45)cc3)c2)cc1 ; c1ccc(-c2ccc(N(c3ccc(-c4cc(-c5ccccc5)cc(-c5ccccc5)c4)cc3)c3ccc(-c4cccc5c4oc4ccccc45)cc3)cc2)cc1 ; c1ccc(-c2cc(-c3ccccc3)cc(-c3ccc(N(c4ccc(-c5cccc6c5oc5ccccc56)cc4)c4cccc5ccccc45)cc3)c2)cc1]

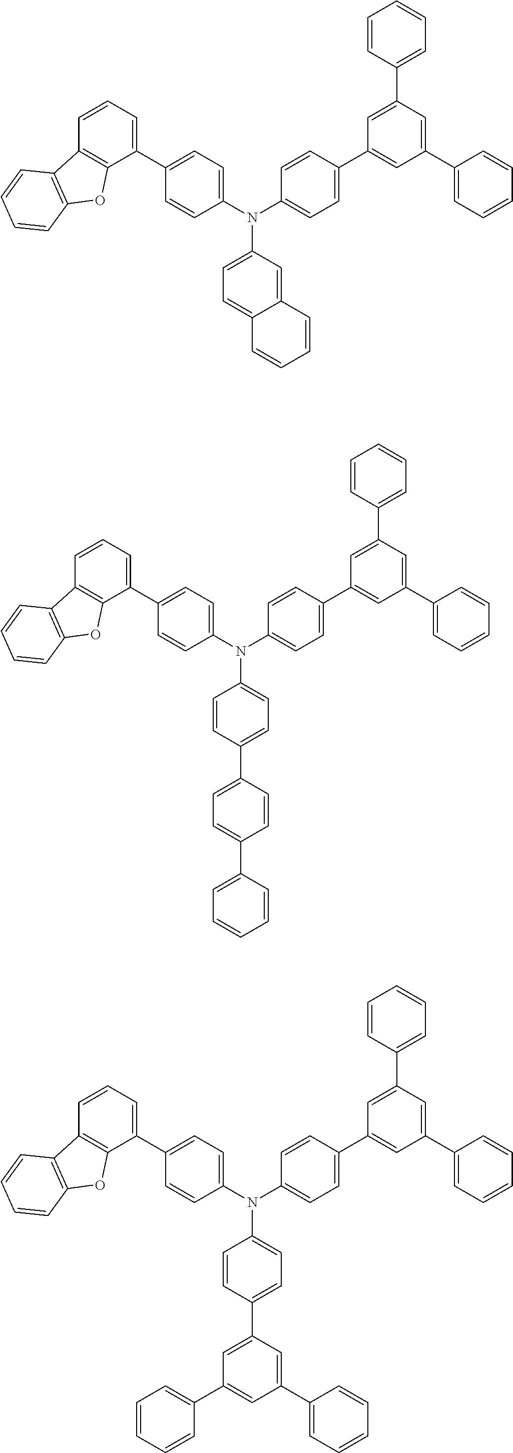 [SMILES: c1ccc(-c2cc(-c3ccccc3)cc(-c3ccc(N(c4ccc(-c5cccc6c5oc5ccccc56)cc4)c4ccc5ccccc5c4)cc3)c2)cc1 ; c1ccc(-c2ccc(-c3ccc(N(c4ccc(-c5cc(-c6ccccc6)cc(-c6ccccc6)c5)cc4)c4ccc(-c5cccc6c5oc5ccccc56)cc4)cc3)cc2)cc1 ; c1ccc(-c2cc(-c3ccccc3)cc(-c3ccc(N(c4ccc(-c5cc(-c6ccccc6)cc(-c6ccccc6)c5)cc4)c4ccc(-c5cccc6c5oc5ccccc56)cc4)cc3)c2)cc1]

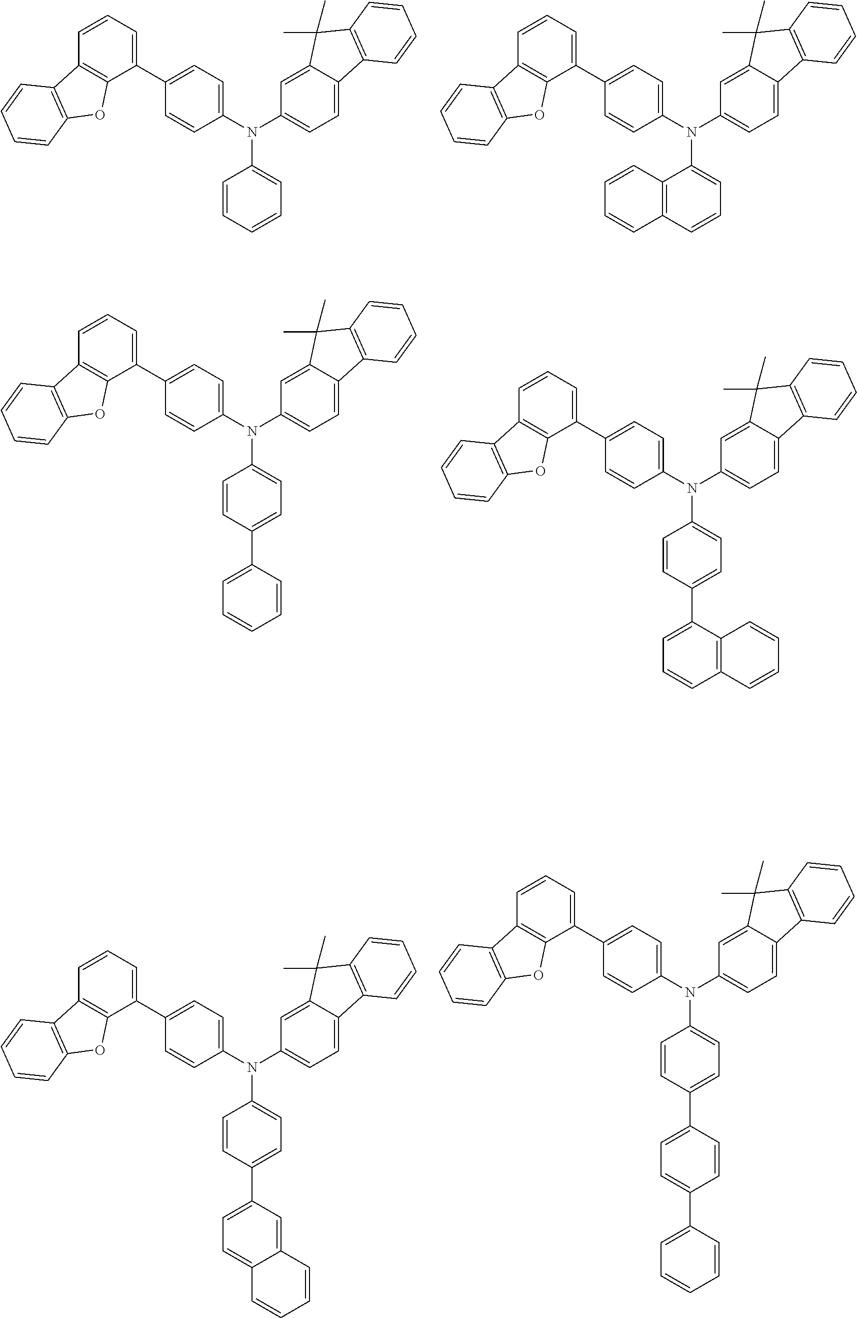

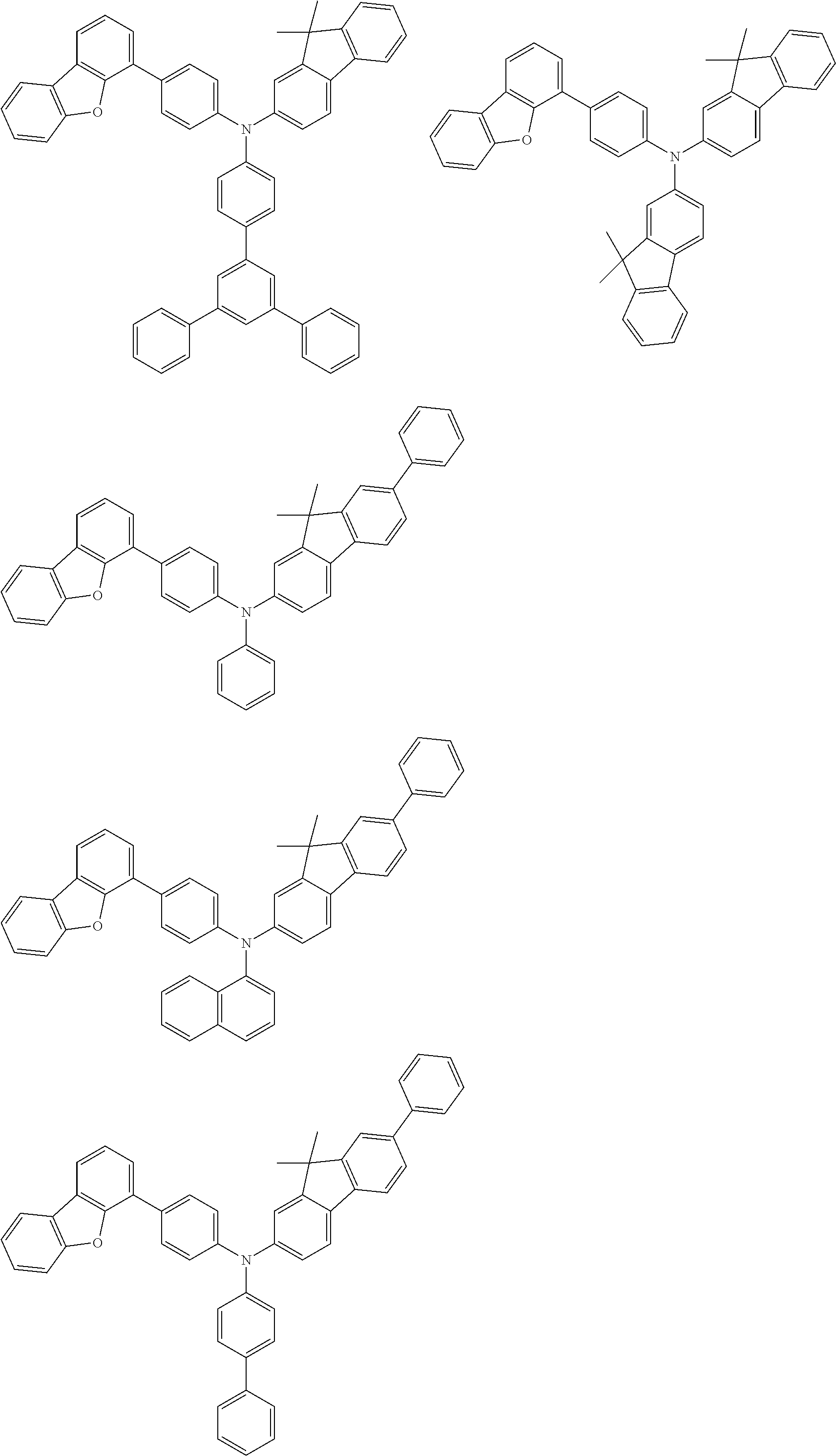 [SMILES: CC1(C)c2ccccc2-c2ccc(N(c3ccc(-c4cc(-c5ccccc5)cc(-c5ccccc5)c4)cc3)c3ccc(-c4cccc5c4oc4ccccc45)cc3)cc21 ; CC1(C)c2ccccc2-c2ccc(N(c3ccc(-c4cccc5c4oc4ccccc45)cc3)c3ccc4c(c3)C(C)(C)c3ccccc3-4)cc21 ; CC1(C)c2cc(-c3ccccc3)ccc2-c2ccc(N(c3ccccc3)c3ccc(-c4cccc5c4oc4ccccc45)cc3)cc21 ; CC1(C)c2cc(-c3ccccc3)ccc2-c2ccc(N(c3ccc(-c4cccc5c4oc4ccccc45)cc3)c3cccc4ccccc34)cc21 ; CC1(C)c2cc(-c3ccccc3)ccc2-c2ccc(N(c3ccc(-c4ccccc4)cc3)c3ccc(-c4cccc5c4oc4ccccc45)cc3)cc21]

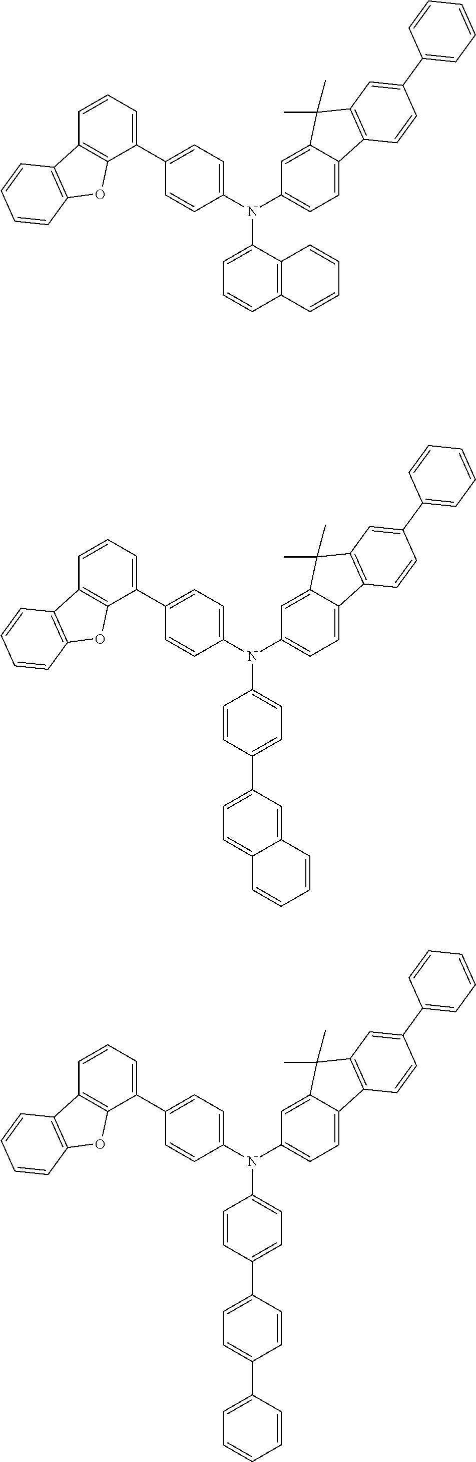 [SMILES: CC1(C)c2cc(-c3ccccc3)ccc2-c2ccc(N(c3ccc(-c4cccc5c4oc4ccccc45)cc3)c3cccc4ccccc34)cc21 ; CC1(C)c2cc(-c3ccccc3)ccc2-c2ccc(N(c3ccc(-c4ccc5ccccc5c4)cc3)c3ccc(-c4cccc5c4oc4ccccc45)cc3)cc21 ; CC1(C)c2cc(-c3ccccc3)ccc2-c2ccc(N(c3ccc(-c4ccc(-c5ccccc5)cc4)cc3)c3ccc(-c4cccc5c4oc4ccccc45)cc3)cc21]

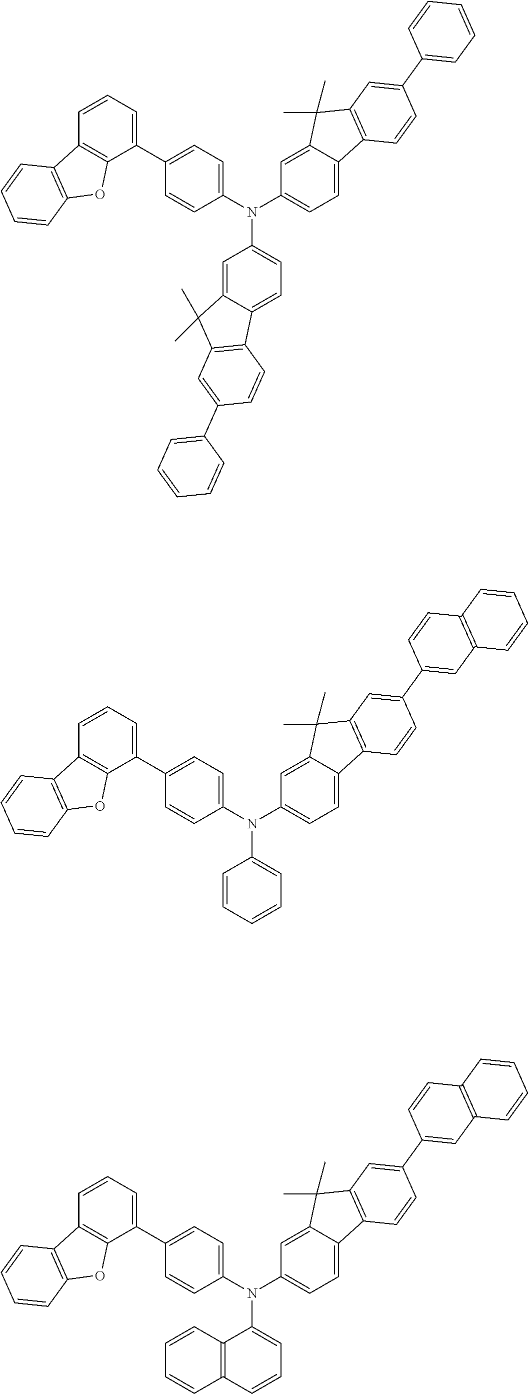 [SMILES: CC1(C)c2cc(-c3ccccc3)ccc2-c2ccc(N(c3ccc(-c4cccc5c4oc4ccccc45)cc3)c3ccc4c(c3)C(C)(C)c3cc(-c5ccccc5)ccc3-4)cc21 ; CC1(C)c2cc(-c3ccc4ccccc4c3)ccc2-c2ccc(N(c3ccccc3)c3ccc(-c4cccc5c4oc4ccccc45)cc3)cc21 ; CC1(C)c2cc(-c3ccc4ccccc4c3)ccc2-c2ccc(N(c3ccc(-c4cccc5c4oc4ccccc45)cc3)c3cccc4ccccc34)cc21]

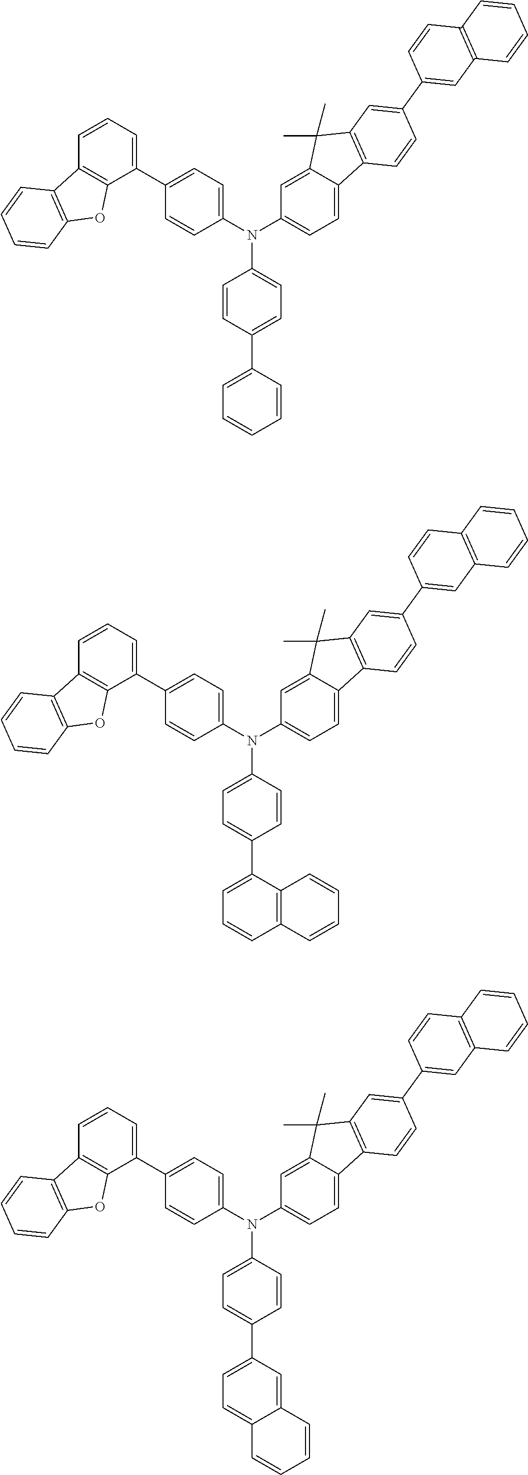 [SMILES: CC1(C)c2cc(-c3ccc4ccccc4c3)ccc2-c2ccc(N(c3ccc(-c4ccccc4)cc3)c3ccc(-c4cccc5c4oc4ccccc45)cc3)cc21 ; CC1(C)c2cc(-c3ccc4ccccc4c3)ccc2-c2ccc(N(c3ccc(-c4cccc5ccccc45)cc3)c3ccc(-c4cccc5c4oc4ccccc45)cc3)cc21 ; CC1(C)c2cc(-c3ccc4ccccc4c3)ccc2-c2ccc(N(c3ccc(-c4ccc5ccccc5c4)cc3)c3ccc(-c4cccc5c4oc4ccccc45)cc3)cc21]

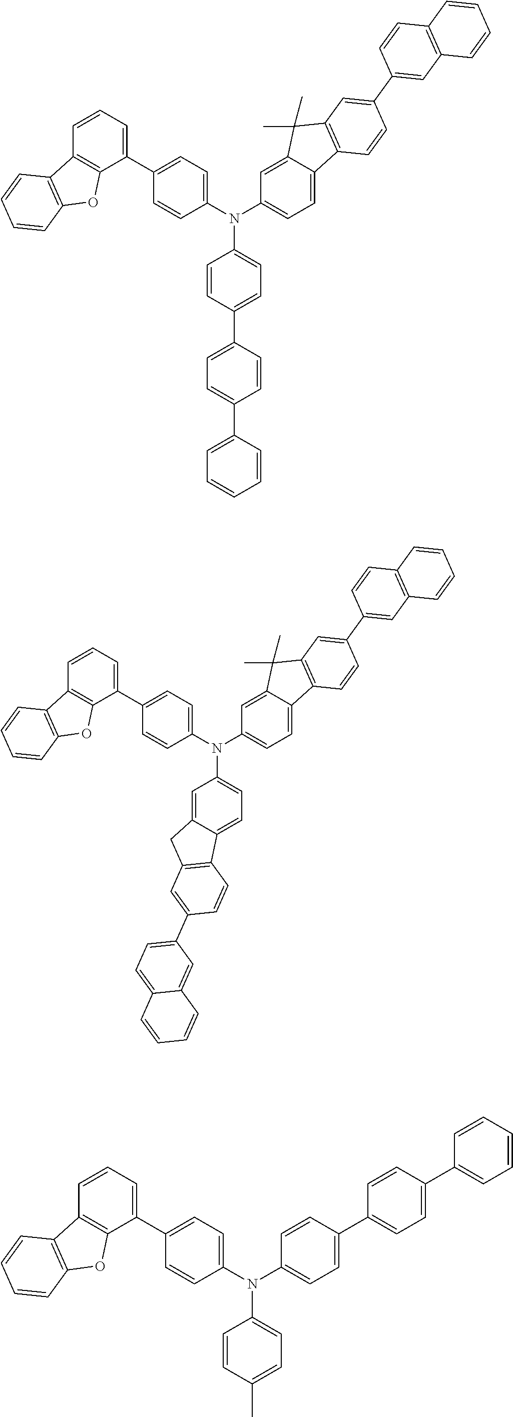 [SMILES: CC1(C)c2cc(-c3ccc4ccccc4c3)ccc2-c2ccc(N(c3ccc(-c4ccc(-c5ccccc5)cc4)cc3)c3ccc(-c4cccc5c4oc4ccccc45)cc3)cc21 ; CC1(C)c2cc(-c3ccc4ccccc4c3)ccc2-c2ccc(N(c3ccc(-c4cccc5c4oc4ccccc45)cc3)c3ccc4c(c3)Cc3cc(-c5ccc6ccccc6c5)ccc3-4)cc21 ; Cc1ccc(N(c2ccc(-c3ccc(-c4ccccc4)cc3)cc2)c2ccc(-c3cccc4c3oc3ccccc34)cc2)cc1]

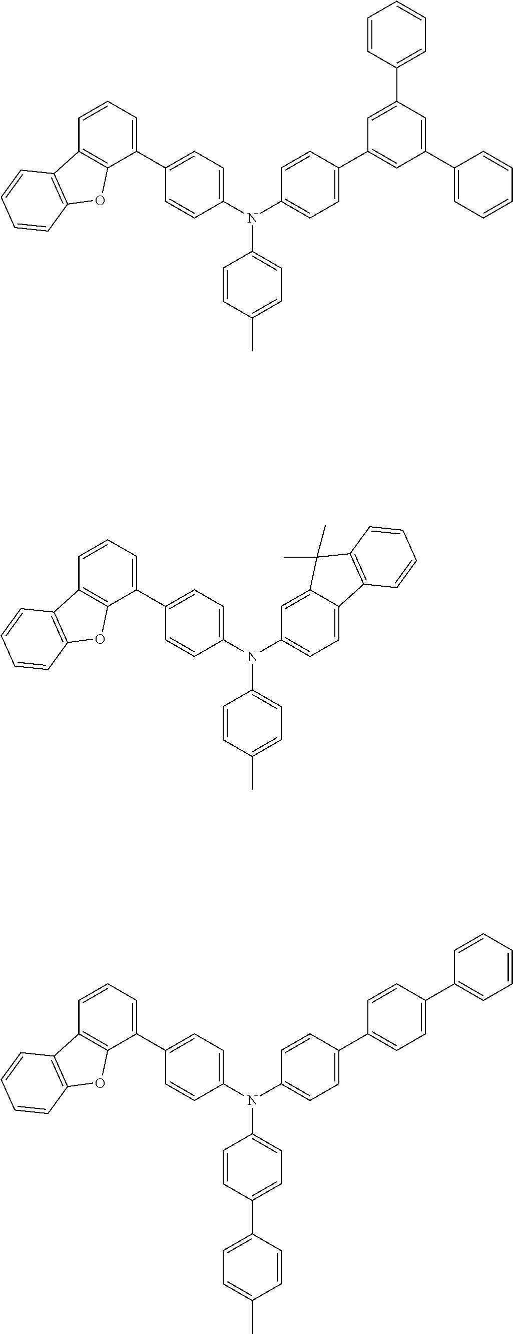 [SMILES: Cc1ccc(N(c2ccc(-c3cc(-c4ccccc4)cc(-c4ccccc4)c3)cc2)c2ccc(-c3cccc4c3oc3ccccc34)cc2)cc1 ; Cc1ccc(N(c2ccc(-c3cccc4c3oc3ccccc34)cc2)c2ccc3c(c2)C(C)(C)c2ccccc2-3)cc1 ; Cc1ccc(-c2ccc(N(c3ccc(-c4ccc(-c5ccccc5)cc4)cc3)c3ccc(-c4cccc5c4oc4ccccc45)cc3)cc2)cc1]

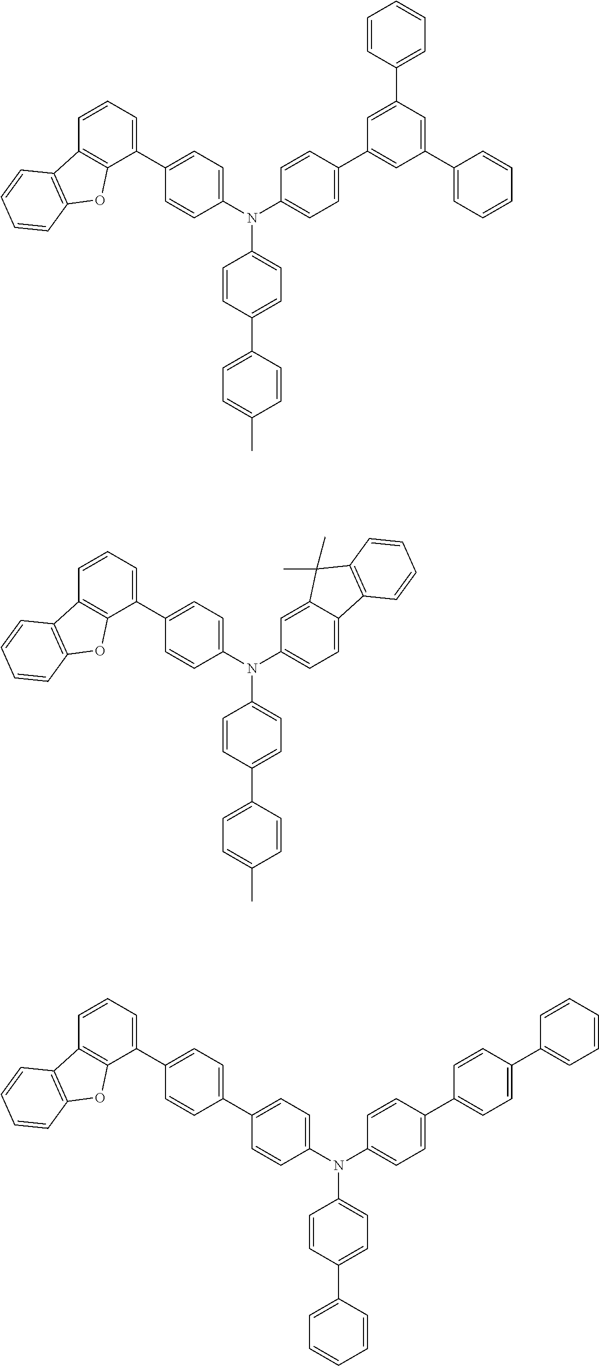 [SMILES: Cc1ccc(-c2ccc(N(c3ccc(-c4cc(-c5ccccc5)cc(-c5ccccc5)c4)cc3)c3ccc(-c4cccc5c4oc4ccccc45)cc3)cc2)cc1 ; Cc1ccc(-c2ccc(N(c3ccc(-c4cccc5c4oc4ccccc45)cc3)c3ccc4c(c3)C(C)(C)c3ccccc3-4)cc2)cc1 ; c1ccc(-c2ccc(-c3ccc(N(c4ccc(-c5ccccc5)cc4)c4ccc(-c5ccc(-c6cccc7c6oc6ccccc67)cc5)cc4)cc3)cc2)cc1]

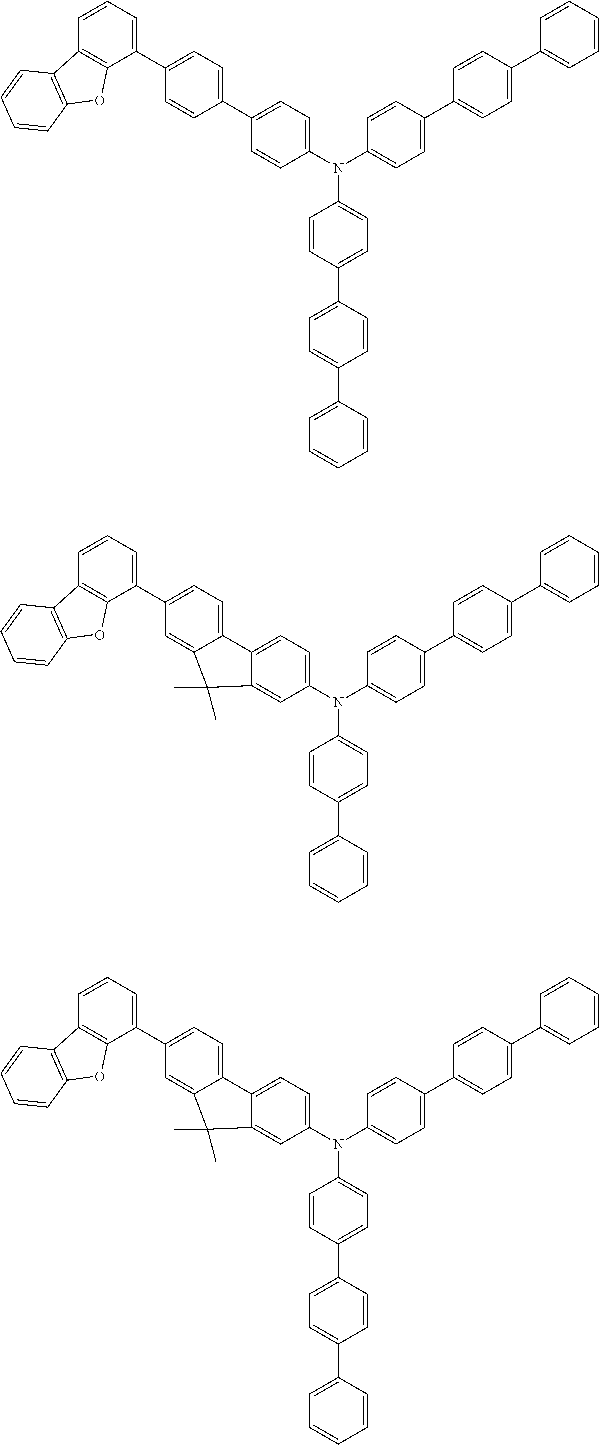 [SMILES: c1ccc(-c2ccc(-c3ccc(N(c4ccc(-c5ccc(-c6ccccc6)cc5)cc4)c4ccc(-c5ccc(-c6cccc7c6oc6ccccc67)cc5)cc4)cc3)cc2)cc1 ; CC1(C)c2cc(-c3cccc4c3oc3ccccc34)ccc2-c2ccc(N(c3ccc(-c4ccccc4)cc3)c3ccc(-c4ccc(-c5ccccc5)cc4)cc3)cc21 ; CC1(C)c2cc(-c3cccc4c3oc3ccccc34)ccc2-c2ccc(N(c3ccc(-c4ccc(-c5ccccc5)cc4)cc3)c3ccc(-c4ccc(-c5ccccc5)cc4)cc3)cc21]

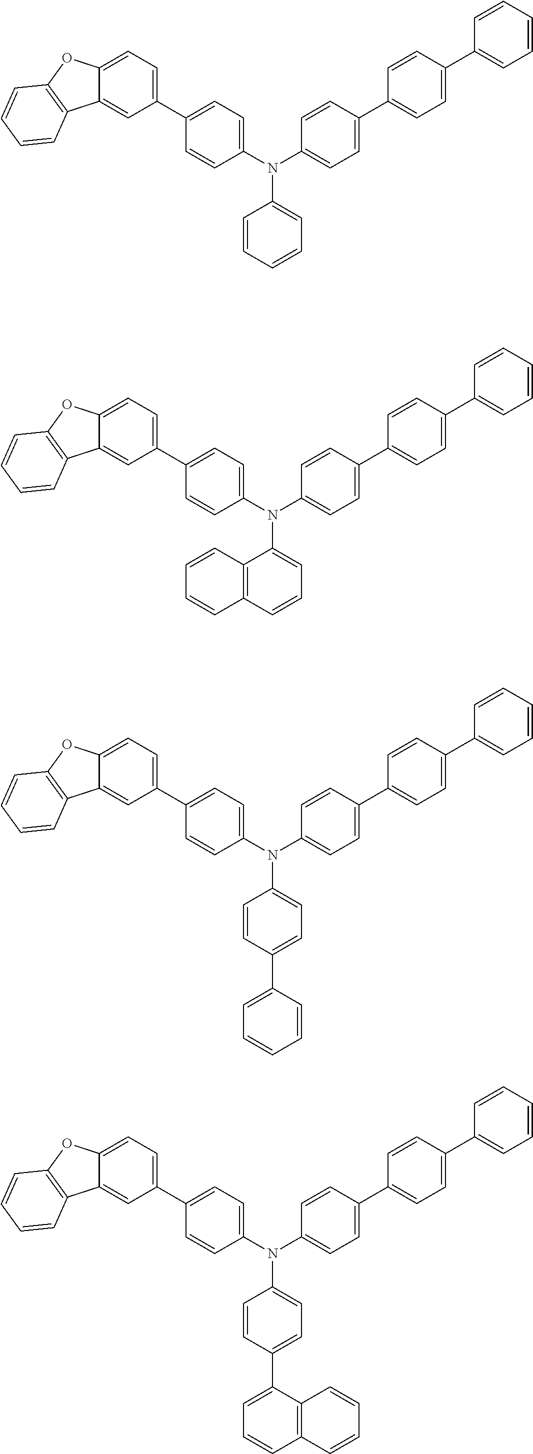 [SMILES: c1ccc(-c2ccc(-c3ccc(N(c4ccccc4)c4ccc(-c5ccc6oc7ccccc7c6c5)cc4)cc3)cc2)cc1 ; c1ccc(-c2ccc(-c3ccc(N(c4ccc(-c5ccc6oc7ccccc7c6c5)cc4)c4cccc5ccccc45)cc3)cc2)cc1 ; c1ccc(-c2ccc(-c3ccc(N(c4ccc(-c5ccccc5)cc4)c4ccc(-c5ccc6oc7ccccc7c6c5)cc4)cc3)cc2)cc1 ; c1ccc(-c2ccc(-c3ccc(N(c4ccc(-c5ccc6oc7ccccc7c6c5)cc4)c4ccc(-c5cccc6ccccc56)cc4)cc3)cc2)cc1]

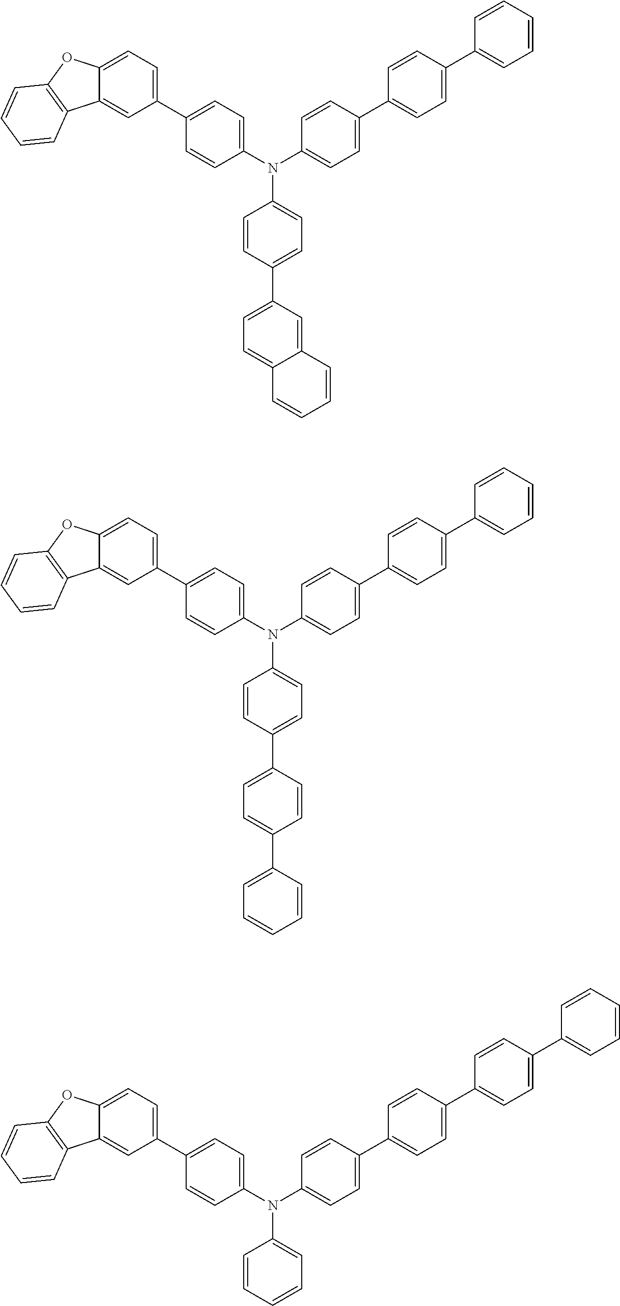 [SMILES: c1ccc(-c2ccc(-c3ccc(N(c4ccc(-c5ccc6ccccc6c5)cc4)c4ccc(-c5ccc6oc7ccccc7c6c5)cc4)cc3)cc2)cc1 ; c1ccc(-c2ccc(-c3ccc(N(c4ccc(-c5ccc(-c6ccccc6)cc5)cc4)c4ccc(-c5ccc6oc7ccccc7c6c5)cc4)cc3)cc2)cc1 ; c1ccc(-c2ccc(-c3ccc(-c4ccc(N(c5ccccc5)c5ccc(-c6ccc7oc8ccccc8c7c6)cc5)cc4)cc3)cc2)cc1]

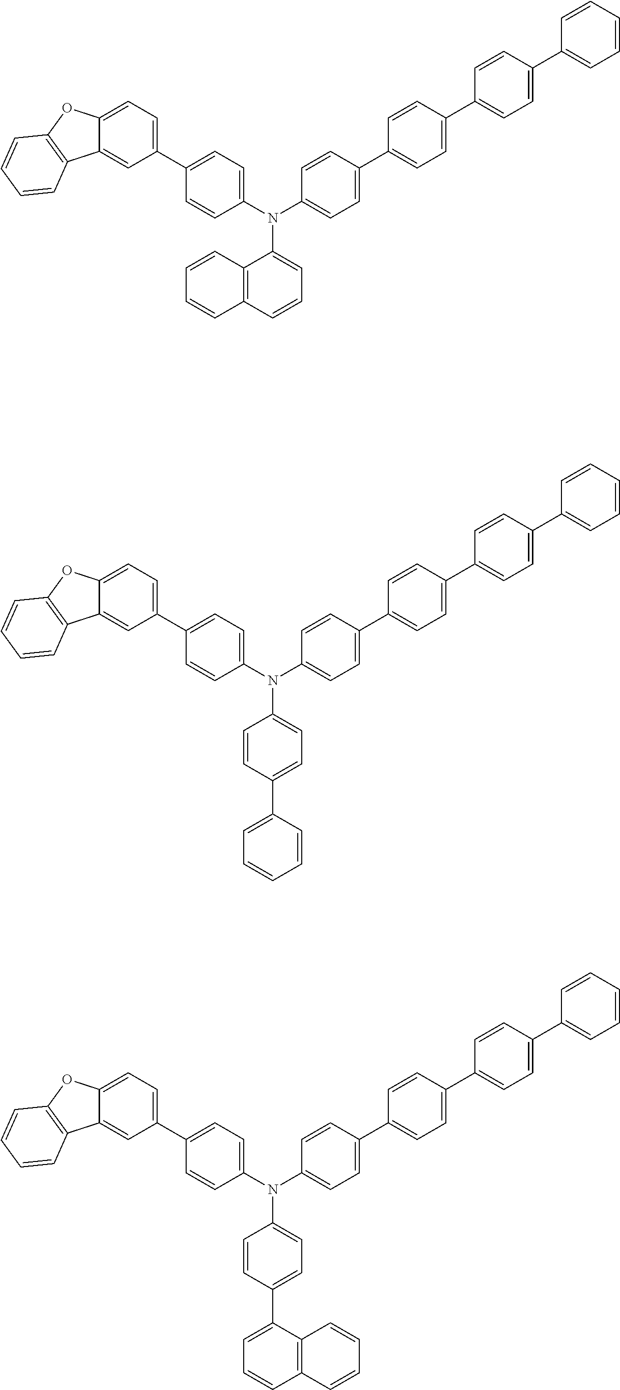 [SMILES: c1ccc(-c2ccc(-c3ccc(-c4ccc(N(c5ccc(-c6ccc7oc8ccccc8c7c6)cc5)c5cccc6ccccc56)cc4)cc3)cc2)cc1 ; c1ccc(-c2ccc(-c3ccc(-c4ccc(N(c5ccc(-c6ccccc6)cc5)c5ccc(-c6ccc7oc8ccccc8c7c6)cc5)cc4)cc3)cc2)cc1 ; c1ccc(-c2ccc(-c3ccc(-c4ccc(N(c5ccc(-c6ccc7oc8ccccc8c7c6)cc5)c5ccc(-c6cccc7ccccc67)cc5)cc4)cc3)cc2)cc1]

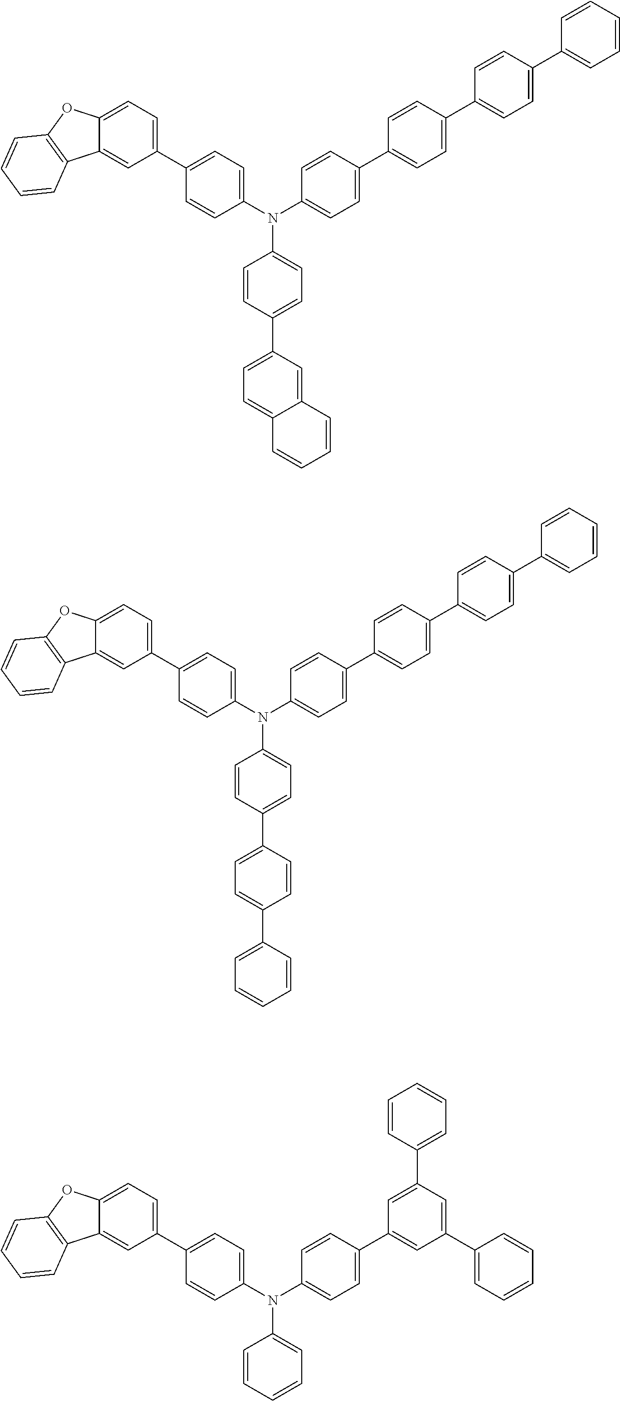 [SMILES: c1ccc(-c2ccc(-c3ccc(-c4ccc(N(c5ccc(-c6ccc7ccccc7c6)cc5)c5ccc(-c6ccc7oc8ccccc8c7c6)cc5)cc4)cc3)cc2)cc1 ; c1ccc(-c2ccc(-c3ccc(-c4ccc(N(c5ccc(-c6ccc(-c7ccccc7)cc6)cc5)c5ccc(-c6ccc7oc8ccccc8c7c6)cc5)cc4)cc3)cc2)cc1 ; c1ccc(-c2cc(-c3ccccc3)cc(-c3ccc(N(c4ccccc4)c4ccc(-c5ccc6oc7ccccc7c6c5)cc4)cc3)c2)cc1]

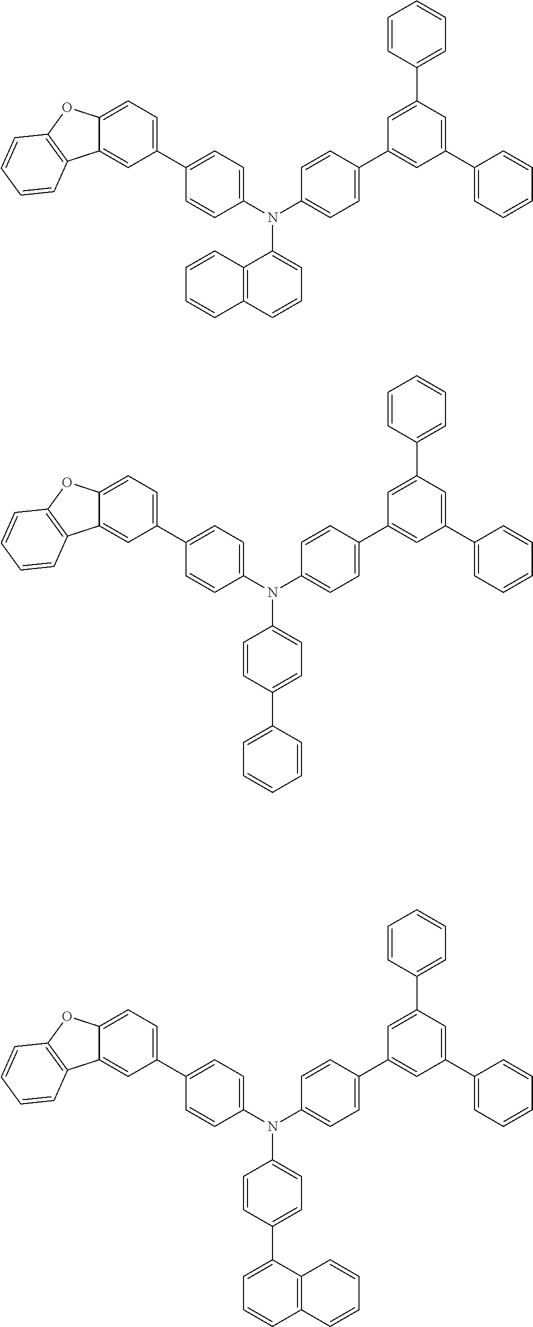 [SMILES: c1ccc(-c2cc(-c3ccccc3)cc(-c3ccc(N(c4ccc(-c5ccc6oc7ccccc7c6c5)cc4)c4cccc5ccccc45)cc3)c2)cc1 ; c1ccc(-c2ccc(N(c3ccc(-c4cc(-c5ccccc5)cc(-c5ccccc5)c4)cc3)c3ccc(-c4ccc5oc6ccccc6c5c4)cc3)cc2)cc1 ; c1ccc(-c2cc(-c3ccccc3)cc(-c3ccc(N(c4ccc(-c5ccc6oc7ccccc7c6c5)cc4)c4ccc(-c5cccc6ccccc56)cc4)cc3)c2)cc1]

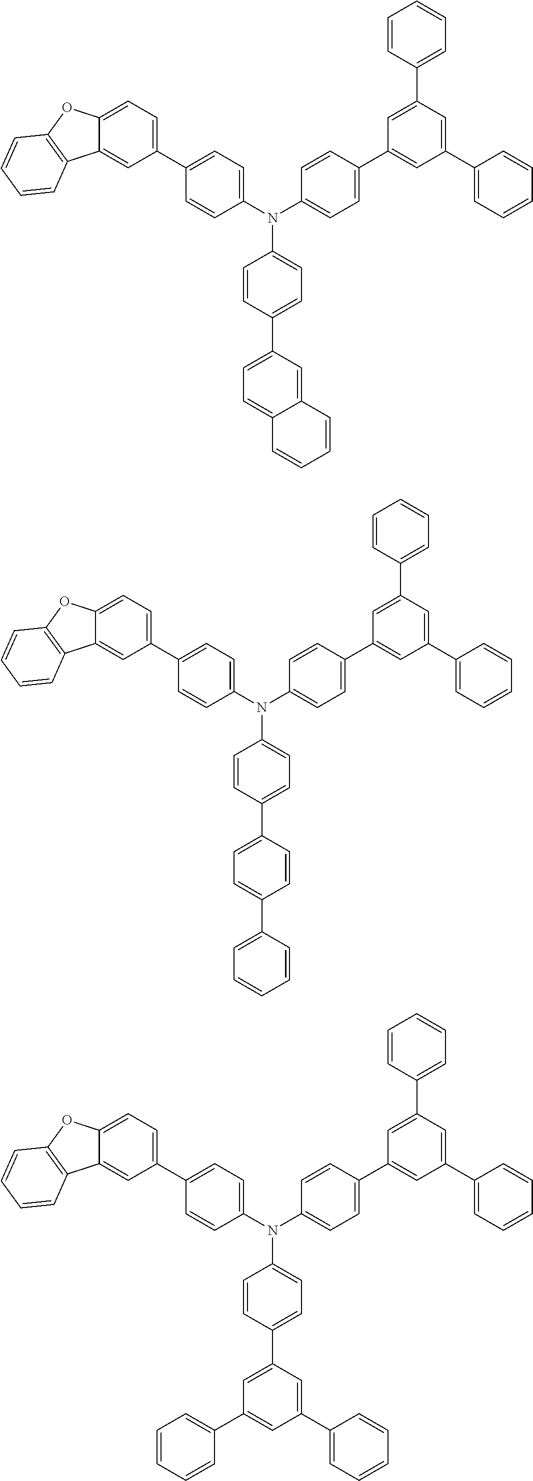 [SMILES: c1ccc(-c2cc(-c3ccccc3)cc(-c3ccc(N(c4ccc(-c5ccc6ccccc6c5)cc4)c4ccc(-c5ccc6oc7ccccc7c6c5)cc4)cc3)c2)cc1 ; c1ccc(-c2ccc(-c3ccc(N(c4ccc(-c5cc(-c6ccccc6)cc(-c6ccccc6)c5)cc4)c4ccc(-c5ccc6oc7ccccc7c6c5)cc4)cc3)cc2)cc1 ; c1ccc(-c2cc(-c3ccccc3)cc(-c3ccc(N(c4ccc(-c5cc(-c6ccccc6)cc(-c6ccccc6)c5)cc4)c4ccc(-c5ccc6oc7ccccc7c6c5)cc4)cc3)c2)cc1]

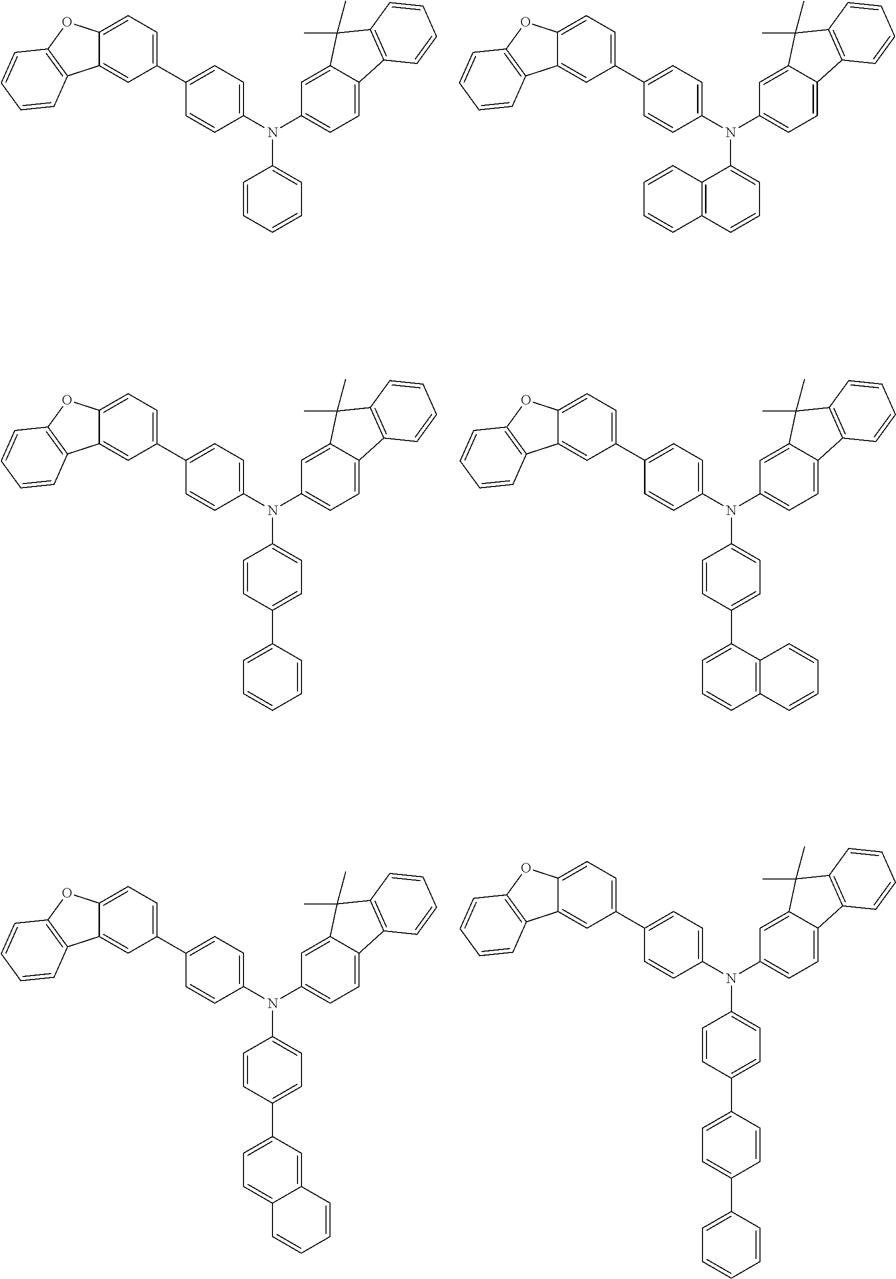

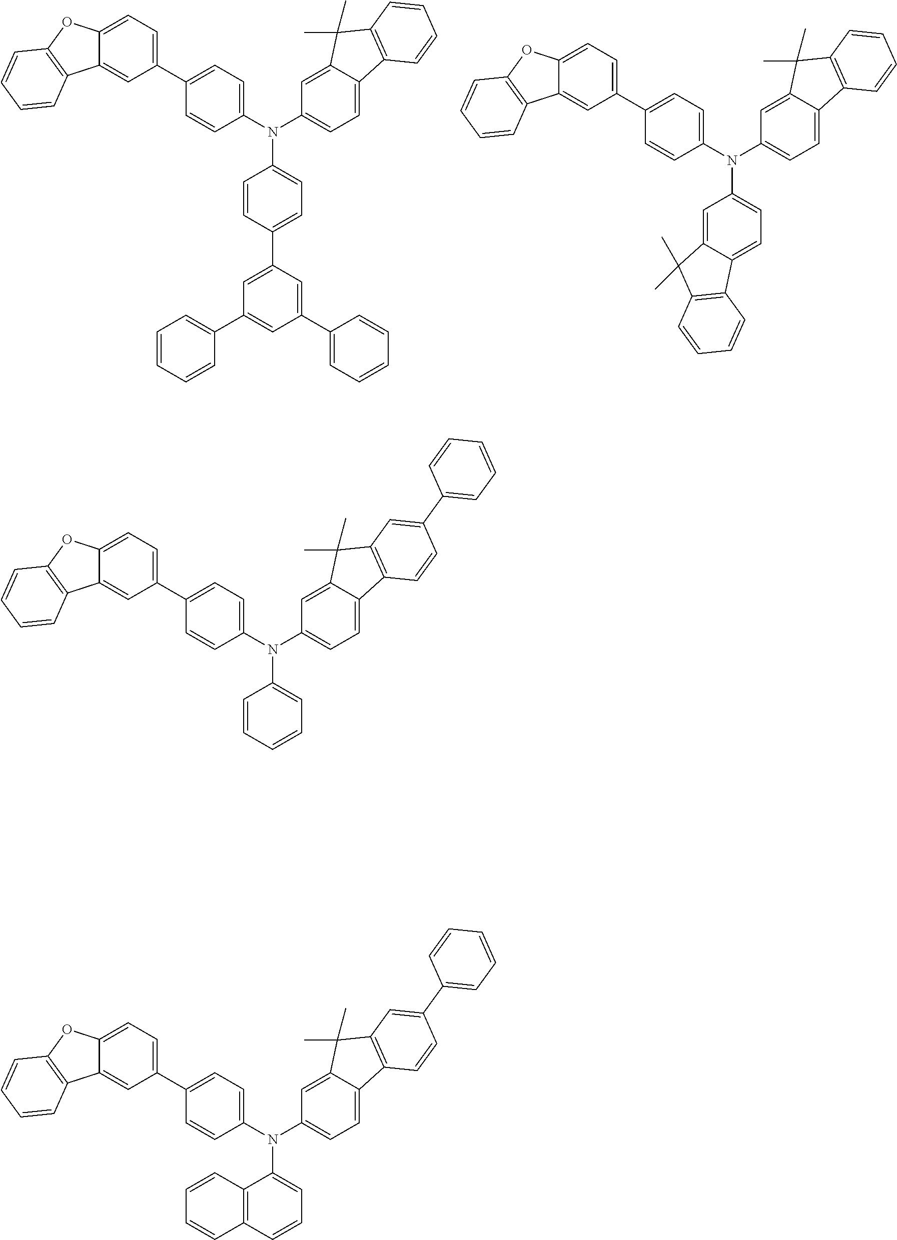 [SMILES: CC1(C)c2ccccc2-c2ccc(N(c3ccc(-c4cc(-c5ccccc5)cc(-c5ccccc5)c4)cc3)c3ccc(-c4ccc5oc6ccccc6c5c4)cc3)cc21 ; CC1(C)c2ccccc2-c2ccc(N(c3ccc(-c4ccc5oc6ccccc6c5c4)cc3)c3ccc4c(c3)C(C)(C)c3ccccc3-4)cc21 ; CC1(C)c2cc(-c3ccccc3)ccc2-c2ccc(N(c3ccccc3)c3ccc(-c4ccc5oc6ccccc6c5c4)cc3)cc21 ; CC1(C)c2cc(-c3ccccc3)ccc2-c2ccc(N(c3ccc(-c4ccc5oc6ccccc6c5c4)cc3)c3cccc4ccccc34)cc21]

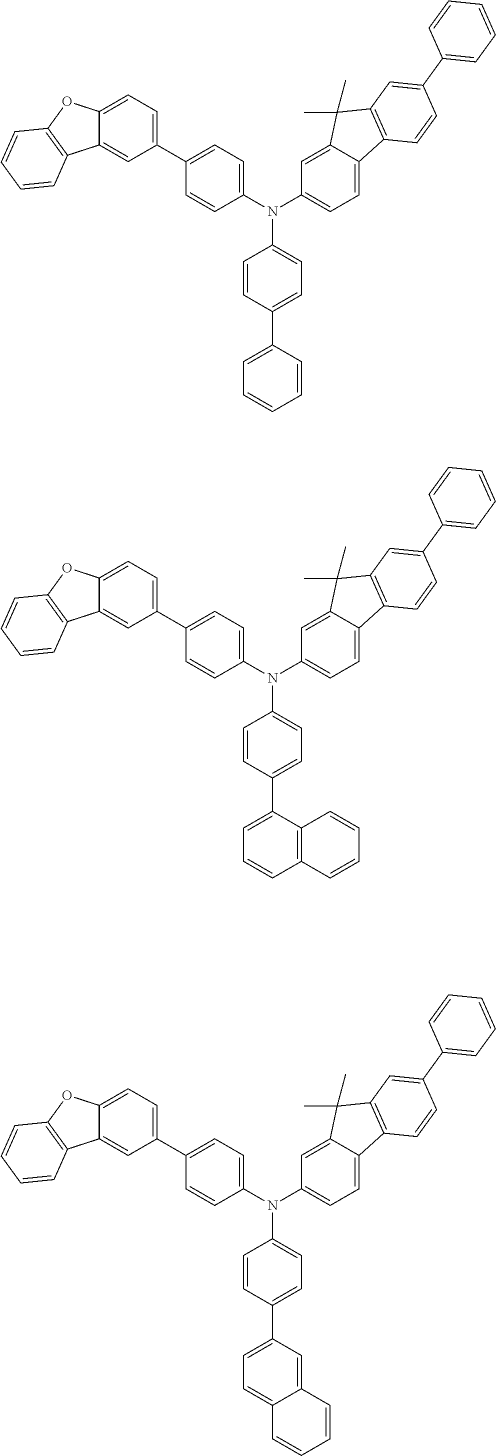 [SMILES: CC1(C)c2cc(-c3ccccc3)ccc2-c2ccc(N(c3ccc(-c4ccccc4)cc3)c3ccc(-c4ccc5oc6ccccc6c5c4)cc3)cc21 ; CC1(C)c2cc(-c3ccccc3)ccc2-c2ccc(N(c3ccc(-c4ccc5oc6ccccc6c5c4)cc3)c3ccc(-c4cccc5ccccc45)cc3)cc21 ; CC1(C)c2cc(-c3ccccc3)ccc2-c2ccc(N(c3ccc(-c4ccc5ccccc5c4)cc3)c3ccc(-c4ccc5oc6ccccc6c5c4)cc3)cc21]

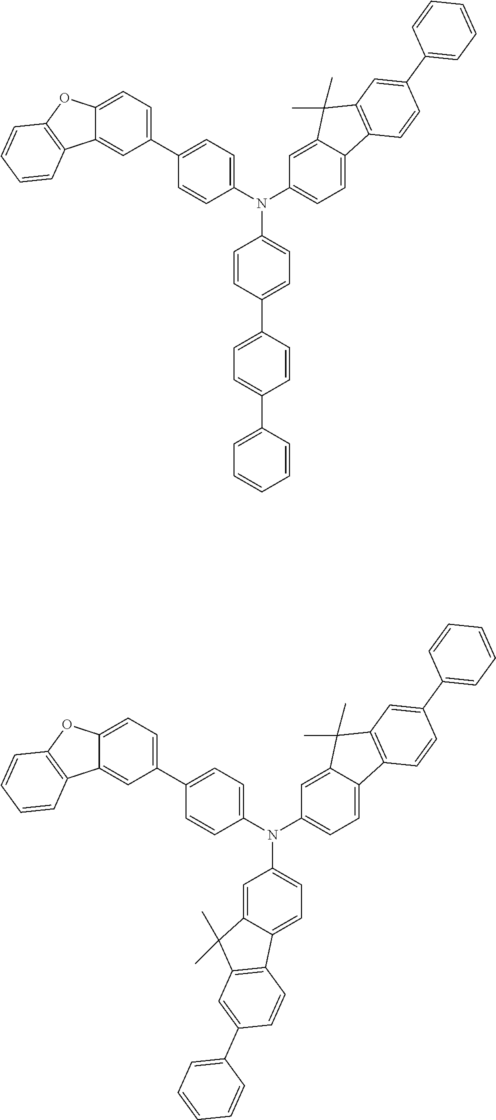 [SMILES: CC1(C)c2cc(-c3ccccc3)ccc2-c2ccc(N(c3ccc(-c4ccc(-c5ccccc5)cc4)cc3)c3ccc(-c4ccc5oc6ccccc6c5c4)cc3)cc21 ; CC1(C)c2cc(-c3ccccc3)ccc2-c2ccc(N(c3ccc(-c4ccc5oc6ccccc6c5c4)cc3)c3ccc4c(c3)C(C)(C)c3cc(-c5ccccc5)ccc3-4)cc21]

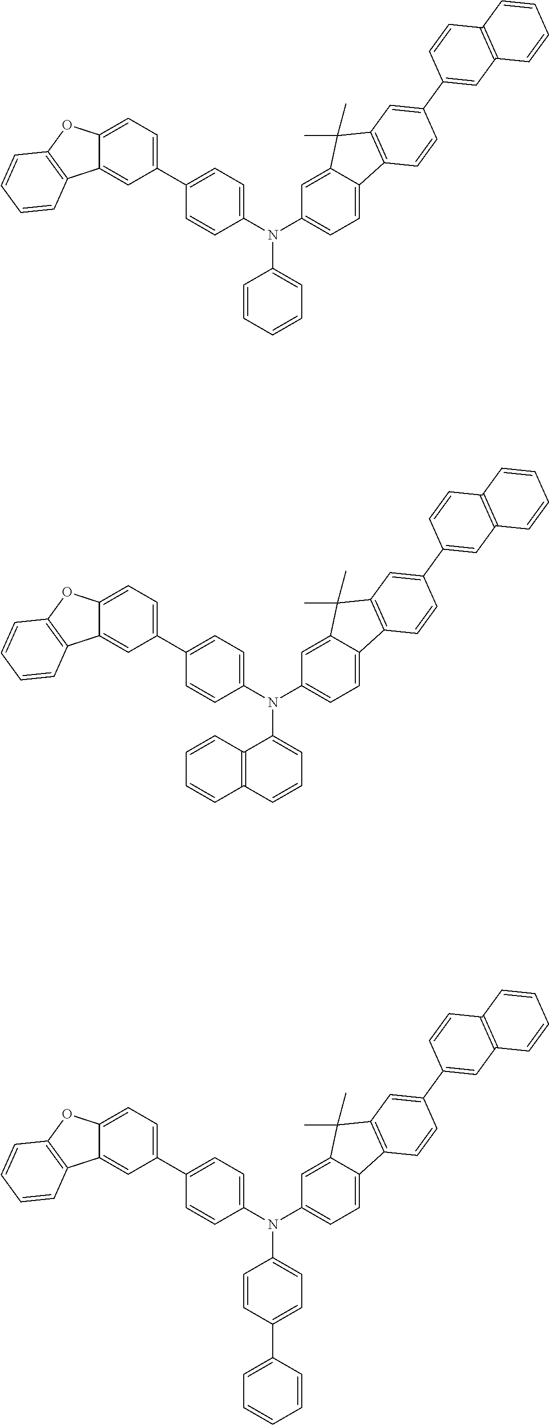 [SMILES: CC1(C)c2cc(-c3ccc4ccccc4c3)ccc2-c2ccc(N(c3ccccc3)c3ccc(-c4ccc5oc6ccccc6c5c4)cc3)cc21 ; CC1(C)c2cc(-c3ccc4ccccc4c3)ccc2-c2ccc(N(c3ccc(-c4ccc5oc6ccccc6c5c4)cc3)c3cccc4ccccc34)cc21 ; CC1(C)c2cc(-c3ccc4ccccc4c3)ccc2-c2ccc(N(c3ccc(-c4ccccc4)cc3)c3ccc(-c4ccc5oc6ccccc6c5c4)cc3)cc21]

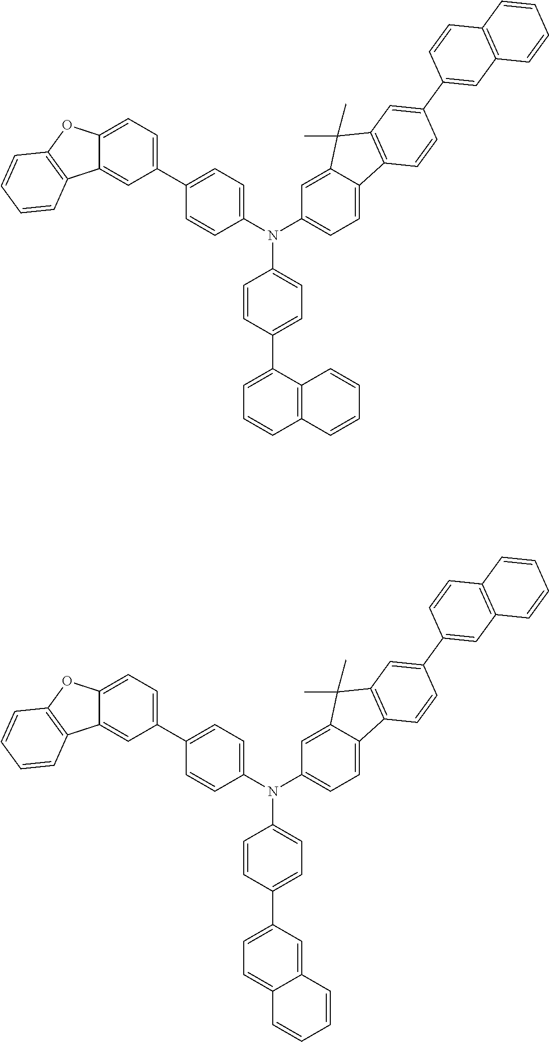 [SMILES: CC1(C)c2cc(-c3ccc4ccccc4c3)ccc2-c2ccc(N(c3ccc(-c4ccc5oc6ccccc6c5c4)cc3)c3ccc(-c4cccc5ccccc45)cc3)cc21 ; CC1(C)c2cc(-c3ccc4ccccc4c3)ccc2-c2ccc(N(c3ccc(-c4ccc5ccccc5c4)cc3)c3ccc(-c4ccc5oc6ccccc6c5c4)cc3)cc21]

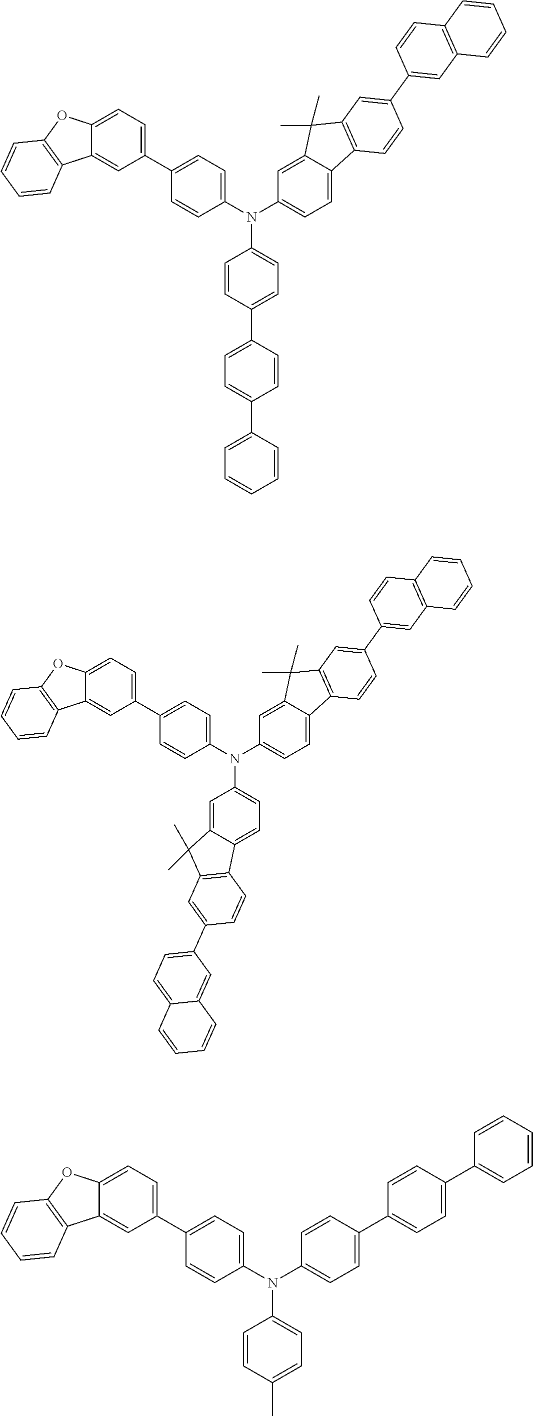 [SMILES: CC1(C)c2cc(-c3ccc4ccccc4c3)ccc2-c2ccc(N(c3ccc(-c4ccc(-c5ccccc5)cc4)cc3)c3ccc(-c4ccc5oc6ccccc6c5c4)cc3)cc21 ; CC1(C)c2cc(-c3ccc4ccccc4c3)ccc2-c2ccc(N(c3ccc(-c4ccc5oc6ccccc6c5c4)cc3)c3ccc4c(c3)C(C)(C)c3cc(-c5ccc6ccccc6c5)ccc3-4)cc21 ; Cc1ccc(N(c2ccc(-c3ccc(-c4ccccc4)cc3)cc2)c2ccc(-c3ccc4oc5ccccc5c4c3)cc2)cc1]

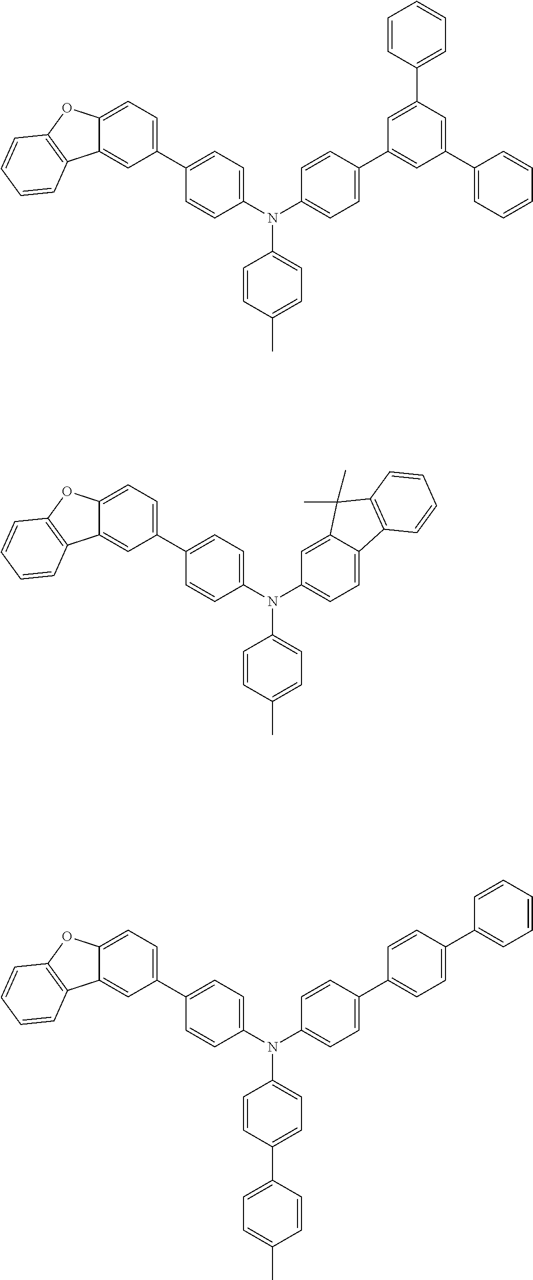 [SMILES: Cc1ccc(N(c2ccc(-c3cc(-c4ccccc4)cc(-c4ccccc4)c3)cc2)c2ccc(-c3ccc4oc5ccccc5c4c3)cc2)cc1 ; Cc1ccc(N(c2ccc(-c3ccc4oc5ccccc5c4c3)cc2)c2ccc3c(c2)C(C)(C)c2ccccc2-3)cc1 ; Cc1ccc(-c2ccc(N(c3ccc(-c4ccc(-c5ccccc5)cc4)cc3)c3ccc(-c4ccc5oc6ccccc6c5c4)cc3)cc2)cc1]

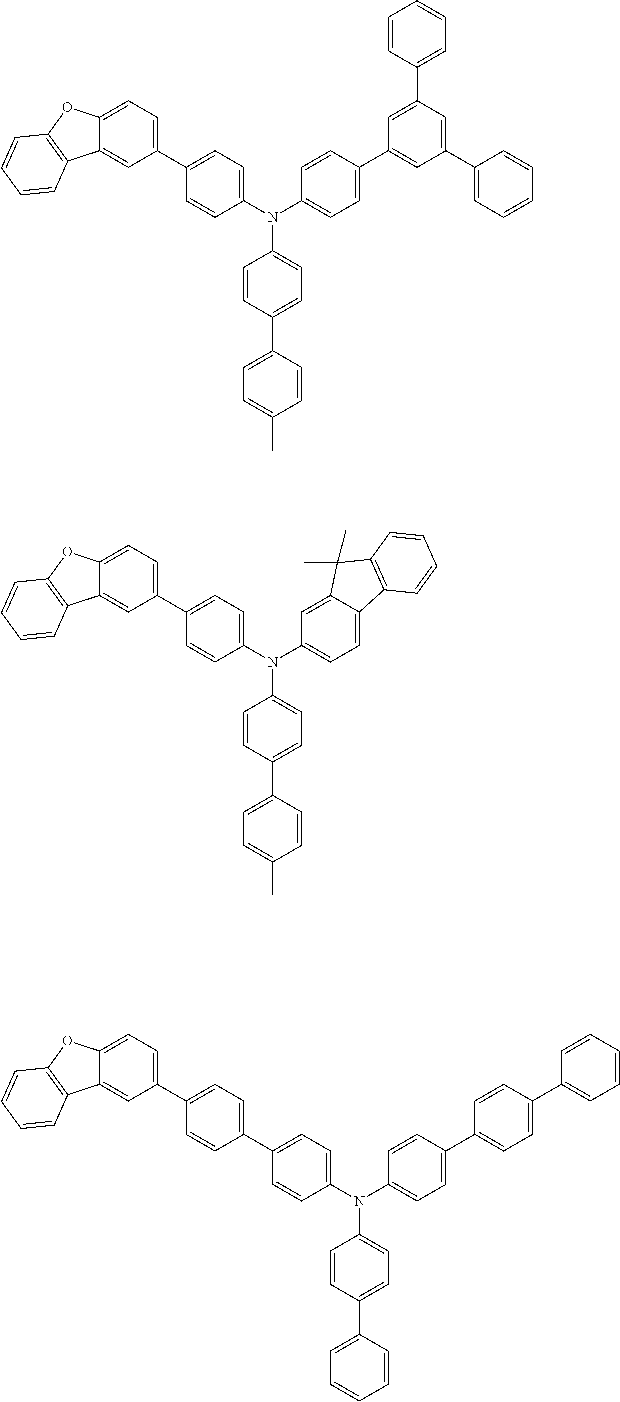 [SMILES: Cc1ccc(-c2ccc(N(c3ccc(-c4cc(-c5ccccc5)cc(-c5ccccc5)c4)cc3)c3ccc(-c4ccc5oc6ccccc6c5c4)cc3)cc2)cc1 ; Cc1ccc(-c2ccc(N(c3ccc(-c4ccc5oc6ccccc6c5c4)cc3)c3ccc4c(c3)C(C)(C)c3ccccc3-4)cc2)cc1 ; c1ccc(-c2ccc(-c3ccc(N(c4ccc(-c5ccccc5)cc4)c4ccc(-c5ccc(-c6ccc7oc8ccccc8c7c6)cc5)cc4)cc3)cc2)cc1]

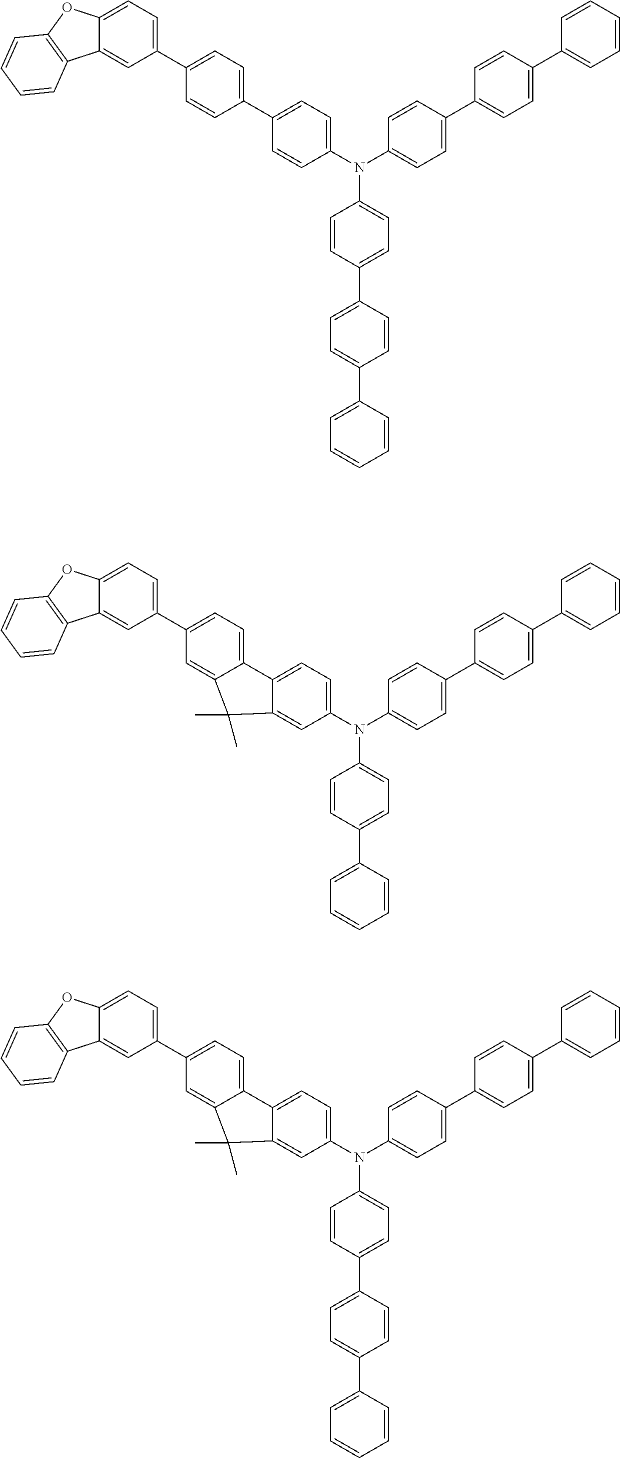 [SMILES: c1ccc(-c2ccc(-c3ccc(N(c4ccc(-c5ccc(-c6ccccc6)cc5)cc4)c4ccc(-c5ccc(-c6ccc7oc8ccccc8c7c6)cc5)cc4)cc3)cc2)cc1 ; CC1(C)c2cc(-c3ccc4oc5ccccc5c4c3)ccc2-c2ccc(N(c3ccc(-c4ccccc4)cc3)c3ccc(-c4ccc(-c5ccccc5)cc4)cc3)cc21 ; CC1(C)c2cc(-c3ccc4oc5ccccc5c4c3)ccc2-c2ccc(N(c3ccc(-c4ccc(-c5ccccc5)cc4)cc3)c3ccc(-c4ccc(-c5ccccc5)cc4)cc3)cc21]

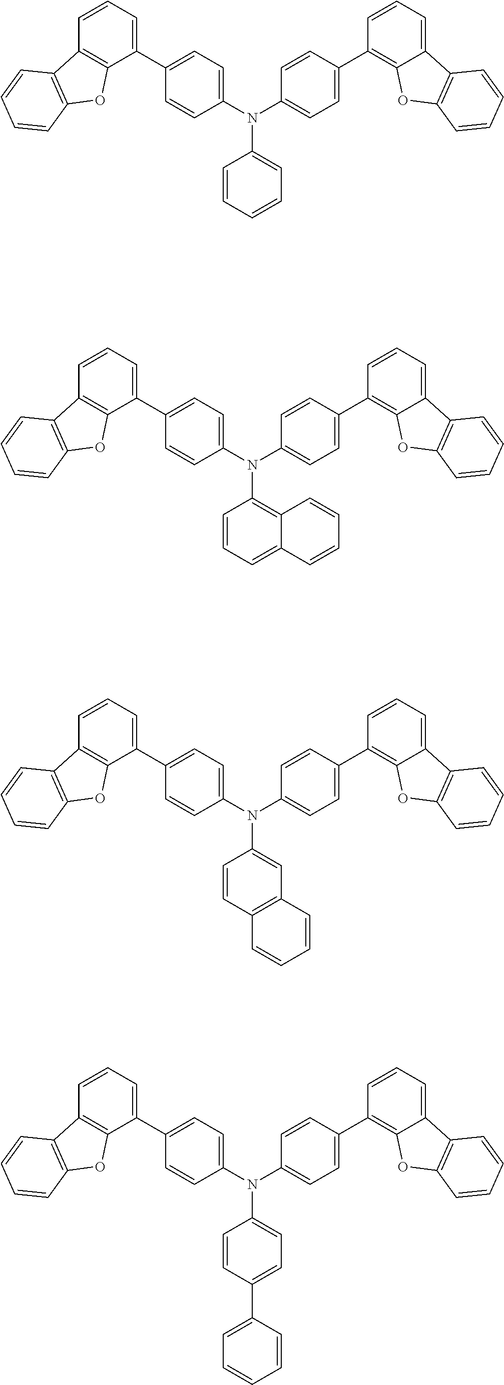 [SMILES: c1ccc(N(c2ccc(-c3cccc4c3oc3ccccc34)cc2)c2ccc(-c3cccc4c3oc3ccccc34)cc2)cc1 ; c1ccc2c(N(c3ccc(-c4cccc5c4oc4ccccc45)cc3)c3ccc(-c4cccc5c4oc4ccccc45)cc3)cccc2c1 ; c1ccc2cc(N(c3ccc(-c4cccc5c4oc4ccccc45)cc3)c3ccc(-c4cccc5c4oc4ccccc45)cc3)ccc2c1 ; c1ccc(-c2ccc(N(c3ccc(-c4cccc5c4oc4ccccc45)cc3)c3ccc(-c4cccc5c4oc4ccccc45)cc3)cc2)cc1]

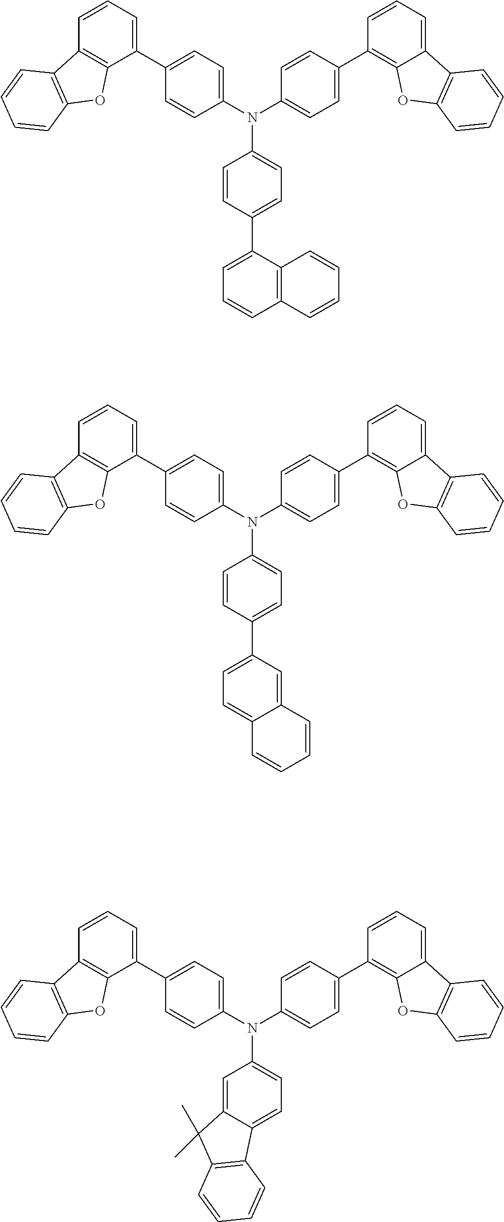 [SMILES: c1ccc2c(-c3ccc(N(c4ccc(-c5cccc6c5oc5ccccc56)cc4)c4ccc(-c5cccc6c5oc5ccccc56)cc4)cc3)cccc2c1 ; c1ccc2cc(-c3ccc(N(c4ccc(-c5cccc6c5oc5ccccc56)cc4)c4ccc(-c5cccc6c5oc5ccccc56)cc4)cc3)ccc2c1 ; CC1(C)c2ccccc2-c2ccc(N(c3ccc(-c4cccc5c4oc4ccccc45)cc3)c3ccc(-c4cccc5c4oc4ccccc45)cc3)cc21]

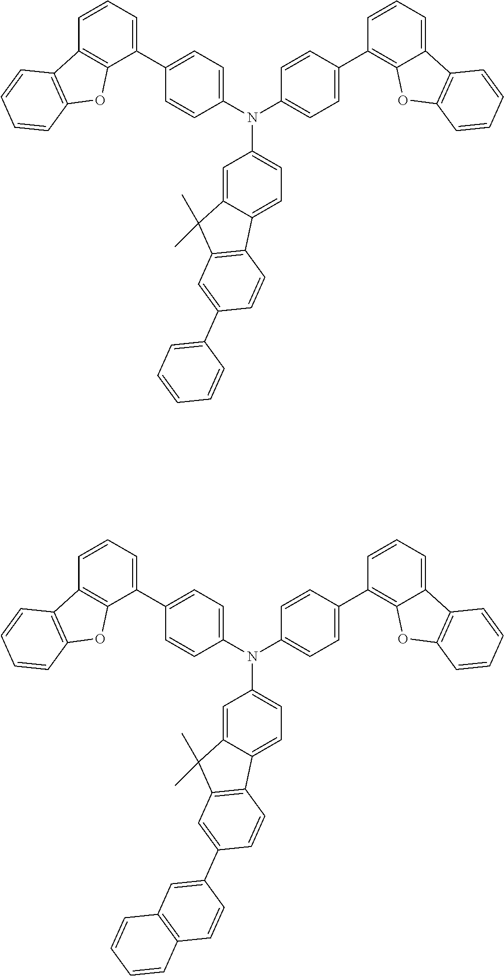 [SMILES: CC1(C)c2cc(-c3ccccc3)ccc2-c2ccc(N(c3ccc(-c4cccc5c4oc4ccccc45)cc3)c3ccc(-c4cccc5c4oc4ccccc45)cc3)cc21 ; CC1(C)c2cc(-c3ccc4ccccc4c3)ccc2-c2ccc(N(c3ccc(-c4cccc5c4oc4ccccc45)cc3)c3ccc(-c4cccc5c4oc4ccccc45)cc3)cc21]

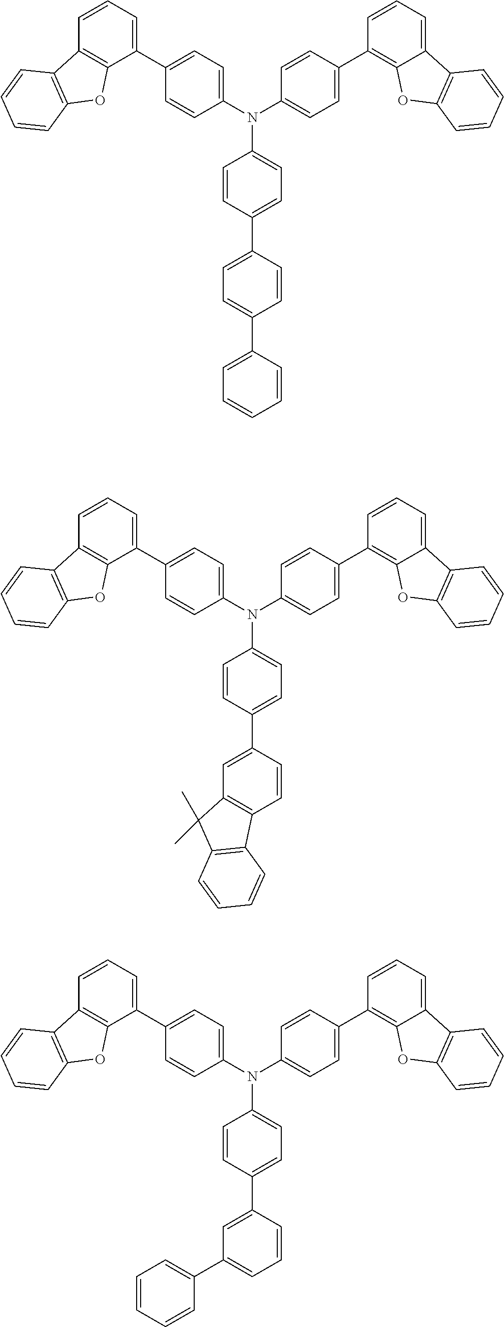

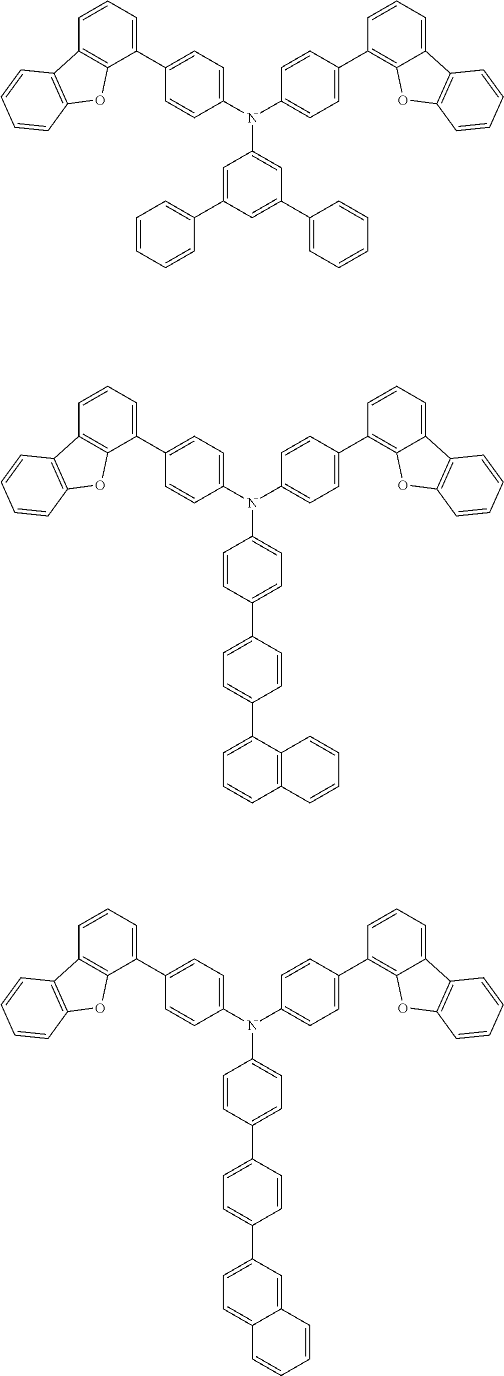 [SMILES: c1ccc(-c2cc(-c3ccccc3)cc(N(c3ccc(-c4cccc5c4oc4ccccc45)cc3)c3ccc(-c4cccc5c4oc4ccccc45)cc3)c2)cc1 ; c1ccc2c(-c3ccc(-c4ccc(N(c5ccc(-c6cccc7c6oc6ccccc67)cc5)c5ccc(-c6cccc7c6oc6ccccc67)cc5)cc4)cc3)cccc2c1 ; c1ccc2cc(-c3ccc(-c4ccc(N(c5ccc(-c6cccc7c6oc6ccccc67)cc5)c5ccc(-c6cccc7c6oc6ccccc67)cc5)cc4)cc3)ccc2c1]

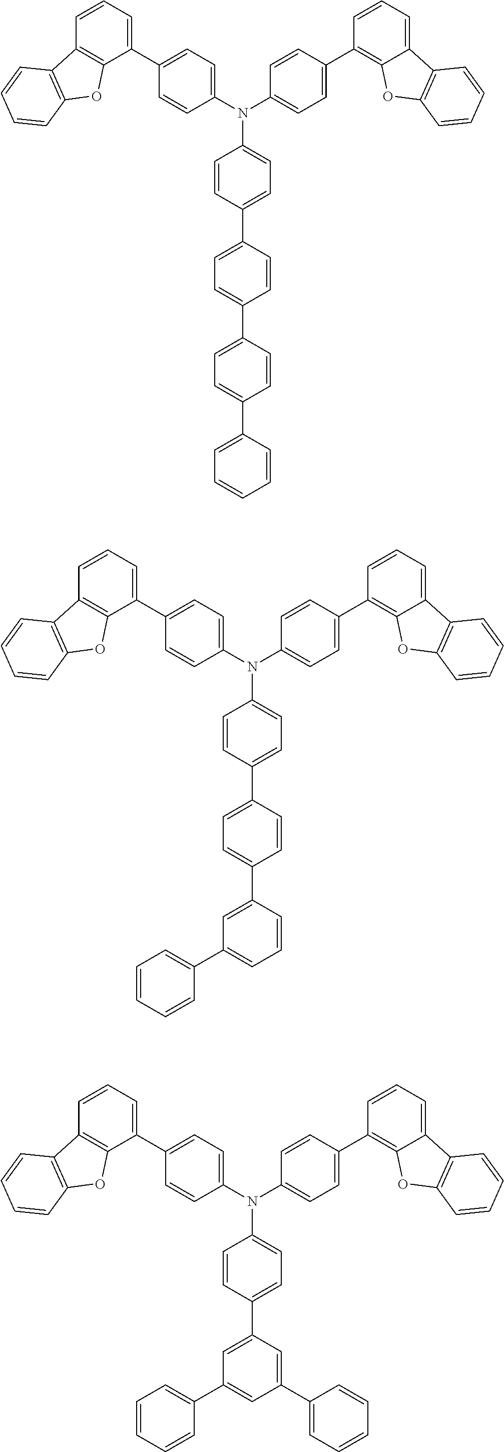 [SMILES: c1ccc(-c2ccc(-c3ccc(-c4ccc(N(c5ccc(-c6cccc7c6oc6ccccc67)cc5)c5ccc(-c6cccc7c6oc6ccccc67)cc5)cc4)cc3)cc2)cc1 ; c1ccc(-c2cccc(-c3ccc(-c4ccc(N(c5ccc(-c6cccc7c6oc6ccccc67)cc5)c5ccc(-c6cccc7c6oc6ccccc67)cc5)cc4)cc3)c2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

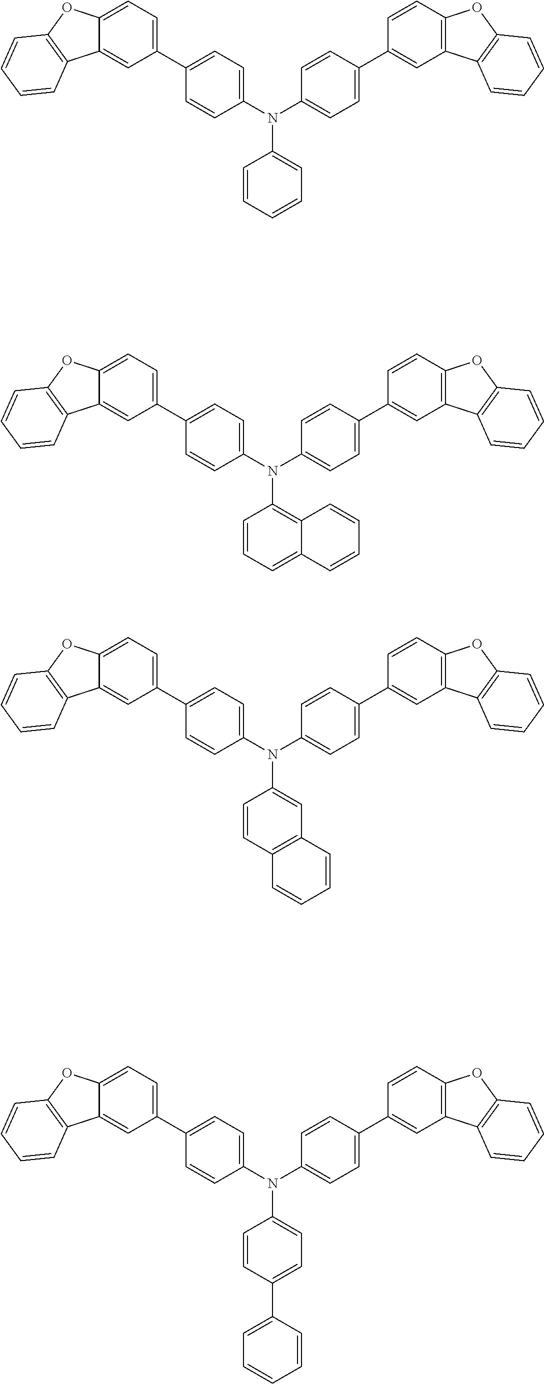 [SMILES: c1ccc(N(c2ccc(-c3ccc4oc5ccccc5c4c3)cc2)c2ccc(-c3ccc4oc5ccccc5c4c3)cc2)cc1 ; c1ccc2c(N(c3ccc(-c4ccc5oc6ccccc6c5c4)cc3)c3ccc(-c4ccc5oc6ccccc6c5c4)cc3)cccc2c1 ; c1ccc2cc(N(c3ccc(-c4ccc5oc6ccccc6c5c4)cc3)c3ccc(-c4ccc5oc6ccccc6c5c4)cc3)ccc2c1 ; c1ccc(-c2ccc(N(c3ccc(-c4ccc5oc6ccccc6c5c4)cc3)c3ccc(-c4ccc5oc6ccccc6c5c4)cc3)cc2)cc1]

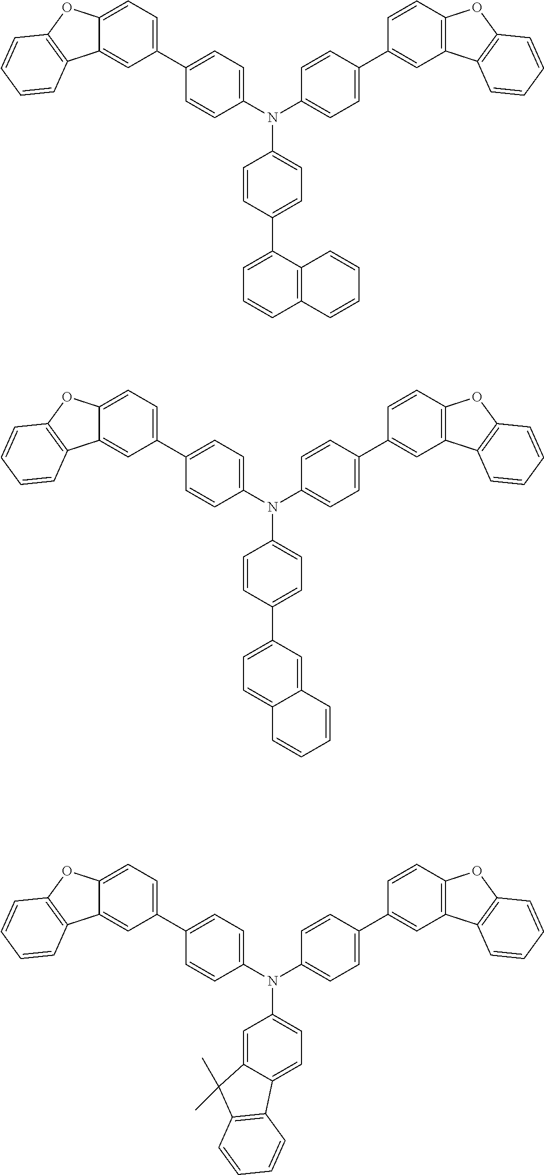 [SMILES: c1ccc2c(-c3ccc(N(c4ccc(-c5ccc6oc7ccccc7c6c5)cc4)c4ccc(-c5ccc6oc7ccccc7c6c5)cc4)cc3)cccc2c1 ; c1ccc2cc(-c3ccc(N(c4ccc(-c5ccc6oc7ccccc7c6c5)cc4)c4ccc(-c5ccc6oc7ccccc7c6c5)cc4)cc3)ccc2c1 ; CC1(C)c2ccccc2-c2ccc(N(c3ccc(-c4ccc5oc6ccccc6c5c4)cc3)c3ccc(-c4ccc5oc6ccccc6c5c4)cc3)cc21]

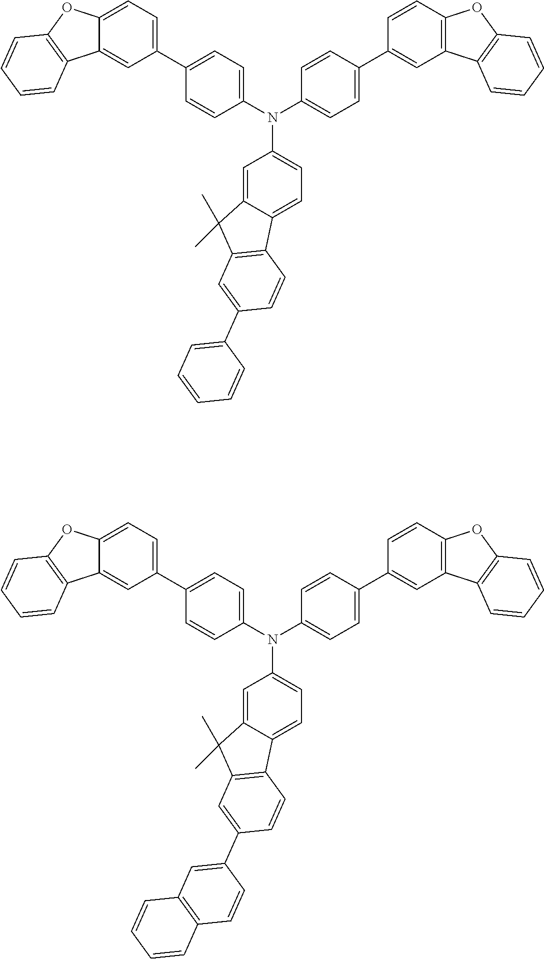 [SMILES: CC1(C)c2cc(-c3ccccc3)ccc2-c2ccc(N(c3ccc(-c4ccc5oc6ccccc6c5c4)cc3)c3ccc(-c4ccc5oc6ccccc6c5c4)cc3)cc21 ; CC1(C)c2cc(-c3ccc4ccccc4c3)ccc2-c2ccc(N(c3ccc(-c4ccc5oc6ccccc6c5c4)cc3)c3ccc(-c4ccc5oc6ccccc6c5c4)cc3)cc21]

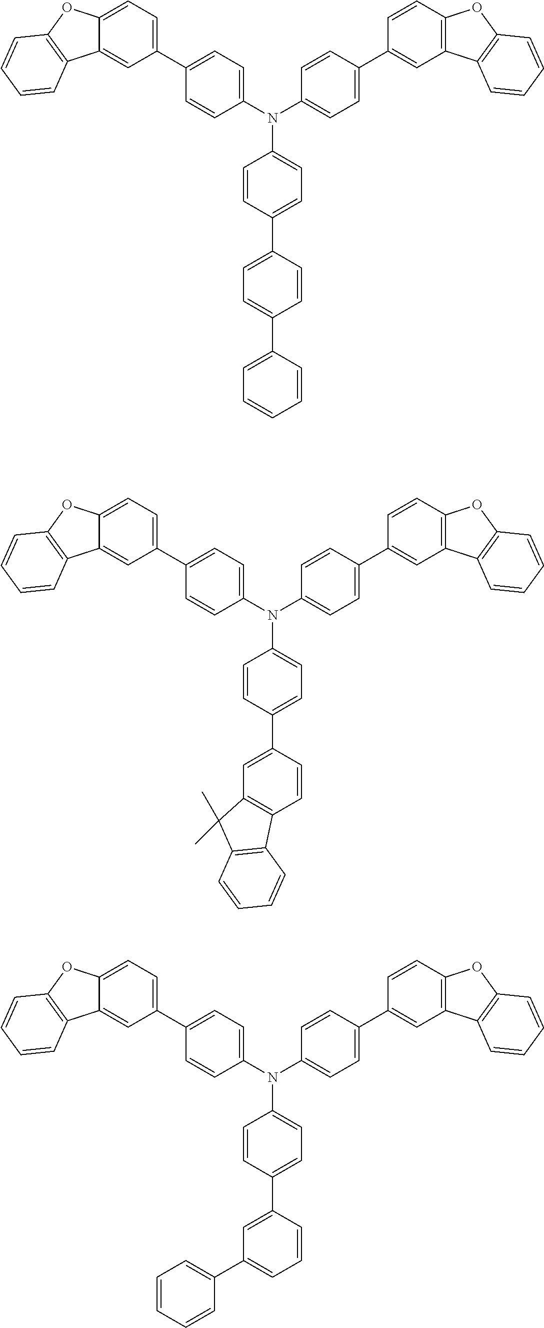

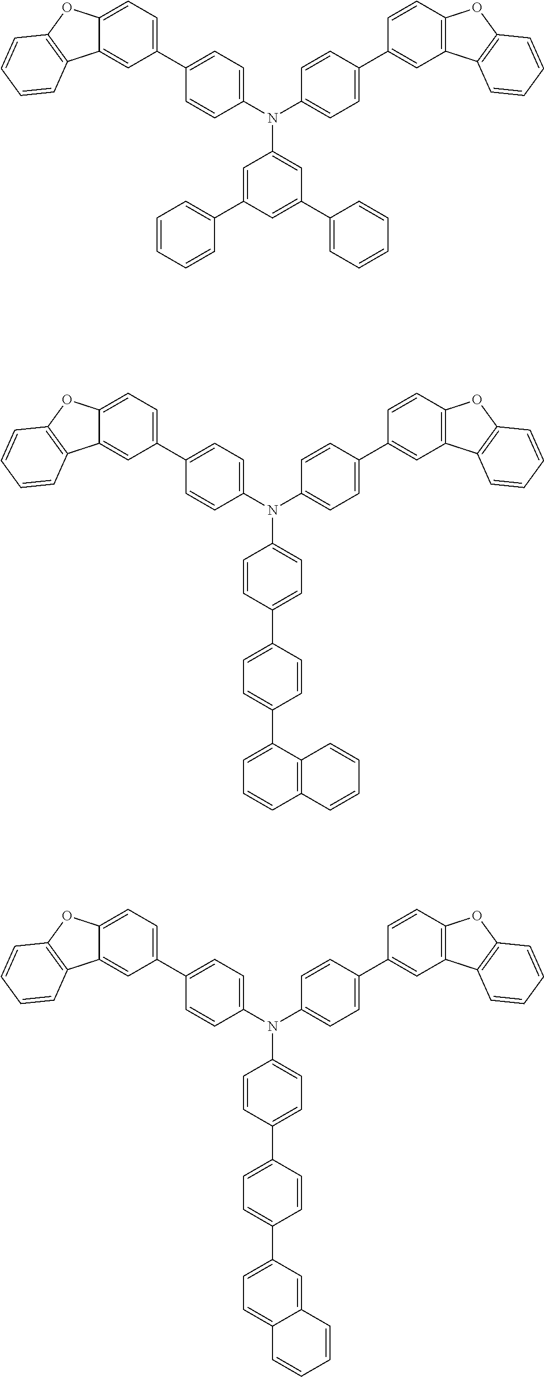 [SMILES: c1ccc(-c2cc(-c3ccccc3)cc(N(c3ccc(-c4ccc5oc6ccccc6c5c4)cc3)c3ccc(-c4ccc5oc6ccccc6c5c4)cc3)c2)cc1 ; c1ccc2c(-c3ccc(-c4ccc(N(c5ccc(-c6ccc7oc8ccccc8c7c6)cc5)c5ccc(-c6ccc7oc8ccccc8c7c6)cc5)cc4)cc3)cccc2c1 ; c1ccc2cc(-c3ccc(-c4ccc(N(c5ccc(-c6ccc7oc8ccccc8c7c6)cc5)c5ccc(-c6ccc7oc8ccccc8c7c6)cc5)cc4)cc3)ccc2c1]

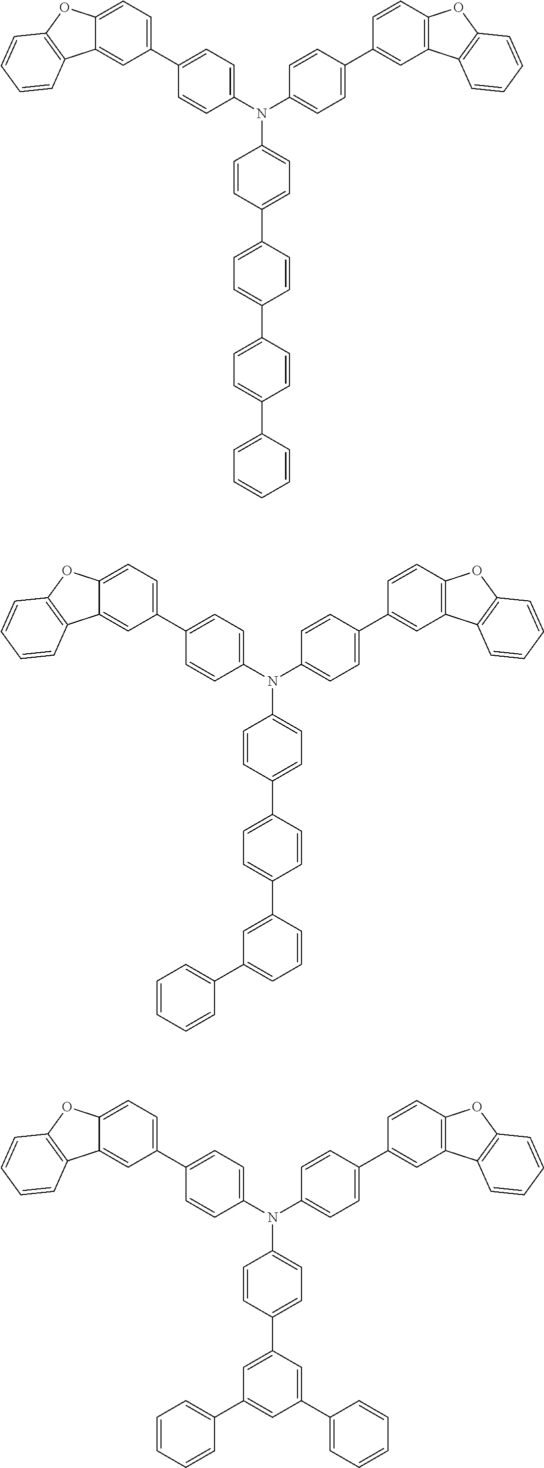 [SMILES: c1ccc(-c2ccc(-c3ccc(-c4ccc(N(c5ccc(-c6ccc7oc8ccccc8c7c6)cc5)c5ccc(-c6ccc7oc8ccccc8c7c6)cc5)cc4)cc3)cc2)cc1 ; c1ccc(-c2cccc(-c3ccc(-c4ccc(N(c5ccc(-c6ccc7oc8ccccc8c7c6)cc5)c5ccc(-c6ccc7oc8ccccc8c7c6)cc5)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6oc7ccccc7c6c5)cc4)cc3)c2)cc1]

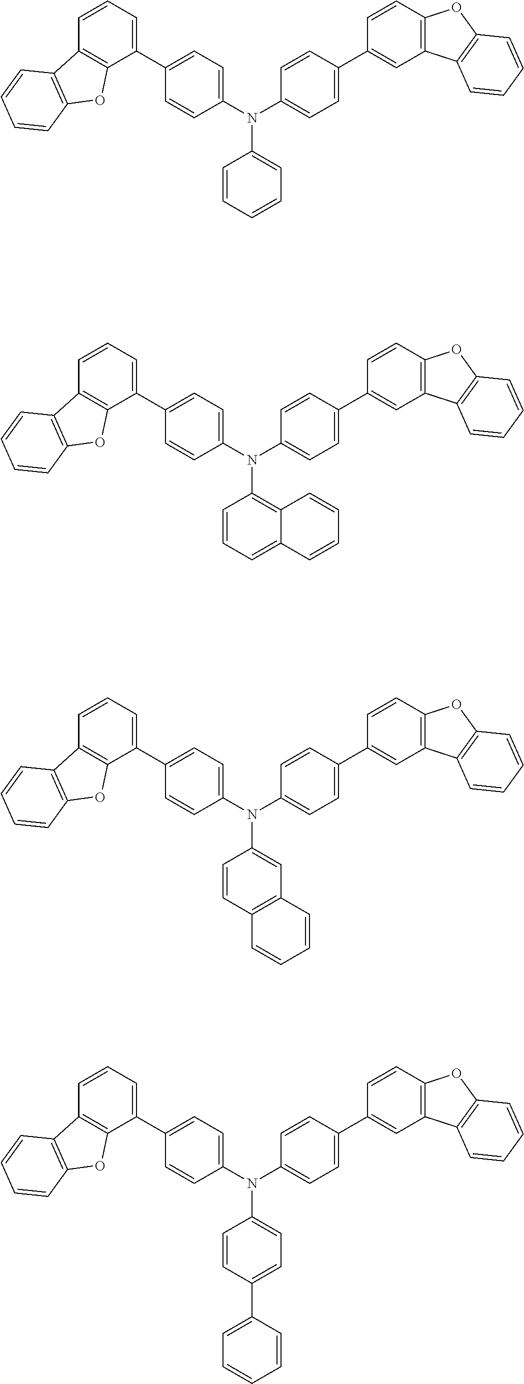 [SMILES: c1ccc(N(c2ccc(-c3ccc4oc5ccccc5c4c3)cc2)c2ccc(-c3cccc4c3oc3ccccc34)cc2)cc1 ; c1ccc2c(N(c3ccc(-c4ccc5oc6ccccc6c5c4)cc3)c3ccc(-c4cccc5c4oc4ccccc45)cc3)cccc2c1 ; c1ccc2cc(N(c3ccc(-c4ccc5oc6ccccc6c5c4)cc3)c3ccc(-c4cccc5c4oc4ccccc45)cc3)ccc2c1 ; c1ccc(-c2ccc(N(c3ccc(-c4ccc5oc6ccccc6c5c4)cc3)c3ccc(-c4cccc5c4oc4ccccc45)cc3)cc2)cc1]

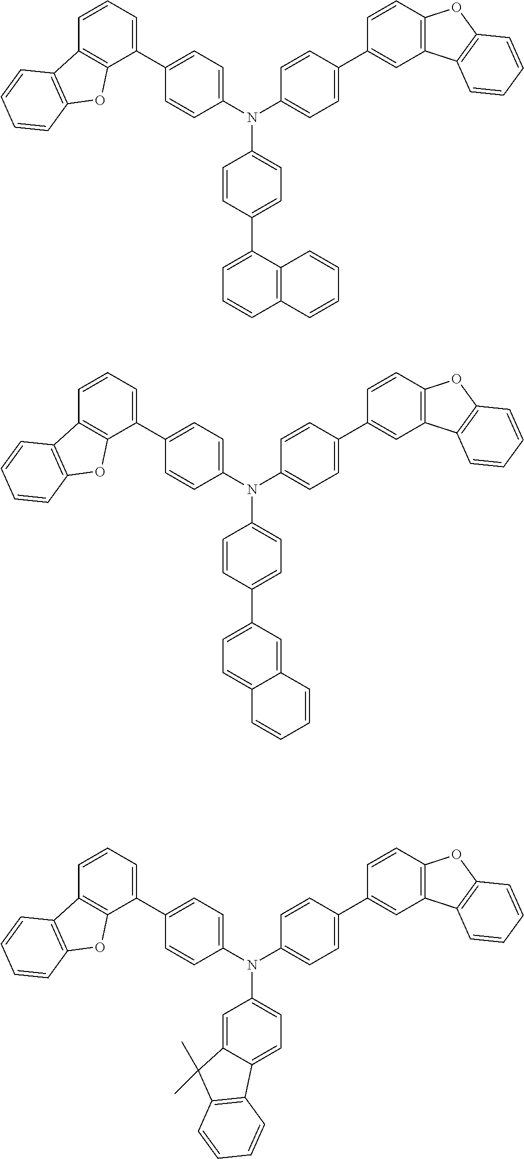 [SMILES: c1ccc2c(-c3ccc(N(c4ccc(-c5ccc6oc7ccccc7c6c5)cc4)c4ccc(-c5cccc6c5oc5ccccc56)cc4)cc3)cccc2c1 ; c1ccc2cc(-c3ccc(N(c4ccc(-c5ccc6oc7ccccc7c6c5)cc4)c4ccc(-c5cccc6c5oc5ccccc56)cc4)cc3)ccc2c1 ; CC1(C)c2ccccc2-c2ccc(N(c3ccc(-c4ccc5oc6ccccc6c5c4)cc3)c3ccc(-c4cccc5c4oc4ccccc45)cc3)cc21]

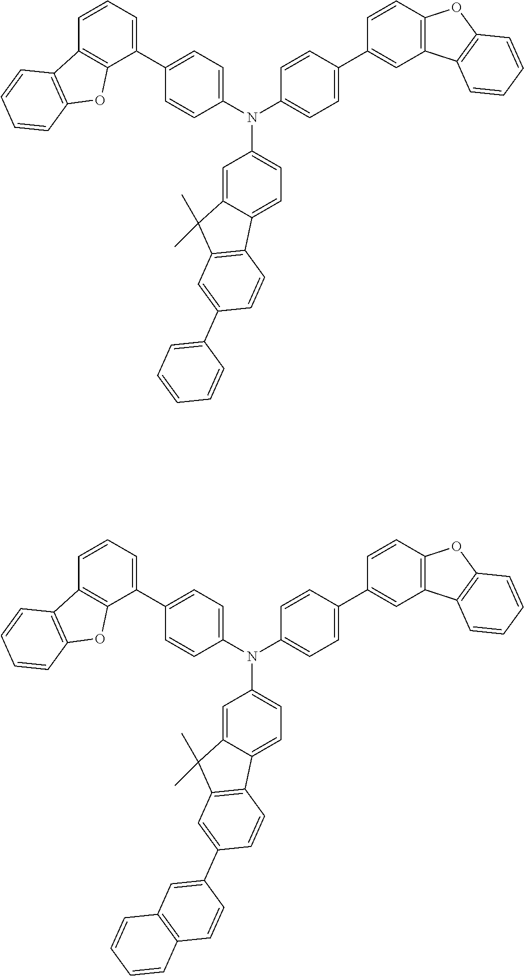 [SMILES: CC1(C)c2cc(-c3ccccc3)ccc2-c2ccc(N(c3ccc(-c4ccc5oc6ccccc6c5c4)cc3)c3ccc(-c4cccc5c4oc4ccccc45)cc3)cc21 ; CC1(C)c2cc(-c3ccc4ccccc4c3)ccc2-c2ccc(N(c3ccc(-c4ccc5oc6ccccc6c5c4)cc3)c3ccc(-c4cccc5c4oc4ccccc45)cc3)cc21]

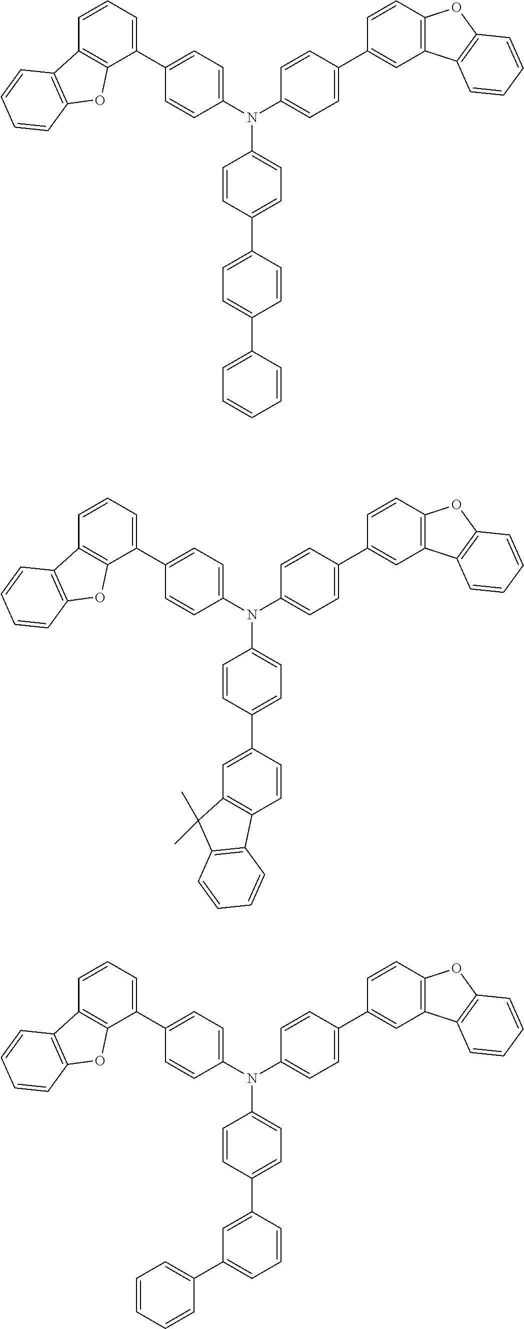

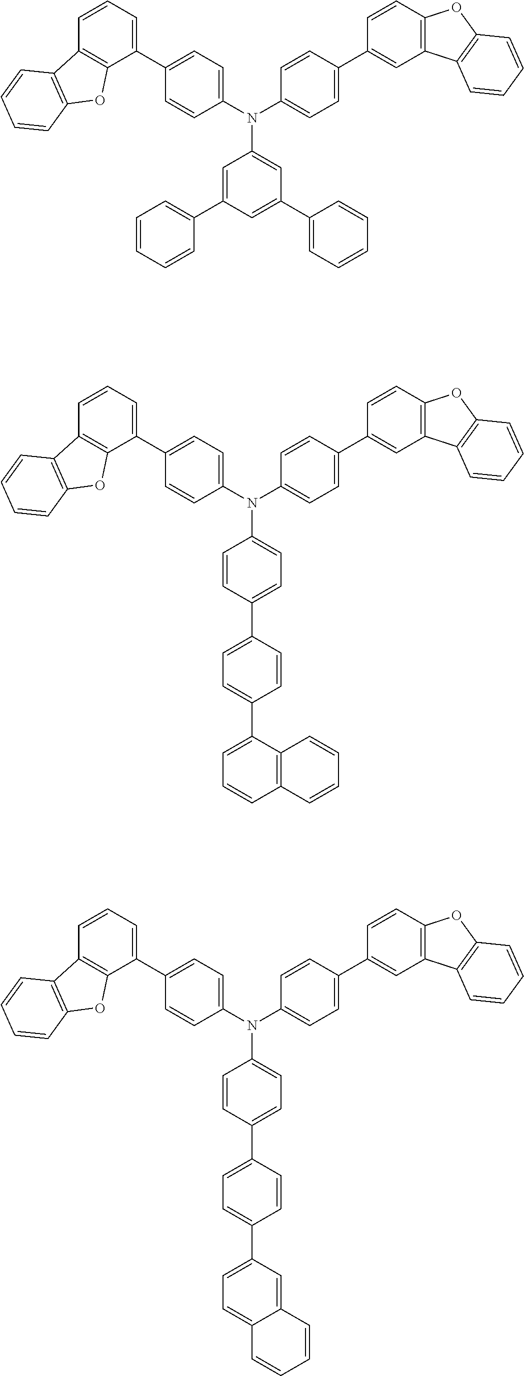 [SMILES: c1ccc(-c2cc(-c3ccccc3)cc(N(c3ccc(-c4ccc5oc6ccccc6c5c4)cc3)c3ccc(-c4cccc5c4oc4ccccc45)cc3)c2)cc1 ; c1ccc2c(-c3ccc(-c4ccc(N(c5ccc(-c6ccc7oc8ccccc8c7c6)cc5)c5ccc(-c6cccc7c6oc6ccccc67)cc5)cc4)cc3)cccc2c1 ; c1ccc2cc(-c3ccc(-c4ccc(N(c5ccc(-c6ccc7oc8ccccc8c7c6)cc5)c5ccc(-c6cccc7c6oc6ccccc67)cc5)cc4)cc3)ccc2c1]

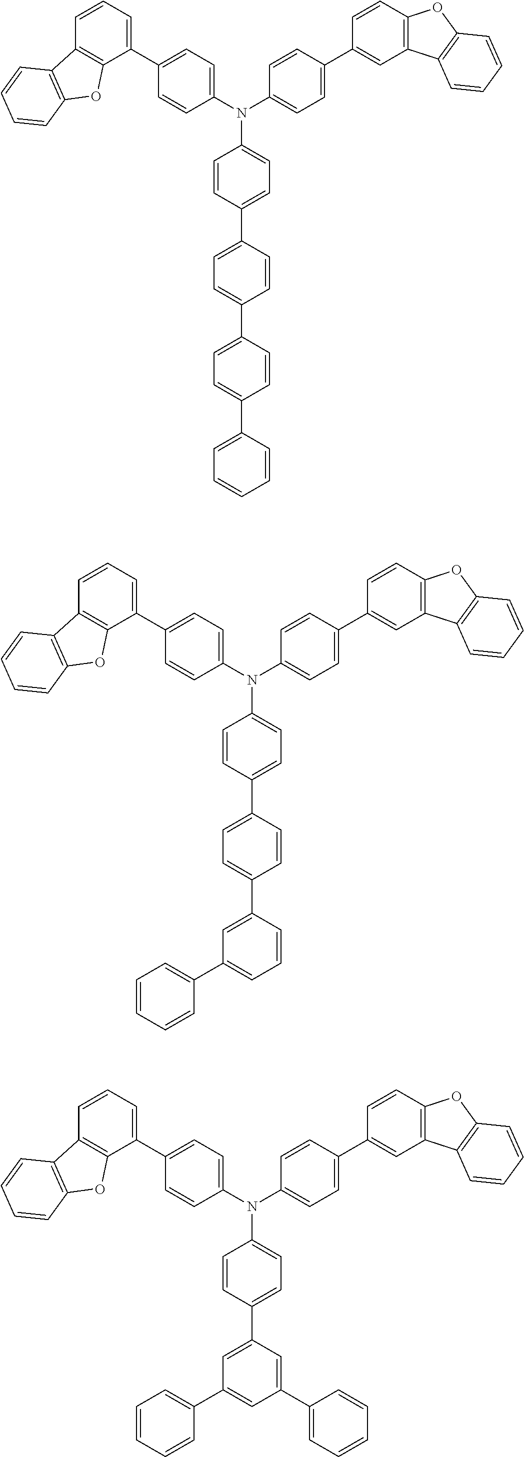 [SMILES: c1ccc(-c2ccc(-c3ccc(-c4ccc(N(c5ccc(-c6ccc7oc8ccccc8c7c6)cc5)c5ccc(-c6cccc7c6oc6ccccc67)cc5)cc4)cc3)cc2)cc1 ; c1ccc(-c2cccc(-c3ccc(-c4ccc(N(c5ccc(-c6ccc7oc8ccccc8c7c6)cc5)c5ccc(-c6cccc7c6oc6ccccc67)cc5)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5cccc6c5oc5ccccc56)cc4)cc3)c2)cc1]

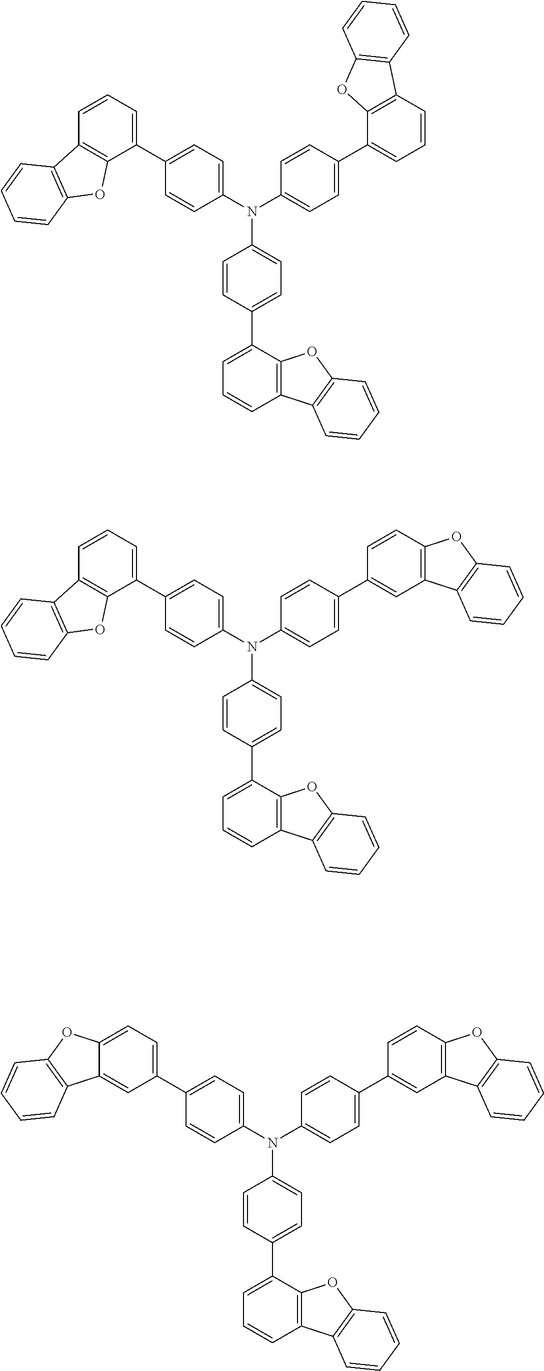 [SMILES: c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc2c(c1)oc1ccc(-c3ccc(N(c4ccc(-c5cccc6c5oc5ccccc56)cc4)c4ccc(-c5cccc6c5oc5ccccc56)cc4)cc3)cc12 ; c1ccc2c(c1)oc1ccc(-c3ccc(N(c4ccc(-c5ccc6oc7ccccc7c6c5)cc4)c4ccc(-c5cccc6c5oc5ccccc56)cc4)cc3)cc12]

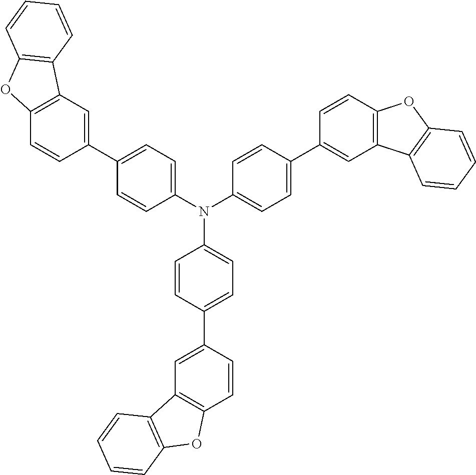 [SMILES: c1ccc2c(c1)oc1ccc(-c3ccc(N(c4ccc(-c5ccc6oc7ccccc7c6c5)cc4)c4ccc(-c5ccc6oc7ccccc7c6c5)cc4)cc3)cc12]

Material for hole transporting layer adjacent to light emitting layer (second hole transporting material) represented by any of formulae (5) to (7);

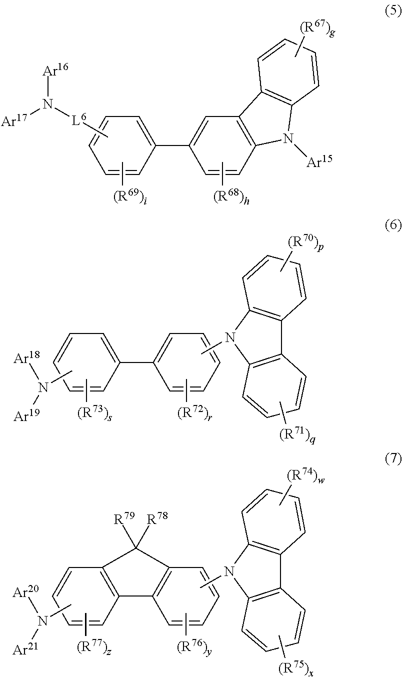

wherein:

each of Ar¹⁵ to Ar²¹ independently represents a substituted or unsubstituted aryl group having 6 to 50 ring carbon atoms, a substituted or unsubstituted aromatic heterocyclic group having 5 to 50 ring carbon atoms, an aromatic amino group-substituted aryl group having 8 to 50 ring carbon atoms, or an aromatic heterocyclic group-substituted aryl group having 8 to 50 ring carbon atoms;

Ar¹⁶ and Ar¹⁷, Ar¹⁸ and Ar¹⁹, and Ar²⁰ and Ar²¹ may be bonded to each other to form a ring;

L⁶ represents a single bond or a substituted or unsubstituted arylene group having 6 to 50 ring carbon atoms, which may be substituted with at least one substituent selected from the group consisting of a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms wherein the aryl portion has 6 to 14 ring carbon atoms, an aryl group having 6 to 50 ring carbon atoms, a halogen atom, and a cyano group;

each of R⁶⁷ to R⁷⁷ independently represents a halogen atom, a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, a substituted or unsubstituted aralkyl group having 7 to 20 carbon atoms, a substituted or unsubstituted alkenyl group having 2 to 40 carbon atoms, a substituted or unsubstituted alkylamino group having 1 to 40 carbon atoms, a substituted or unsubstituted aralkylamino group having 7 to 60 carbon atoms, a substituted or unsubstituted alkylsilyl group having 3 to 20 carbon atoms, a substituted or unsubstituted arylsilyl group having 8 to 40 carbon atoms, a substituted or unsubstituted aralkylsilyl group having 8 to 40 carbon atoms, or a substituted or unsubstituted haloalkyl group having 1 to 40 carbon atoms;

each of R⁷⁸ and R⁷⁹ independently represents a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, or a substituted or unsubstituted aralkyl group having 7 to 20 carbon atoms;

each of g, i, p, q, r, s, w, and x independently represents an integer of 0 to 4; and

each of h, y and z independently represents an integer of 0 to 3.

Examples of the aryl group having 6 to 50 ring carbon atoms for Ar¹⁵ to Ar²¹ include a phenyl group, a naphthyl phenyl group, a biphenylyl group, a terphenylyl group, a biphenylenyl group, a naphthyl group, a phenylnaphthyl group, an acenaphthylenylene group, an anthryl group, a benzoanthryl group, an aceanthryl group, a phenanthryl group, a benzophenanthryl group, a phenalenylene group, a fluorenyl group, a 9,9-dimethylfluorenyl group, a 7-phenyl-9,9-dimethylfluorenyl group, a pentacenyl group, a picenyl group, a pentaphenyl group, a pyrenyl group, a chrysenyl group, a benzochrysenyl group, a s-indacenyl group, an as-indacenyl group, a fluoranthenyl group, and a perylenyl group, with an aryl group having 6 to 20 ring carbon atoms being preferred, an aryl group having 6 to 14 ring carbon atoms being more preferred, and an aryl group having 6 to 10 ring carbon atoms being still more preferred.

Examples of the aromatic heterocyclic group having 5 to 50 ring carbon atoms include a pyrrolyl group, a furyl group, a thienyl group, a pyridyl group, a pyridazinyl group, a pyrimidinyl group, a pyrazinyl group, a triazinyl group, an imidazolyl group, an oxazolyl group, a thiazolyl group, a pyrazolyl group, an isoxazolyl group, an isothiazolyl group, an oxadiazolyl group, a thiadiazolyl group, a triazolyl group, an indolyl group, an isoindolyl group, a benzofuranyl group, an isobenzofuranyl group, a benzothiophenyl group, an indolizinyl group, a quinolizinyl group, a quinolyl group, an isoquinolyl group, a cinnolyl group, a phthalazinyl group, a quinazolinyl group, a quinoxalinyl group, a benzimidazolyl group, a benzoxazolyl group, a benzothiazolyl group, an indazolyl group, a benzisoxazolyl group, a benzisothiazolyl group, a carbazolyl group, a dibenzofuranyl group, a dibenzothiophenyl group, a phenanthridinyl group, an acridinyl group, a phenanthrolinyl group, a phenazinyl group, a phenothiazinyl group, a phenoxazinyl group, and a xanthenyl group, with an aromatic heterocyclic group having 5 to 20 ring carbon atoms being preferred and an aromatic heterocyclic group having 5 to 14 ring carbon atoms being more preferred.

The aromatic amino group which may be bonded to the aryl group is preferably a diarylamino group. The aryl group to be substituted with the aromatic amino group and its preferred examples are selected from the aryl group having 6 to 50 ring carbon atoms mentioned above and its preferred examples.

The aromatic heterocyclic group which may be bonded to the aryl group and its preferred examples are selected from the aromatic heterocyclic group having 5 to 50 ring carbon atoms mentioned above and its preferred examples.

The groups mentioned above may be substituted, for example, with at least one substituent selected from the group consisting of a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms wherein the aryl portion has 6 to 14 ring carbon atoms, an aryl group having 6 to 50 ring carbon atoms, a halogen atom, and a cyano group.

Examples of the arylene group having 6 to 50 ring carbon atoms for L⁶ include a phenylene group, a naphthylene group, a anthrylene group, and a phenanthrylene group, with an arylene group having 6 to 30 ring carbon atoms being preferred, an arylene group having 6 to 20 ring carbon atoms being more preferred, and an arylene group having 6 to 14 ring carbon atoms being still more preferred.

Examples of the halogen atom for R⁶⁷ to R⁷⁷ include a fluorine atom, a chlorine atom, a bromine atom, and an iodine atom, with a fluorine atom being preferred.

The alkyl group having 1 to 40 carbon atoms is preferably an alkyl group having 1 to 20 carbon atoms, more preferably an alkyl group having 1 to 10 carbon atoms, and still more preferably an alkyl group having 1 to 5 carbon atoms.

The heteroaryl group having 5 to 20 ring atoms is preferably a heteroaryl group having 3 to 14 carbon atoms.

The non-fused aryl group having 6 to 40 ring carbon atoms is preferably a non-fused aryl group having 6 to 30 ring carbon atoms, more preferably a non-fused aryl group having 6 to 20 ring carbon atoms, and still more preferably a non-fused aryl group having 6 to 14 ring carbon atoms.

The alkyl group having 1 to 40 carbon atoms for R⁷⁸ and R⁷⁹ is preferably an alkyl group having 1 to 20 carbon atoms, more preferably an alkyl group having 1 to 10 carbon atoms, still more preferably an alkyl group having 1 to 5 carbon atoms, and particularly preferably a methyl group.

The heteroaryl group having 5 to 20 ring atoms is preferably a heteroaryl group having 5 to 14 ring atoms.

The non-fused aryl group having 6 to 40 ring carbon atoms is preferably a non-fused aryl group having 6 to 30 ring carbon atoms, more preferably a non-fused aryl group having 6 to 20 ring carbon atoms, still more preferably a non-fused aryl group having 6 to 14 ring carbon atoms, and particularly preferably a phenyl group.

The aralkyl group having 7 to 20 carbon atoms is preferably an aralkyl group having 7 to 13 carbon atoms.

Each of R⁷⁸ and R⁷⁹ preferably represents an alkyl group having 1 to 40 carbon atoms (its preferred examples are as mentioned above) and more preferably represents a methyl group.

Of the compound represented by any of formulae (5) to (7), the compound represented by formula (6) or (7) is preferred and the compound represented by formula (7) is more preferred.

Examples of the compound represented by formula (6) or (7) are shown below, although not limited to the following compounds.

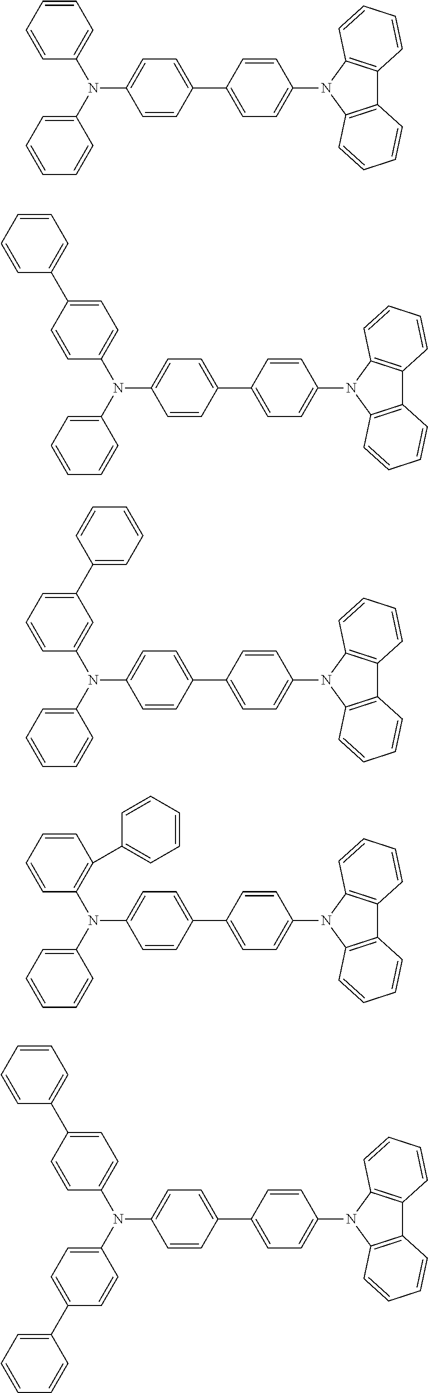

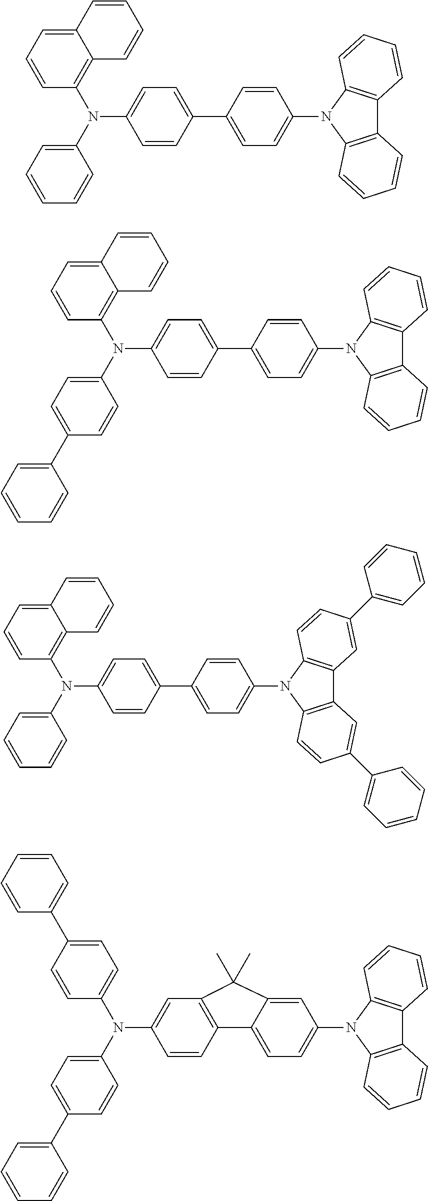 [SMILES: c1ccc(N(c2ccc(-c3ccc(-n4c5ccccc5c5ccccc54)cc3)cc2)c2cccc3ccccc23)cc1 ; c1ccc(-c2ccc(N(c3ccc(-c4ccc(-n5c6ccccc6c6ccccc65)cc4)cc3)c3cccc4ccccc34)cc2)cc1 ; c1ccc(-c2ccc3c(c2)c2cc(-c4ccccc4)ccc2n3-c2ccc(-c3ccc(N(c4ccccc4)c4cccc5ccccc45)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21]

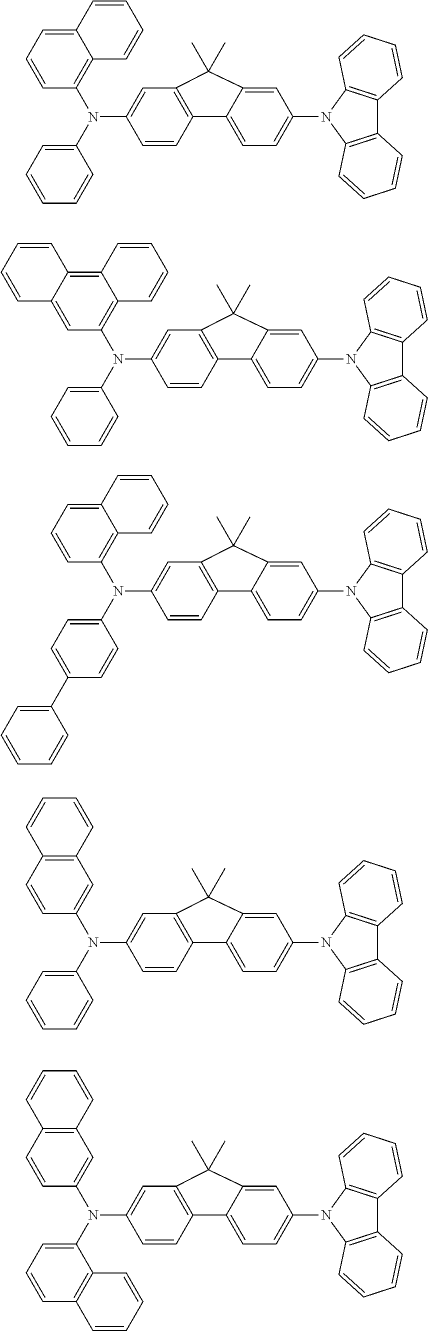

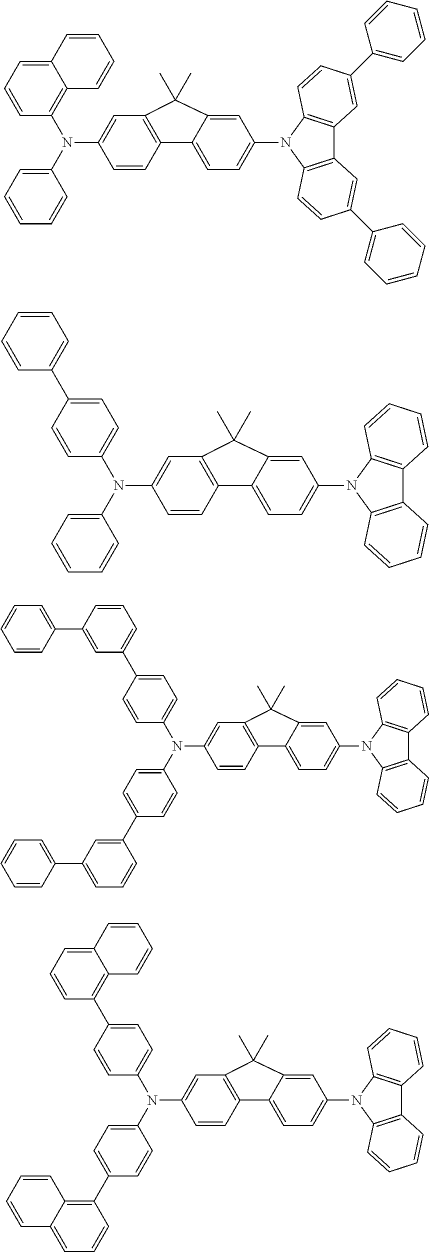

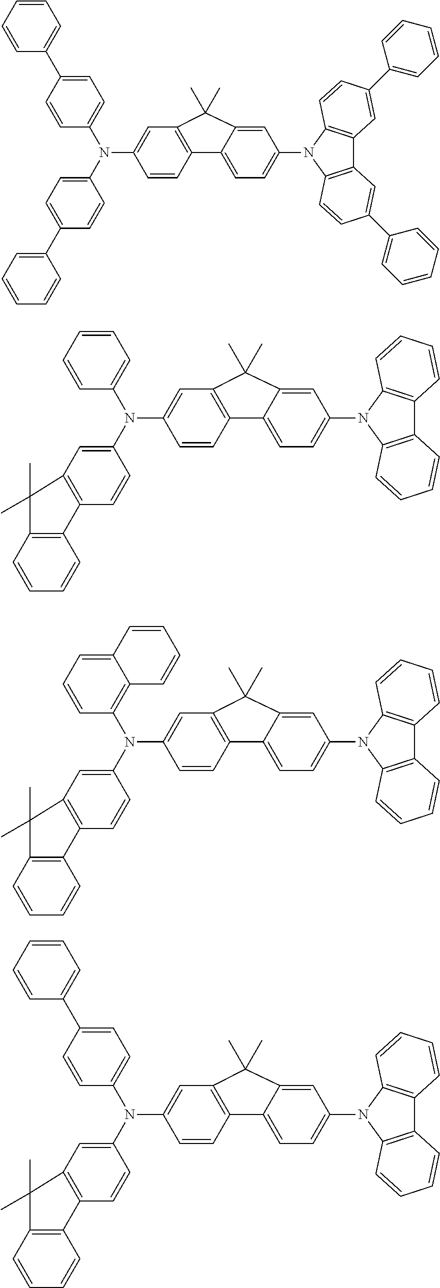

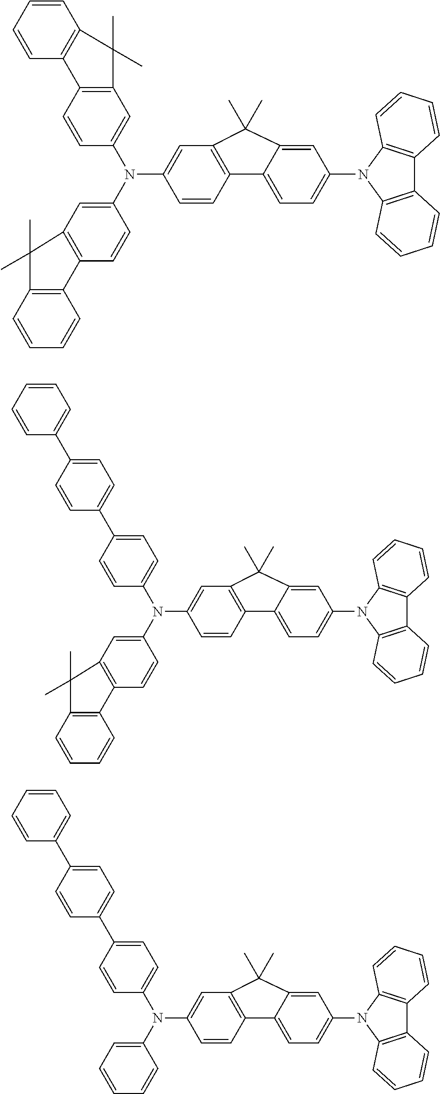

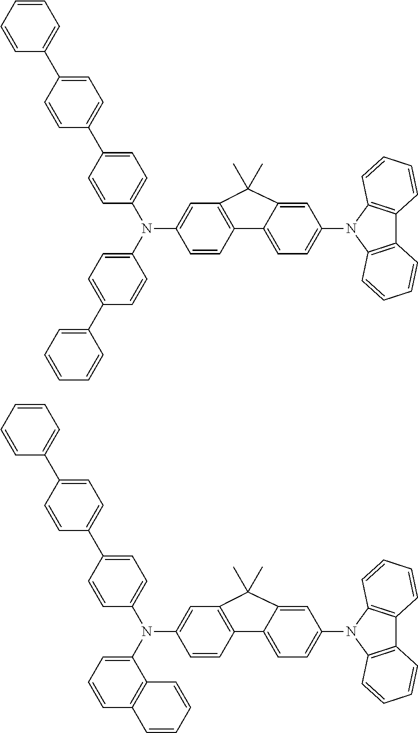

Material for hole transporting layer adjacent to light emitting layer (second hole transporting material) represented by formula (8):

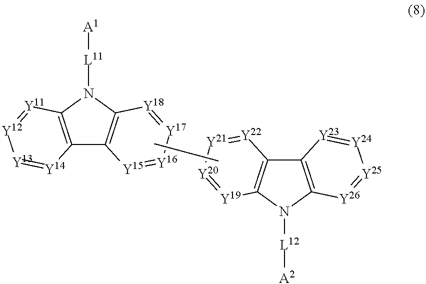

wherein:

each of A¹ and A² independently represents a substituted or unsubstituted aryl group having 6 to 30 ring carbon atoms or a substituted or unsubstituted heteroaryl group having 2 to 30 ring carbon atoms;

each of Y¹¹ to Y²⁶ independently represents C(R) or a nitrogen atom,

wherein R independently represents a hydrogen atom, a substituent, or a bond bonded to a carbazole skeleton; and

each of L¹¹ and L¹² independently represents a single bond or a substituted or unsubstituted arylene group having 6 to 50 ring carbon atoms, and an optional substituent for the arylene group is selected from a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms wherein the aryl portion has 6 to 14 ring carbon atoms, an aryl group having 6 to 50 ring carbon atoms, a halogen atom, and a cyano group.

The arylene group having 6 to 50 ring carbon atoms is preferably an arylene group having 6 to 30 ring carbon atoms, more preferably an arylene group having 6 to 20 ring carbon atoms, still more preferably an arylene group having 6 to 14 ring carbon atoms, and particularly preferably a phenylene group.

The compound represented by formula (8) is preferably represented by formula (8′):

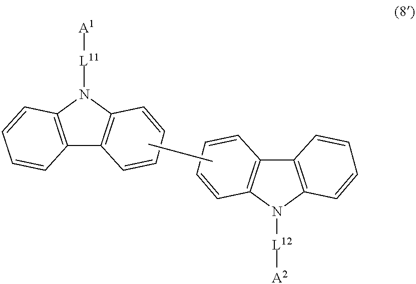

wherein each group of formula (8′) and its preferred example are as defined in formula (8).

### (5) Light Emitting Layer

The organic EL device of the invention may comprise a light emitting layer comprising a fluorescent material, i.e., a fluorescent emitting layer. The fluorescent emitting layer may be formed from a known fluorescent material, for example, at least one material selected from an anthracene derivative, a fluoranthene derivative, a styrylamine derivative, and an arylamine derivative, with the anthracene derivative and the arylamine derivative being more preferred. In particular, the anthracene derivative is preferably used as the host material and the arylamine derivative is preferably used as the dopant. The materials described in WO 2010/134350 and WO 2010/134352 are preferably used.

The organic EL device of the invention may comprise a light emitting layer comprising a phosphorescent material, i.e., a phosphorescent emitting layer. The phosphorescent emitting layer may be formed from a known phosphorescent material, for example, those described in WO 2005/079118. The dopant acting as the phosphorescent material is preferably an ortho-metallated complex of a metal, such as iridium (Ir), osmium (Os), and platinum (Pt), with an ortho-metallated complex of iridium (Ir) being more preferred. The host material acting as the phosphorescent material is preferably a carbazolyl-comprising compound, more preferably a compound comprising a carbazolyl group and a triazine skeleton or a compound comprising a carbazolyl group and a pyrimidine skeleton, and still more preferably a compound comprising two carbazolyl groups and one triazine skeleton or a compound comprising two carbazolyl groups and one pyrimidine skeleton. The compound represented by formula (8) or (8′) mentioned above as the second hole transporting material is also preferred as the carbazolyl-comprising compound.

Two or more kinds of the host materials are preferably used as described below, more preferably a compound comprising a carbazolyl group and a triazine skeleton and a compound comprising a carbazolyl group and pyrimidine skeleton are combinedly used, and still more preferably a compound comprising two carbazolyl groups and one triazine skeleton and a compound comprising two carbazolyl groups and one pyrimidine skeleton are combinedly used.

The anthracene derivative for use as a fluorescent material has preferably 26 to 100, more preferably 26 to 80, and still more preferably 26 to 60 ring carbon atoms. The anthracene derivative is preferably represented by formula (10):

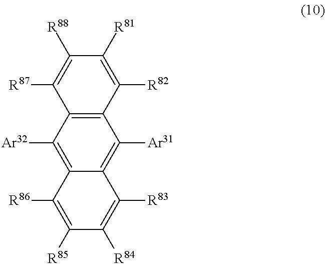

wherein:

each of Ar³¹ and Ar³² independently represents a substituted or unsubstituted aryl group having 6 to 50 ring carbon atoms or a substituted or unsubstituted heterocyclic group having 5 to 50 ring atoms; and

each of R⁸¹ to R⁸⁸ independently represents a hydrogen atom, a substituted or unsubstituted aryl group having 6 to 50 ring carbon atoms, a substituted or unsubstituted heterocyclic group having 5 to 50 ring atoms, a substituted or unsubstituted alkyl group having 1 to 50 carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted silyl group, a carboxyl group, a halogen atom, a cyano group, a nitro group, or a hydroxyl group.

The aryl group having 6 to 50 ring carbon atoms is preferably an aryl group having 6 to 40 ring carbon atoms and more preferably an aryl group having 6 to 30 ring carbon atoms.

The heterocyclic group having 5 to 50 ring atoms is preferably a heterocyclic group having 5 to 40 ring atoms and more preferably a heterocyclic group having 5 to 30 ring atoms.

The alkyl group having 1 to 50 carbon atoms is preferably an alkyl group having 1 to 30 carbon atoms, more preferably an alkyl group having 1 to 10 carbon atoms, and still more preferably an alkyl group having 1 to 5 carbon atoms.

The alkoxy group having 1 to 50 carbon atoms is preferably an alkoxy group having 1 to 30 carbon atoms, more preferably an alkoxy group having 1 to 10 carbon atoms, and still more preferably an alkoxy group having 1 to 5 carbon atoms.

The aralkyl group having 7 to 50 carbon atoms is preferably an aralkyl group having 7 to 30 carbon atoms and more preferably an aralkyl group having 7 to 20 carbon atoms.

The aryloxy group having 6 to 50 ring carbon atoms is preferably an aryloxy group having 6 to 40 ring carbon atoms and more preferably an aryloxy group having 6 to 30 ring carbon atoms.

The arylthio group having 6 to 50 ring carbon atoms is preferably an arylthio group having 6 to 40 ring carbon atoms and more preferably an arylthio group having 6 to 30 ring carbon atoms.

The alkoxycarbonyl group having 2 to 50 carbon atoms is preferably an alkoxycarbonyl group having 2 to 30 carbon atoms, more preferably an alkoxycarbonyl group having 2 to 10 carbon atoms, and still more preferably an alkoxycarbonyl group having 2 to 5 carbon atoms.

Examples of the halogen atom include a fluorine atom, a chlorine atom, and a bromine atom.

Each of Ar³¹ and Ar³² particularly preferably represents a substituted or unsubstituted aryl group having 6 to 50 ring carbon atoms.

The anthracene derivative represented by formula (10) is preferably represented by formula (10-1):

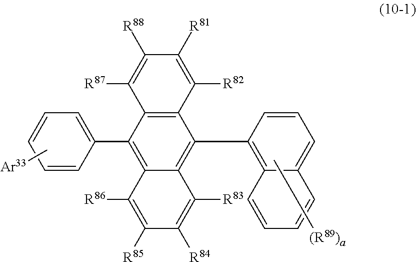

wherein:

Ar³³ represents a substituted or unsubstituted aryl group having 6 to 50 ring carbon atoms or a substituted or unsubstituted heterocyclic group having 5 to 50 ring atoms;

each of R⁸¹ to R⁸⁸ is as defined above;

R⁸⁹ is defined in the same manner as in R⁸¹ to R⁸⁸; and

a is an integer of 1 to 7.

Preferred examples of R⁸¹ to R⁸⁸ are as described above. Preferred examples of R⁸⁹ are the same as those of R⁸¹ to R⁸⁸. The subscript a is preferably an integer of 1 to 3 and more preferably 1 or 2.

The aryl group having 6 to 50 ring carbon atoms for Ar³³ is preferably an aryl group having 6 to 40 ring carbon atoms, more preferably an aryl group having 6 to 30 ring carbon atoms, still more preferably an aryl group having 6 to 20 ring carbon atoms, and particularly preferably an aryl group having 6 to 12 ring carbon atoms.

The arylamine derivative for use as the fluorescent material is preferably an aryldiamine derivative, more preferably an aryldiamine derivative comprising a pyrene skeleton, and still more preferably an aryldiamine derivative having a pyrene skeleton and a dibenzofuran skeleton.

The aryldiamine derivative is preferably an aryldiamine derivative represented by formula (11):

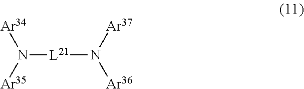

wherein:

each of Ar³⁴ to Ar³⁷ independently represents a substituted or unsubstituted aryl group having 6 to 50 ring carbon atoms or a substituted or unsubstituted heteroaryl group having 5 to 50 ring atoms; and

L²¹ represents a substituted or unsubstituted arylene group having 6 to 50 ring carbon atoms or a substituted or unsubstituted heteroarylene group having 5 to 50 ring atoms.

The aryl group having 6 to 50 ring carbon atoms is preferably an aryl group having 6 to 30 ring carbon atoms, more preferably an aryl group having 6 to 20 ring carbon atoms, still more preferably an aryl group having 6 to 12 ring carbon atoms, with a phenyl group and a naphthyl group being particularly preferred.

The heteroaryl group having 5 to 50 ring atoms is preferably a heteroaryl group having 5 to 40 ring atoms, more preferably a heteroaryl group having 5 to 30 ring atoms, and still more preferably a heteroaryl group having 5 to 20 ring atoms, for example, a carbazolyl group, a dibenzofuranyl group and dibenzothiophenyl group, with a dibenzofuranyl group being preferred. Preferred examples of the substituent for the heteroaryl group include an aryl group having 6 to 30, preferably 6 to 20, and more preferably 6 to 12 ring carbon atoms, with a phenyl group and a naphthyl group being more preferred.

The arylene group having 6 to 50 ring carbon atoms is preferably an arylene group having 6 to 40 ring carbon atoms, more preferably an arylene group having 6 to 30 ring carbon atoms, and still more preferably an arylene group having 6 to 20 ring carbon atoms, with a pyrenyl group being particularly preferred.

Examples of the compound comprising a carbazolyl group which is a preferred host material for use as the phosphorescent material are shown below.

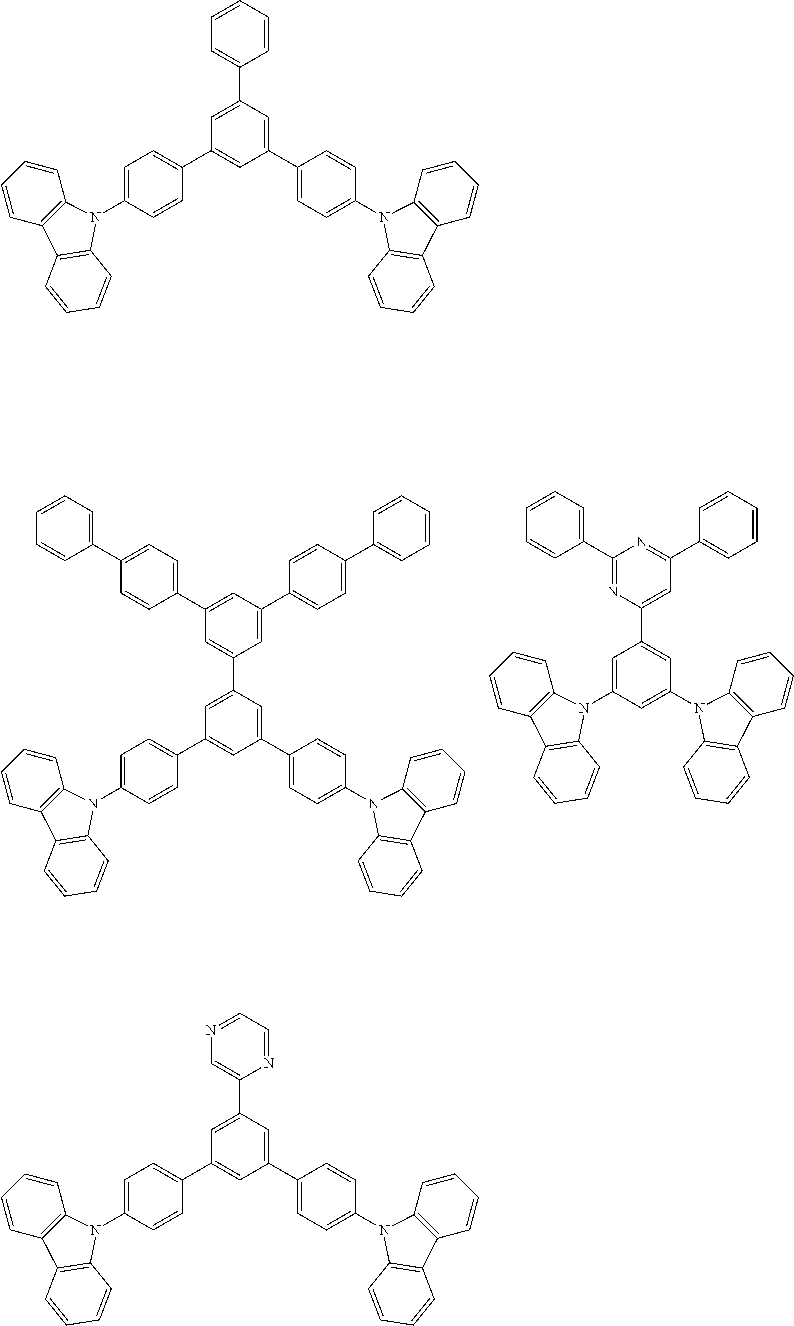 [SMILES: c1ccc(-c2cc(-c3ccc(-n4c5ccccc5c5ccccc54)cc3)cc(-c3ccc(-n4c5ccccc5c5ccccc54)cc3)c2)cc1 ; c1ccc(-c2ccc(-c3cc(-c4ccc(-c5ccccc5)cc4)cc(-c4cc(-c5ccc(-n6c7ccccc7c7ccccc76)cc5)cc(-c5ccc(-n6c7ccccc7c7ccccc76)cc5)c4)c3)cc2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc2c(c1)c1ccccc1n2-c1ccc(-c2cc(-c3ccc(-n4c5ccccc5c5ccccc54)cc3)cc(-c3cnccn3)c2)cc1]

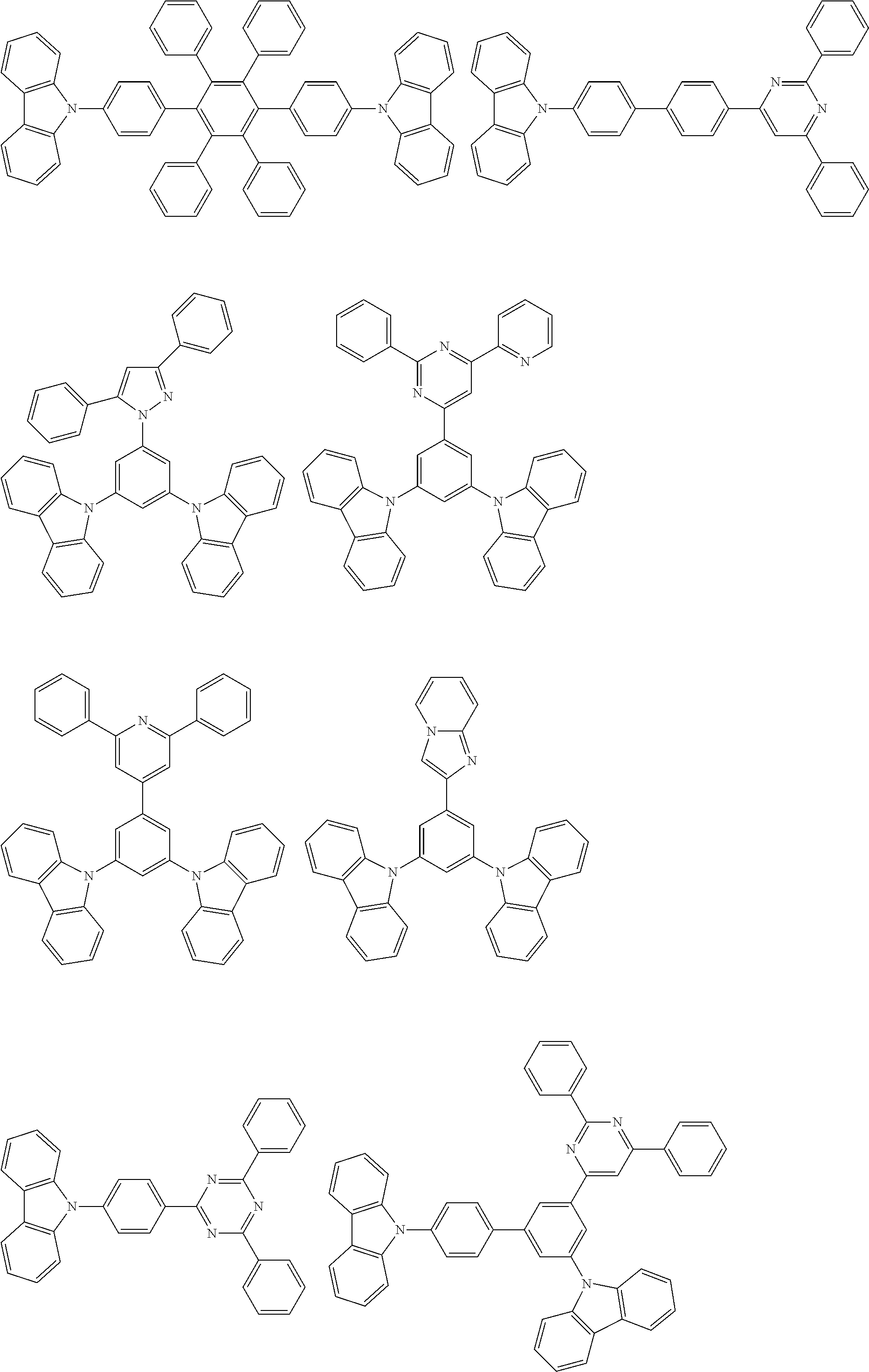

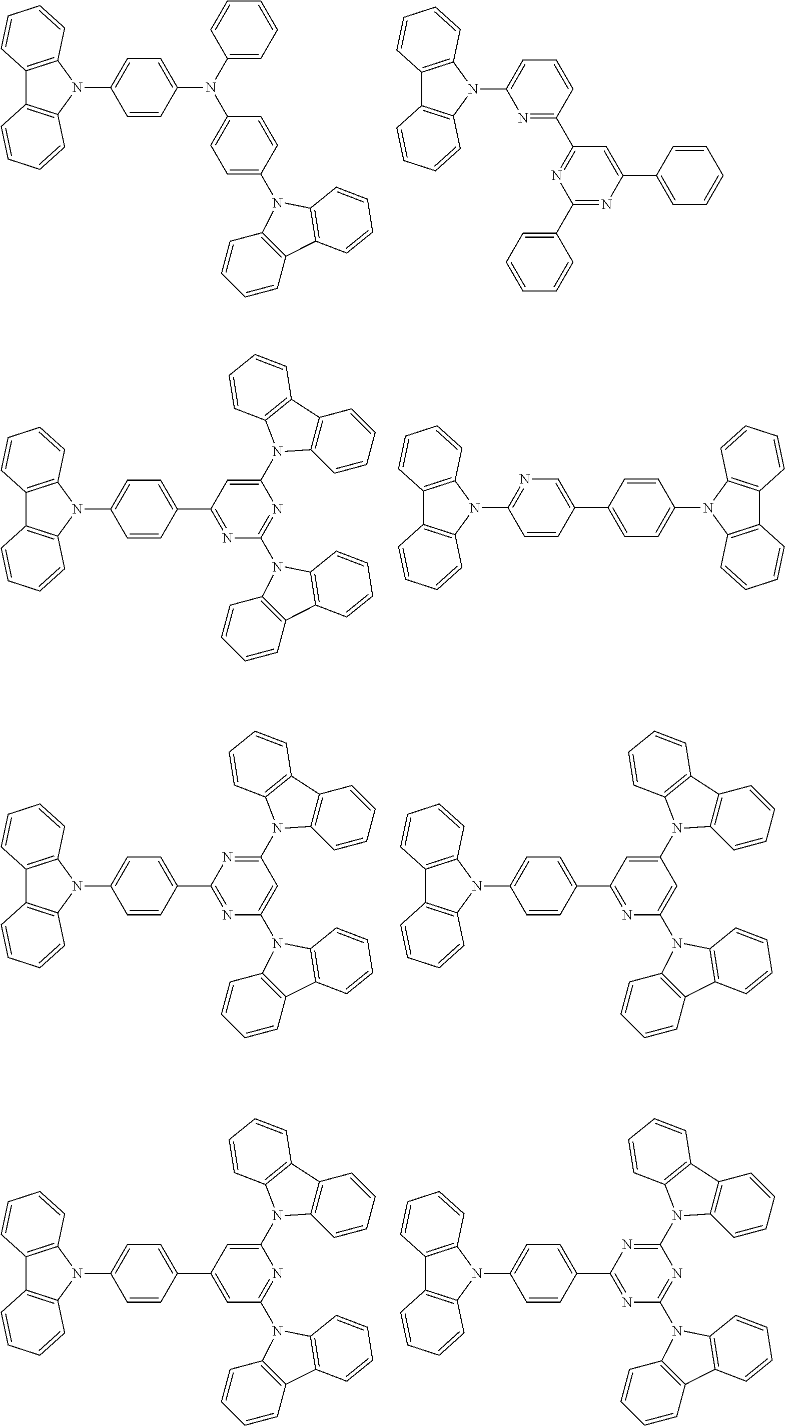

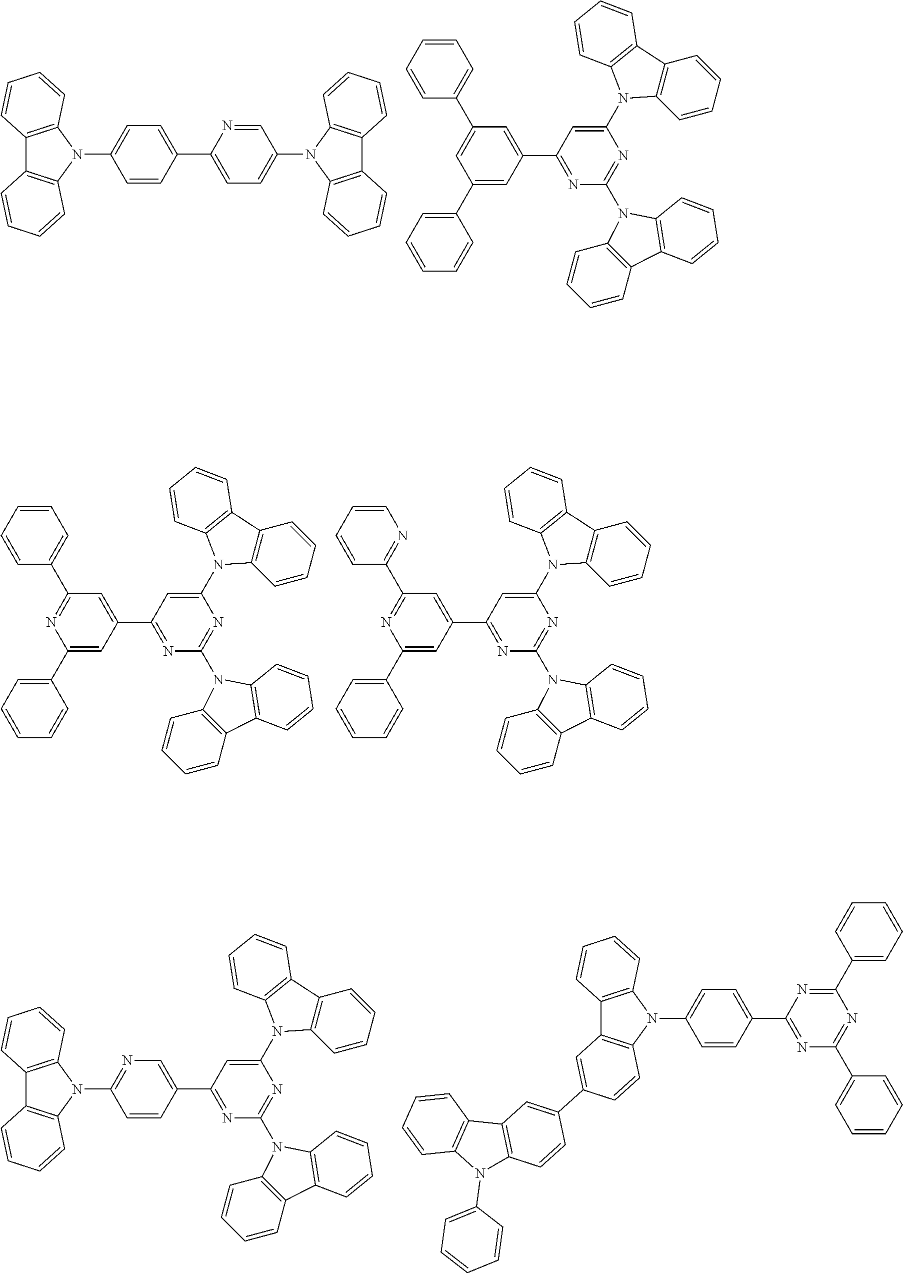

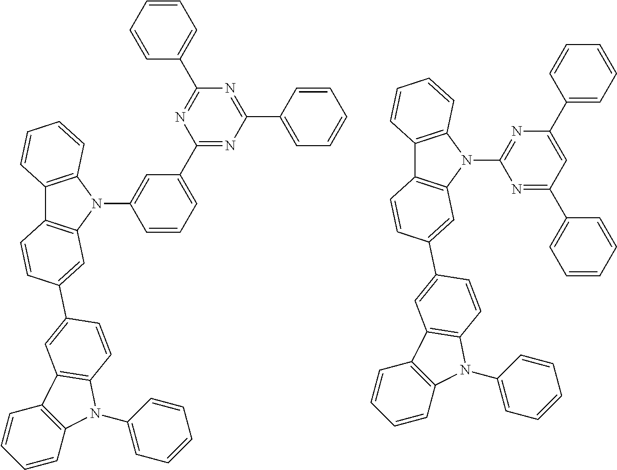

A double host (host/co-host) system may be used for the light emitting layer. For example, to control the carrier balance in the light emitting layer, an electron transporting host and a hole transporting host may be combinedly used.

The light emitting layer may be also made into a double dopant layer. When two or more kinds of dopant materials having high quantum yield are used in the light emitting layer, each dopant emits light with its own color. For example, a yellow light emitting layer can be obtained by co-depositing a host, a red-emitting dopant and a green-emitting dopant.

The light emitting layer may further comprise a hole transporting material, a electron transporting material, and a polymer binder, if necessary.

The thickness of the light emitting layer is preferably 5 to 50 nm, more preferably 7 to 50 nm and most preferably 10 to 50 nm. If less than 5 nm, the light emitting layer may be difficult to form and the color may be difficult to control. If exceeding 50 nm, the driving voltage is likely to increase.

### (6) Electron Injecting/Transporting Layer

The electron injecting/transporting layer is a layer which helps the injection of electrons into the light emitting layer, transports the electrons to the light emitting region, and has a large electron mobility. The adhesion improving layer is an electron injecting/transporting layer comprising a material having a good adhesion particularly to the cathode.

In addition, the emitted light is reflected by an electrode (cathode in this case). Therefore, it has been known that the emitted light directly passing through an anode and the emitted light passing through the anode after reflected by the electrode interfere with each other. To effectively utilize this interference effect, the thickness of the electron injecting/transporting layer is appropriately selected from several nanometers to several micrometers. When the thickness is large, the electron mobility is preferably 10⁻⁵ cm²/Vs or more at an electric field of 10⁴ to 10⁶ V/cm in order to avoid the increase in voltage.

A metal complex of 8-hydroxyquinoline or its derivative or an oxadiazole derivative is suitable as the material for the electron injecting/transporting layer. Specific examples of the metal complex of 8-hydroxyquinoline or its derivative include metal chelate oxynoid compounds containing a chelate of oxine (generally 8-quinolinol or 8-hydroxyquinoline), such as tris(8-quinolinol)aluminum.

Examples of the electron injecting material include the compounds represented by any of formulae (31) to (36):

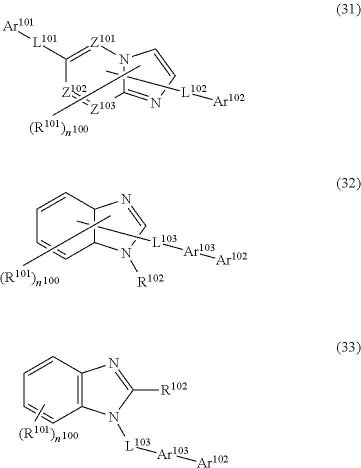

wherein:

each of Z¹⁰¹, Z¹⁰², and Z¹⁰³ independently represents a nitrogen atom, CH, or a carbon atom to which -L¹⁰²-Ar¹⁰² is bonded;

each of R¹⁰¹ R¹⁰² independently represents a substituted or unsubstituted aryl group having 6 to 50 carbon atoms, a substituted or unsubstituted heteroaryl group having 3 to 50 carbon atoms, an alkyl group having 1 to 20 carbon atoms, a haloalkyl group having 1 to 20 carbon atoms, or an alkoxy group having 1 to 20 carbon atoms;

n¹⁰⁰ represents an integer of 0 to 5, when n¹⁰⁰ represents an integer or 2 or more, R¹⁰¹ groups may be the same or different and adjacent R¹⁰¹ groups may be bonded to each other to form a substituted or unsubstituted aromatic hydrocarbon ring;

Ar¹⁰¹ represents a substituted or unsubstituted aryl group having 6 to 50 carbon atoms or a substituted or unsubstituted heteroaryl group having 3 to 50 carbon atoms;

Ar¹⁰² represents a hydrogen atom, an alkyl group having 1 to 20 carbon atoms, a haloalkyl group having 1 to 20 carbon atoms, an alkoxy group having 1 to 20 carbon atoms, a substituted or unsubstituted aryl group having 6 to 50 carbon atoms, or a substituted or unsubstituted heteroaryl group having 3 to 50 carbon atoms;

provided that one of Ar¹⁰¹ and Ar¹⁰² represents a substituted or unsubstituted fused ring group having 10 to 50 carbon atoms or a substituted or unsubstituted fused heteroring group having 9 to 50 ring atoms;

Ar¹⁰³ represents a substituted or unsubstituted arylene group having 6 to 50 carbon atoms or a substituted or unsubstituted heteroarylene group having 3 to 50 carbon atoms; and

each of L¹⁰¹, L¹⁰² and L¹⁰³ independently represents a single bond, a substituted or unsubstituted arylene group having 6 to 50 carbon atoms, a substituted or unsubstituted fused heteroring group having 9 to 50 ring atoms, or a substituted or unsubstituted fluorenylene group.

Of the compounds represented by formulae (31) to (33), the compounds represented by formula (33) are preferred.

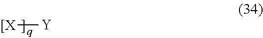

wherein X represents a fused ring comprising a nitrogen atom or a sulfur atom; Y represents a single bond, an alkyl linkage, an alkylene linkage, a cycloalkyl linkage, an aryl linkage, a heteroring linkage, a silyl linkage, an ether linkage, a thioether linkage, or a linkage derived by combining any of the preceding linkages; and q is a natural number of 2 or more.

The molecular weight of the compound represented by formula (34) is 480 or more.

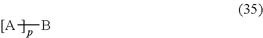

wherein A represents a group comprising a phenanthroline skeleton or a benzoquinoline skeleton, B represents a p-valent organic group comprising a structure represented by formula (35A), and p is a natural number of 2 or more:

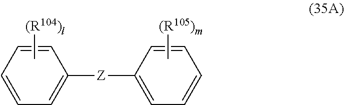

wherein each of R¹⁰⁴ and R¹⁰⁵ independently represents an alkyl group or an aryl group inclusive of an aryl group fused to the phenyl group, each of l and m independently represents a natural number of 0 to 5, and Z represents at least one group selected from formula (35B):

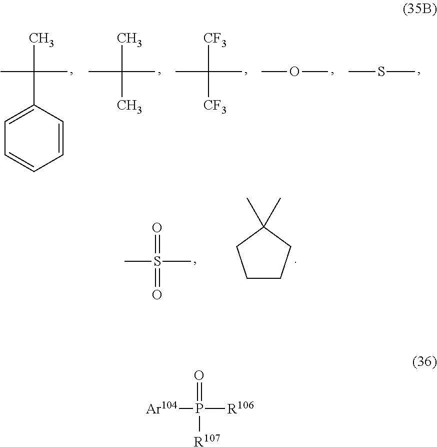

wherein:

R¹⁰⁶ and ¹⁰⁷ may be the same or different and independently selected from a hydrogen atom, an alkyl group, a cycloalkyl group, a heterocyclic group, an alkenyl group, a cycloalkenyl group, an alkynyl group, an alkoxy group, an alkylthio group, an aryl ether group, an aryl thioether group, an aryl group, a heteroaryl group, a cyano group, a carbonyl group, an ester group, a carbamoyl group, an amino group, a silyl group, and a fused ring formed by adjacent groups, and Ar¹⁰⁴ represents an aryl group or a heteroaryl group.

The organic EL device of the present invention preferably comprises at least one of an electron-donating dopant and an organometallic complex in an interfacial region between the cathode and the organic thin film layer.

With such a construction, the organic EL device has an improved luminance and an elongated lifetime.

Examples of the electron-donating dopant include at least one compound selected from an alkali metal, an alkali metal compound, an alkaline earth metal, an alkaline earth metal compound, a rare earth metal, and a rare earth metal compound.

Examples of the organometallic complex include at least one complex selected from an organometallic complex containing an alkali metal, an organometallic complex containing an alkaline earth metal, and an organometallic complex containing a rare earth metal.

Examples of the alkali metal include lithium (Li) (work function: 2.93 eV), sodium (Na) (work function: 2.36 eV), potassium (K) (work function: 2.28 eV), rubidium (Rb) (work function: 2.16 eV), and cesium (Cs) (work function: 1.95 eV), with those having a work function of 2.9 eV or less being particularly preferred. Of the above, preferred are K, Rb, and Cs, more preferred are Rb and Cs, and most preferred is Cs.

Examples of the alkaline earth metal include calcium (Ca) (work function: 2.9 eV), strontium (Sr) (work function: 2.0 to 2.5 eV), and barium (Ba) (work function: 2.52 eV), with those having a work function of 2.9 eV or less being particularly preferred.

Examples of the rare earth metal include scandium (Sc), yttrium (Y), cerium (Ce), terbium (Tb), and ytterbium (Yb), with those having a work function of 2.9 eV or less being particularly preferred.

The preferred metals described above have a particularly high reducing ability. Therefore, the emission luminance and life time of an organic EL device can be improved by adding a relatively small amount of the metal to an electron injecting region.

Examples of the alkali metal compound include an alkali oxide, such as lithium oxide (Li₂O), cesium oxide (Cs₂O), and potassium oxide (K₂O), and an alkali halide, such as lithium fluoride (LiF), sodium fluoride (NaF), cesium fluoride (CsF), and potassium fluoride (KF), with lithium fluoride (LiF), lithium oxide (Li₂O), and sodium fluoride (NaF) being preferred.

Examples of the alkaline earth metal compound include barium oxide (BaO), strontium oxide (SrO), calcium oxide (CaO), and a mixture thereof, such as a barium salt of strontium acid (BaₓSr₁₋ₓO) (0<x<1) and a barium salt of calcium acid (BaₓCa₁₋ₓO) (0<x<1), with BaO, SrO, and CaO being preferred.

Examples of the rare earth metal compound include Ytterbium fluoride (YbF₃), scandium fluoride (ScF₃), scandium oxide (ScO₃), yttrium oxide (Y₂O₃), cerium oxide (Ce₂O₃), gadolinium fluoride (GdF₃), and terbium fluoride (TbF₃), with YbF₃, ScF₃, and TbF₃ being preferred.

The organic metal complex is not particularly limited as long as it comprises at least one metal ion selected from alkali metal ions, alkaline earth metal ions, and rare earth metal ions, as described above. The ligand is preferably, but not limited to, quinolinol, benzoquinolinol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzimidazole, hydroxybenzotriazole, hydroxyfulborane, bipyridyl, phenanthroline, phthalocyanine, porphyrin, cyclopentadiene, β-diketones, azomethines, and derivative thereof.

The electron-donating dopant and organic metal complex are preferably formed into a layered form or an island form at the interfacial region. The electron-donating dopant and/or the organic metal complex is preferably co-deposited with the organic material (the light emitting material and the electron injecting material) for forming the interfacial region by a resistance heating deposition method, thereby dispersing the electron-donating dopant and/or the organic metal complex into the organic material. The disperse concentration expressed by the molar ratio of the organic material and the electron-donating dopant and/or the organic metal complex is generally 100:1 to 1:100 and preferably 5:1 to 1:5.

When the electron-donating dopant and/or the organic metal complex is formed into a layered form, a light emitting material or an electron injecting material is made into a layered form to form an interfacial organic layer, and then, the electron-donating dopant and/or the organic metal complex is deposited by a resistance heating deposition method into a layer having a thickness preferably 0.1 to 15 nm.

When the electron-donating dopant and/or the organic metal complex is formed into an island form, a light emitting material or an electron injecting material is made into an island form to form an interfacial organic layer, and then, the electron-donating dopant and/or the organic metal complex is deposited by a resistance heating deposition method into a form of island having a thickness preferably 0.05 to 1 nm.

The molar ratio of the main component and the electron-donating dopant and/or the organic metal complex in the organic EL device of the invention is preferably 5:1 to 1:5 and more preferably 2:1 to 1:2.

### (7) Cathode

In view of injecting electrons into the electron injecting/transporting layer or the light emitting layer, the cathode is formed from an electrode material, such as a metal, an alloy, an electrically conductive compound and a mixture thereof, each having a small work function (4 eV or smaller). Examples of the electrode material include sodium, sodium-potassium alloy, magnesium, lithium, magnesium-silver alloy, aluminum/aluminum oxide, aluminum-lithium alloy, indium, and rare earth metal.

The cathode is formed by making the electrode material described above into a thin film by a process, such as a vapor deposition process and a sputtering process.

When the light emitted from the light emitting layer is taken through the cathode, the transmittance of the cathode to the emitted light is preferably 10% or more.

The sheet resistivity of the cathode is preferably several hundreds Ω/□ or less and the thickness of the cathode is generally 10 nm to 1 μm and preferably 50 to 200 nm.

### (8) Insulating Layer

Since electric field is applied to the ultra-thin films of organic EL devices, the pixel defects due to leak and short circuit tends to occur. To prevent the defects, an insulating thin film layer is preferably interposed between the pair of electrodes.

Examples of the material for the insulating layer include aluminum oxide, lithium fluoride, lithium oxide, cesium fluoride, cesium oxide, magnesium oxide, magnesium fluoride, calcium oxide, calcium fluoride, aluminum nitride, titanium oxide, silicon oxide, germanium oxide, silicon nitride, boron nitride, molybdenum oxide, ruthenium oxide, and vanadium oxide. These materials may be used in combination or may be made into laminated layers.

The preferred materials for the respective layers mentioned above may be used in any arbitrary combinations. The organic EL device of the invention wherein each layer is formed by the preferred material is a preferred embodiment of the invention.

### (9) Production of Organic EL Device

The organic EL device is produced, for example, by forming an anode, a light emitting layer, a hole transporting layer, and an optional electron injecting/transporting layer, and then forming a cathode by using the materials and production methods mentioned above. Alternatively, the organic EL device is produced by forming each layer in a reverse order from the cathode to the anode.

Example of the production of an organic EL device having a layered structure: anode/hole transporting layer/light emitting layer/electron injecting-transporting layer/cathode on a light-transmissive substrate will be described below.

First, on a suitable light-transmissive substrate, an anode is formed by making an anode material into a thin film having a thickness of 1 μm or less, preferably 10 to 200 nm by a method, such as vapor deposition and sputtering. Then, at least two hole transporting layers are formed on the anode. These hole transporting layers may be formed by a vacuum vapor deposition method, a spin coating method, a casting method or LB method, with the vacuum vapor deposition method being preferred because a uniform film is easily obtained and pinholes are hardly formed.

The conditions of the vacuum vapor deposition method for forming the hole transporting layers depend upon the compounds (hole transporting layer material) to be used and the crystalline structure and recombination structure of the intended hole transporting layers. Generally, the vacuum vapor deposition is conducted preferably under the conditions: a deposition source temperature of 50 to 450° C., a vacuum degree of 10⁻⁷ to 10⁻³ torr, a deposition speed of 0.01 to 50 nm/s, a substrate temperature of −50 to 300° C., and a film thickness of 5 nm to 5 μm.

Then, a light emitting layer is formed on the hole transporting layer. The light emitting layer is formed by making an organic light emitting material into a thin film by a vacuum vapor deposition method, a spin coating method, or a casting method, with the vacuum vapor deposition method being preferred because a uniform film is easily obtained and pinholes are hardly formed. The conditions of the vacuum vapor deposition method for forming the light emitting layer depend upon the kind of the compound to be used, and generally selected from those mentioned with respect to the hole transporting layer.

Next, an electron injecting/transporting layer is formed on the light emitting layer. Like the formation of the hole transporting layer and the light emitting layer, the electron transporting layer is formed preferably by the vacuum vapor deposition method because a uniform thin film is needed. The conditions of the vacuum vapor deposition are selected from those mentioned with respect to the hole transporting layer and the light emitting layer.

Finally, a cathode is formed on the electron injecting/transporting layer, to obtain an organic EL device.

The cathode is made of a metal and can be formed by the vapor deposition method or the sputtering method, with the vacuum vapor deposition method being preferred in view of preventing the underlying organic layers from being damaged during the film forming process.

In the production of organic EL device mentioned above, the layers from the anode to the cathode are successively formed preferably in a single evacuation operation.

The light emission is observed when applying a direct voltage of 5 to 40 V to the organic EL device such that the anode is charged to +polarity and the cathode is charged to −polarity. If a voltage is applied in the reverse polarity, no electric current flows and light is not emitted. When an alternating voltage is applied, the uniform light emission is observed only when the anode is charged to +polarity and the cathode is charged to −polarity. The wave shape of alternating voltage in not limited.

### EXAMPLES

The present invention is described in more detail with reference to the examples. However, it should be noted that the scope of the invention is not limited thereto.

### Example 1

### Production of Organic EL Device

A glass substrate with an ITO transparent electrode having a size of 25 mm×75 mm×1.1 mm (manufactured by GEOMATEC Co., Ltd.) was ultrasonically cleaned in isopropyl alcohol for 5 min and then UV (ultraviolet)/ozone cleaned for 30 min.

The cleaned glass substrate with the transparent electrode line was mounted on the substrate holder of a vacuum deposition apparatus. First, the following electron-accepting compound (A) was vapor-deposited onto the surface on the side where the transparent electrode line was formed so as to cover the transparent electrode, thereby forming an acceptor layer having a thickness of 5 nm. On the acceptor layer, the following aromatic amine derivative (X1) as a first hole transporting material was vapor-deposited to form a first hole transporting layer having a thickness of 65 nm. Successively after the formation of the first hole transporting layer, the following aromatic amine derivative (H1) as a second hole transporting material was vapor-deposited to form a second hole transporting layer having a thickness of 10 nm.

On the hole transporting layer, the following compound (host-1) as a first host material, the following compound (host-2) as a second host material, and the following Ir(bzq)₃ as a phosphorescent dopant material were vapor co-deposited, to form a green-emitting light emitting layer having a thickness of 25 nm. The concentration of the phosphorescent dopant material was 10% by mass, the concentration of the first host material was 45% by mass, and the concentration of the second host material was 45% by mass.

Then, a film of the compound (E) having a thickness of 35 nm, a film of LiF having a thickness of 1 nm, and a film of metallic Al having a thickness of 80 nm were successively deposited on the phosphorescent emitting layer to form a cathode. The LiF film as the electron injecting electrode was formed at a film-forming speed of 1 Å/min.

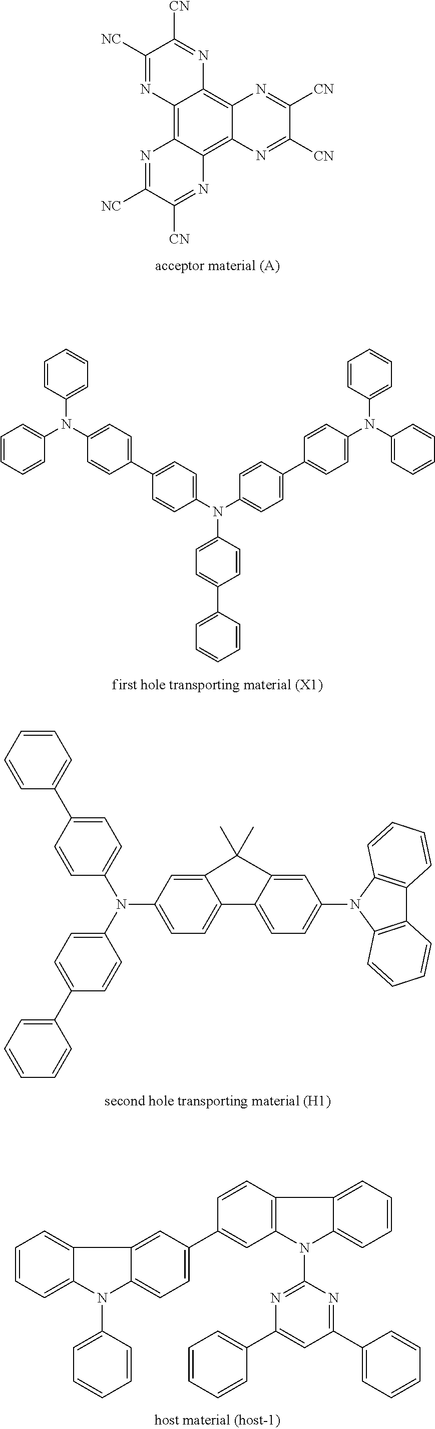 [SMILES: N#Cc1nc2c3nc(C#N)c(C#N)nc3c3nc(C#N)c(C#N)nc3c2nc1C#N ; c1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21 ; c1ccc(-c2cc(-c3ccccc3)nc(-n3c4ccccc4c4ccc(-c5ccc6c(c5)c5ccccc5n6-c5ccccc5)cc43)n2)cc1]

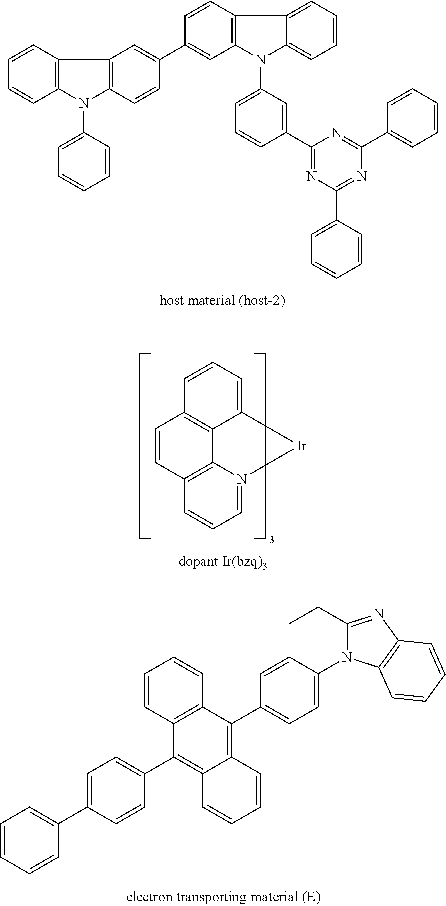

### Evaluation of Emission Performance of Organic EL Device

The organic EL device thus produced was measured for the luminance (L) and the current density by allowing the device to emit light under a direct current drive, thereby determining the current efficiency (L/J) and the driving voltage (V) at a current density of 10 mA/cm². In addition, the organic EL device was measured for the device lifetime (time taken until the luminance was reduced to 80% of the initial luminance) at a current density of 50 mA/cm². The results are shown in Table 1.

### Examples 2-6

### Production of Organic EL Device

Each organic EL device was produced and evaluated in the same manner as in Example 1 except for using the aromatic amine derivatives listed in Table 1 as the first hole transporting material and the second hole transporting material.

The compounds used in Examples 2 to 6 are shown below.

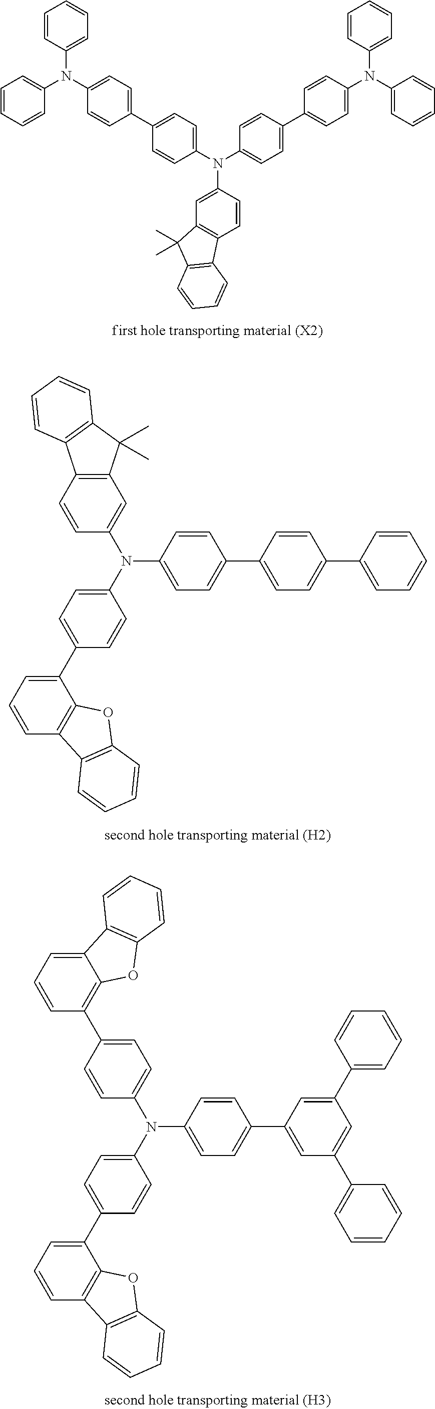 [SMILES: CC1(C)c2ccccc2-c2ccc(N(c3ccc(-c4ccc(N(c5ccccc5)c5ccccc5)cc4)cc3)c3ccc(-c4ccc(N(c5ccccc5)c5ccccc5)cc4)cc3)cc21 ; CC1(C)c2ccccc2-c2ccc(N(c3ccc(-c4ccc(-c5ccccc5)cc4)cc3)c3ccc(-c4cccc5c4oc4ccccc45)cc3)cc21 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

### Comparative Examples 1-6

### Production of Organic EL Device

Each organic EL device was produced and evaluated in the same manner as in Example 1 except for using the aromatic amine derivatives listed in Table 1 as the first hole transporting material and the second hole transporting material.

The compounds used in Comparative Examples 1 to 6 are shown below.

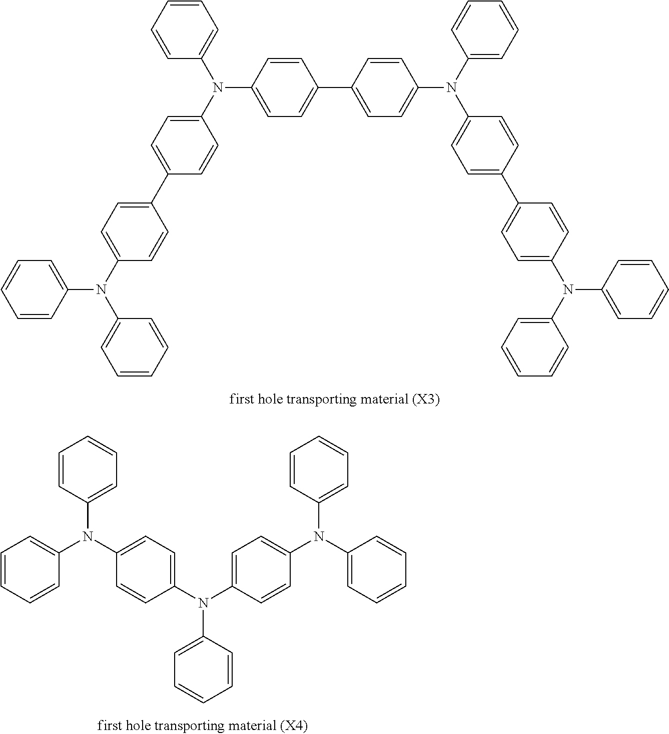 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; c1ccc(N(c2ccccc2)c2ccc(N(c3ccccc3)c3ccc(N(c4ccccc4)c4ccccc4)cc3)cc2)cc1]

TABLE 1

| | First hole | | Second hole | |
|---|---|---|---|---|
| | transporting | Thickness | transporting | Thickness |
| | material | (nm) | material | (nm) |
| Examples | | | | |
| 1 | X1 | 65 | H1 | 10 |
| 2 | X1 | 65 | H2 | 10 |
| 3 | X1 | 65 | H3 | 10 |
| 4 | X2 | 65 | H1 | 10 |
| 5 | X2 | 65 | H2 | 10 |
| 6 | X2 | 65 | H3 | 10 |
| Comparative | | | | |
| Examples | | | | |
| 1 | X3 | 65 | H1 | 10 |
| 2 | X3 | 65 | H2 | 10 |
| 3 | X3 | 65 | H3 | 10 |
| 4 | X4 | 65 | H1 | 10 |
| 5 | X4 | 65 | H2 | 10 |
| 6 | X4 | 65 | H3 | 10 |

| | Measurement Results | | |
|---|---|---|---|
| | Emission | | |
| | efficiency | driving | |
| | (cd/A) | voltage (V) | 80% |
| | @ 10 mA/cm² | @ 10 mA/cm² | Lifetime (h) |
| Examples | | | |
| 1 | 56.8 | 3.2 | 550 |
| 2 | 54.8 | 3.1 | 640 |
| 3 | 61.2 | 3.4 | 500 |
| 4 | 58.2 | 3.3 | 560 |
| 5 | 58.1 | 3.2 | 700 |
| 6 | 62.2 | 3.6 | 600 |
| Comparative | | | |
| Examples | | | |
| 1 | 53.6 | 3.3 | 540 |
| 2 | 53.9 | 3.2 | 620 |
| 3 | 59.6 | 3.5 | 480 |
| 4 | 53.2 | 4.2 | 200 |
| 5 | 52.5 | 4.1 | 220 |
| 6 | 55.5 | 4.5 | 220 |

As seen from Table 1, in the organic EL devices of Comparative Examples 1 to 6 wherein the aromatic amine derivatives different from the compound represented by formula (1) are used in the first hole transporting layers, the driving voltage is increased due to the large thicknesses of the hole transporting layers and both the emission efficiency and the device lifetime are reduced.

In contrast, the organic EL devices wherein the compounds represented by formula (1) are used in the first hole transporting layers are capable of driving at low voltage irrespective of the large thicknesses of the hole transporting layers. In addition, the emission efficiency and the device lifetime are both improved.

In the present invention, the definition of hydrogen atom includes isotopes different in the neutron numbers, i.e., light hydrogen (protium), heavy hydrogen (deuterium), and tritium. The number of ring carbon atoms means the number of carbon atoms which are present as the ring members of a saturated ring, an unsaturated ring or an aromatic ring. The number of ring atoms means the number of carbon atoms and hetero atoms which are present as the ring members of a heteroring (inclusive of a saturated ring, an unsaturated ring or an aromatic ring). In case of a group including a non-cyclic hydrocarbon group and a cyclic hydrocarbon group as in an aralkyl group, etc., the number of carbon atoms is expressed by the total of the number of carbon atoms of the non-cyclic hydrocarbon group (exclusive of the carbon atoms of a substituent thereon) and the number of ring carbon atoms of the cyclic hydrocarbon group.

In the present invention, the preferred examples of respective groups in the compounds mentioned above may be arbitrarily combined and any combination of the preferred examples is also a preferred embodiment of the invention.

### INDUSTRIAL APPLICABILITY

By using the compound of the invention in organic EL device, the thickness of the hole transporting layer can be increased to make it easy to adjust the optical thickness and the emission efficiency and lifetime of the device are improved. The organic EL device of the invention is useful as a backlight for flat light sources and displays.

1. An organic electroluminescence device, comprising:
an anode;
an organic layer which comprises a hole transporting layer;
a light emitting layer; and
a cathode
in this order,
wherein the organic layer comprises an acceptor material,
the hole transporting layer comprises a compound of formula (1): 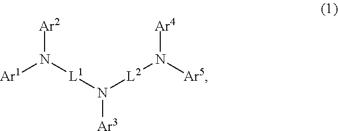
where each of L¹ and L² is independently of formula (1-2) or (1-3): 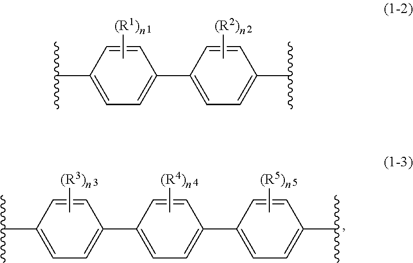
where each of Ar¹ to Ar⁵ is independently of any one of formulae (1-4) to (1-9): 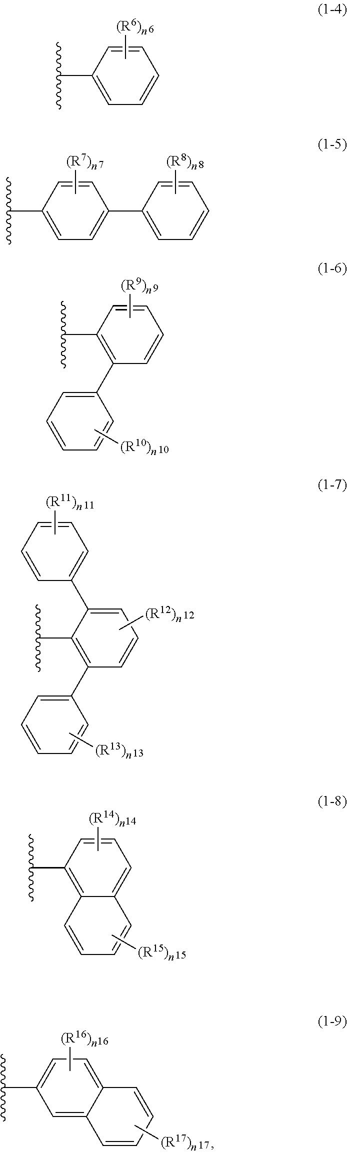
where each of R¹ to R¹⁷ independently represents a substituted or unsubstituted alkyl group having 1 to 20 carbon atom, a halogen atom, a substituted or unsubstituted fluoroalkyl group having 1 to 20 carbon atoms, a substituted or unsubstituted alkoxy group having 1 to 20 carbon atoms, a substituted or unsubstituted fluoroalkoxy group having 1 to 20 carbon atoms, or a cyano group;
each of n¹ to n⁵, n⁷, n⁹, n¹⁵, and n¹⁷ independently represents an integer of 0 to 4;
each of n⁶, n⁸, n¹⁰, n¹¹, and n¹³ independently represents an integer of 0 to 5;
each of n¹², n¹⁴, and n¹⁶ independently represents an integer of 0 to 3;
R⁶ to R¹⁷ is optionally bonded to each other to form a ring; and
each of wavy lines indicates a bonding site.

2. The organic electroluminescence device according to claim 1,
wherein the hole transporting layer comprises two or more layers which comprise one or more first hole transporting layers each being not adjacent to the light emitting layer and a second hole transporting layer adjacent to the light emitting layer, and
at least one layer of the one or more first hole transporting layers comprises the compound of formula (1).

3. The organic electroluminescence device according to claim 1,
wherein the compound of formula (1) is a compound of formula (1′): 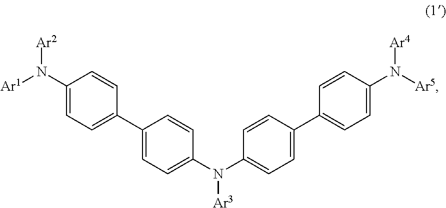
where each of Ar¹ to Ar⁵ is independently of any one of formulae (1-4) to (1-9): 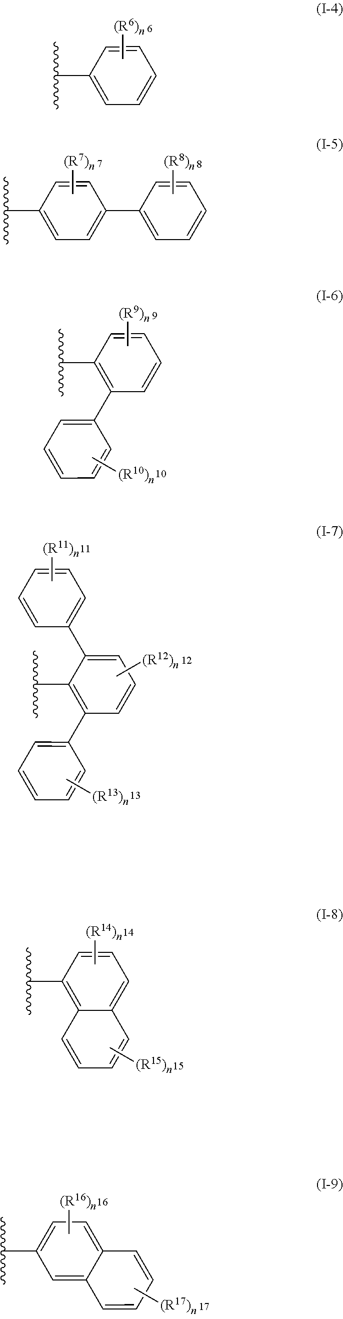
where each of R⁶ to R¹⁷ independently represents a substituted or unsubstituted alkyl group having 1 to 20 carbon atom, a halogen atom, a substituted or unsubstituted fluoroalkyl group having 1 to 20 carbon atoms, a substituted or unsubstituted alkoxy group having 1 to 20 carbon atoms, a substituted or unsubstituted fluoroalkoxy group having 1 to 20 carbon atoms, or a cyano group;
each of n⁷, n⁹, n¹⁵, and n¹⁷ independently represents an integer of 0 to 4;
each of n⁶, n⁸, n¹⁰, n¹¹, and n¹³ independently represents an integer of 0 to 5;
each of n¹², n¹⁴, and n¹⁶ independently represents an integer of 0 to 3;
R⁶ to R¹⁷ is optionally bonded to each other to form a ring; and
each of wavy lines indicates a bonding site.

4. The organic electroluminescence device according to claim 2,
wherein the organic layer comprising the acceptor material is an acceptor layer, and
the acceptor layer is interposed between the anode and one of the one or more first hole transporting layers.

5. The organic electroluminescence device according to claim 1,
wherein the hole transporting layer comprises the acceptor material.

6. The organic electroluminescence device according to claim 1,
wherein the acceptor material is a compound of formula (A): 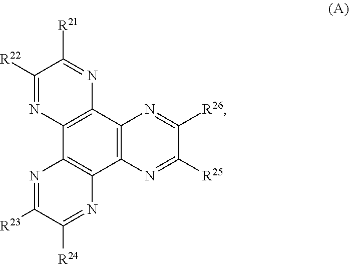
where
each of R²¹ to R²⁶ independently represents a cyano group, —CONH₂, a carboxyl group, or —COOR²⁷,
R²⁷ represents an alkyl group having 1 to 20 carbon atoms; and
R²¹ and R²², R²³ and R²⁴, and R²⁵ and R²⁶ are optionally bonded to each other to form a group of —CO—O—CO—.

7. The organic electroluminescence device according to claim 1,
wherein the acceptor material is a compound of formula (B): 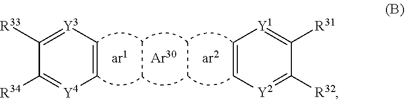
where each of R³¹ to R³⁴ independently represents a hydrogen atom, a substituted or unsubstituted alkyl group having 1 to 20 carbon atoms, a substituted or unsubstituted aryl group having 6 to 50 ring carbon atoms, a substituted or unsubstituted heterocyclic group having 5 to 50 ring atoms, a halogen atom, a substituted or unsubstituted alkoxy group having 1 to 20 carbon atoms, a substituted or unsubstituted aryloxy group having 6 to 50 ring carbon atoms, or a cyano group, R³¹ and R³² are optionally bonded to each other to form a ring, and R³³ and R³⁴ are optionally bonded to each other to form a ring;
each of Y¹ to Y⁴ independently represents —N═, —CH═, or —C(R³⁵)═, and R³⁵ represents a substituted or unsubstituted alkyl group having 1 to 20 carbon atoms, a substituted or unsubstituted aryl group having 6 to 50 ring carbon atoms, a substituted or unsubstituted heterocyclic group having 5 to 50 ring atoms, a halogen atom, a substituted or unsubstituted alkoxy group having 1 to 20 carbon atoms, a substituted or unsubstituted aryloxy group having 6 to 50 ring carbon atoms, or a cyano group;
Ar³⁰ represents a fused ring having 6 to 24 ring carbon atoms or a heteroring having 6 to 24 ring atoms; and
each of ar¹ and ar² independently represents a ring of formula (i) or (ii): 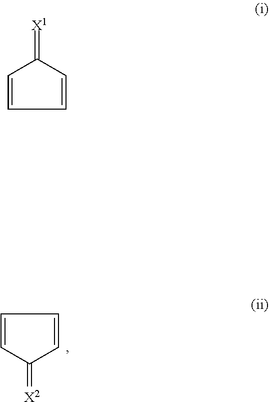
where each of X¹ and X² independently represents a divalent group of any one of formulae (a) to (g): 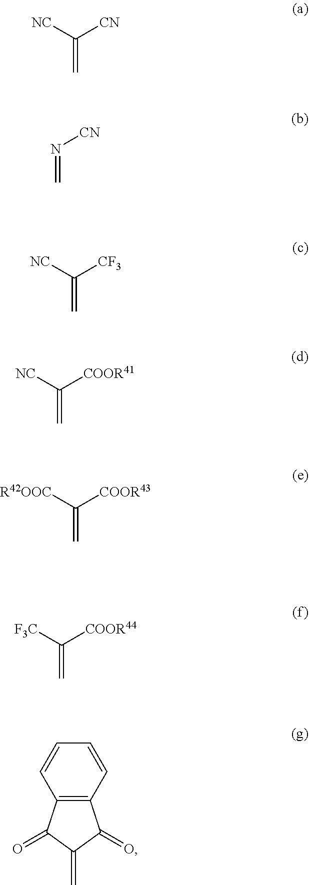
where each of R⁴¹ to R⁴⁴ represents optionally independently a hydrogen atom, a substituted or unsubstituted alkyl group having 1 to 20 carbon atoms, a substituted or unsubstituted aryl group having 6 to 50 ring carbon atoms, or a substituted or unsubstituted heterocyclic group having 5 to 50 ring atoms, and R⁴² and R⁴³ are optionally bonded to each other to form a ring.

8. The organic electroluminescence device according to claim 1,
wherein the acceptor material is a compound of formula (C): 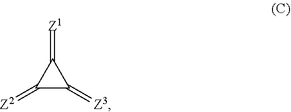
where each of Z¹ to Z³ independently represents a divalent group of formula (h): 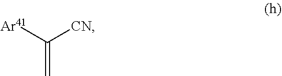
where Ar⁴¹ represents a substituted or unsubstituted aryl group having 6 to 50 ring carbon atoms or a substituted or unsubstituted heteroaryl group having 5 to 50 ring atoms.

9. The organic electroluminescence device according to claim 2,
wherein the second hole transporting layer comprises a compound of formula (4): 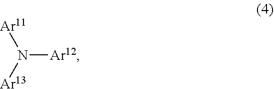
where each of Ar¹¹ to Ar¹³ represents a group of any one of formulae (4-2) to (4-4) or a substituted or unsubstituted aryl group having 6 to 40 ring carbon atoms, and at least one of Ar¹¹ to Ar¹³ represents a group of formula (4-2) or (4-3): 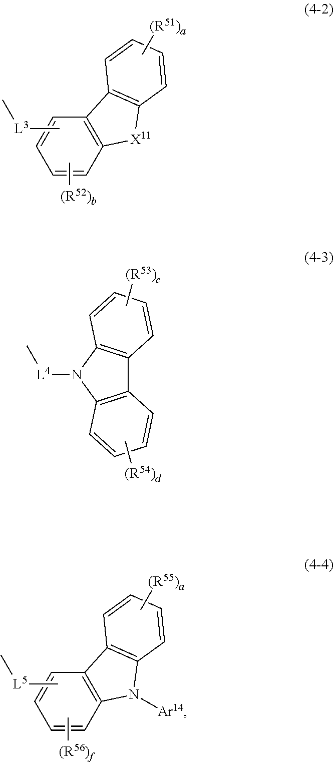
where
X¹¹ represents an oxygen atom or a sulfur atom;
each of L³ to L⁵ independently represents a single bond or a substituted or unsubstituted arylene group having 6 to 50 ring carbon atoms;
an optional substituent of L³ to L⁵ is selected from the group consisting of a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms, an aryl group having 6 to 50 ring carbon atoms, a halogen atom, and a cyano group;
Ar¹⁴ represents a substituted or unsubstituted aryl group having 6 to 50 ring carbon atoms;
an optional substituent of Ar¹⁴ is selected from the group consisting of a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms, an aryl group having 6 to 50 ring carbon atoms, a halogen atom, and a cyano group;
each of R⁵¹ to R⁵⁶ independently represents a substituted or unsubstituted, linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, a substituted or unsubstituted alkylarylsilyl group having 8 to 15 carbon atoms, a substituted or unsubstituted aryl group having 6 to 50 ring carbon atoms, a halogen atom, and a cyano group;
adjacent groups of R⁵¹ to R⁵⁶ are optionally bonded to each other to form a saturated or unsaturated divalent group which completes a ring;
b and f independently represents an integer of 0 to 3; and
a, c, d, and e independently represents an integer of 0 to 4.

10. The organic electroluminescence device according to claim 9,
wherein L³ represents a substituted or unsubstituted arylene group having 6 to 50 ring carbon atoms.

11. The organic electroluminescence device according to claim 9,
wherein L⁴ represents a substituted or unsubstituted arylene group having 6 to 50 ring carbon atoms.

12. The organic electroluminescence device according to claim 9,
wherein the substituted or unsubstituted aryl group having 6 to 40 ring carbon atoms for Ar¹¹ to Ar¹³ of formula (4) is of any one of formulae (4-5) to (4-7): 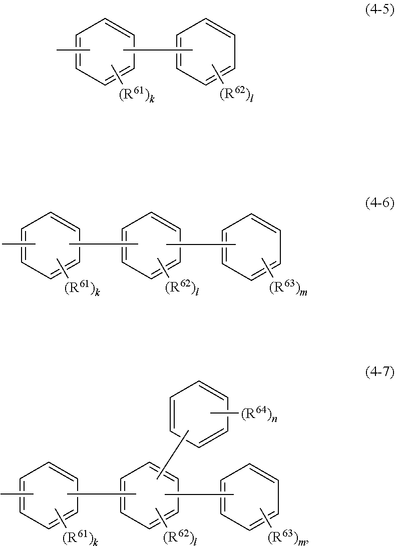
where
each of R⁶¹ to R⁶⁴ independently represents a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms, in which an aryl portion of the alkylarylsilyl group has 6 to 14 ring carbon atoms, an aryl group having 6 to 50 ring carbon atoms, a halogen atom, or a cyano group;
adjacent groups of R⁶¹ to R⁶⁴ are optionally bonded to each other to form a ring; and
each of k, l, m, and n independently represents an integer of 0 to 4, and
l represents an integer of 0 to 3.

13. (canceled)

14. The organic electroluminescence device according to claim 1,
wherein the light emitting layer comprises a phosphorescent material comprising an ortho metallated complex of a metal selected from the group consisting of iridium (Ir), osmium (Os), and platinum (Pt).

15. The organic electroluminescence device according to claim 2,
wherein the hole transporting layer comprises the acceptor material.

16. The organic electroluminescence device according to claim 2,
wherein the acceptor material is a compound of formula (A): 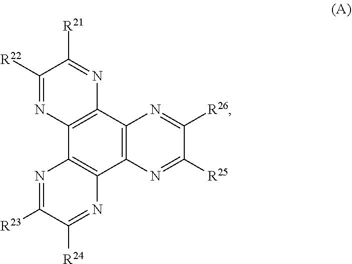
where each of R²¹ to R²⁶ independently represents a cyano group, —CONH₂, a carboxyl group, or —COOR²⁷,
R²⁷ represents an alkyl group having 1 to 20 carbon atoms; and
R²¹ and R²², R²³ and R²⁴, and R²⁵ and R²⁶ are optionally bonded to each other to form a group of —CO—O—CO—.

17. The organic electroluminescence device according to claim 2,
wherein the acceptor material is a compound of formula (B): 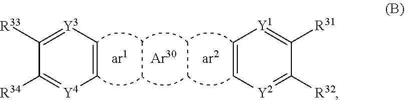
where each of R³¹ to R³⁴ independently represents a hydrogen atom, a substituted or unsubstituted alkyl group having 1 to 20 carbon atoms, a substituted or unsubstituted aryl group having 6 to 50 ring carbon atoms, a substituted or unsubstituted heterocyclic group having 5 to 50 ring atoms, a halogen atom, a substituted or unsubstituted alkoxy group having 1 to 20 carbon atoms, a substituted or unsubstituted aryloxy group having 6 to 50 ring carbon atoms, or a cyano group, R³¹ and R³² are optionally bonded to each other to form a ring, and R³³ and R³⁴ are optionally bonded to each other to form a ring;
each of Y¹ to Y⁴ independently represents —N═, —CH═, or —C(R³⁵)═, and R³⁵ represents a substituted or unsubstituted alkyl group having 1 to 20 carbon atoms, a substituted or unsubstituted aryl group having 6 to 50 ring carbon atoms, a substituted or unsubstituted heterocyclic group having 5 to 50 ring atoms, a halogen atom, a substituted or unsubstituted alkoxy group having 1 to 20 carbon atoms, a substituted or unsubstituted aryloxy group having 6 to 50 ring carbon atoms, or a cyano group;
Ar³⁰ represents a fused ring having 6 to 24 ring carbon atoms or a heteroring having 6 to 24 ring atoms; and
each of ar¹ and ar² independently represents a ring of formula (i) or (ii): 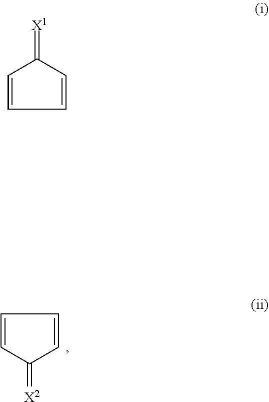
where each of X¹ and X² independently represents a divalent group of any one of formulae (a) to (g): 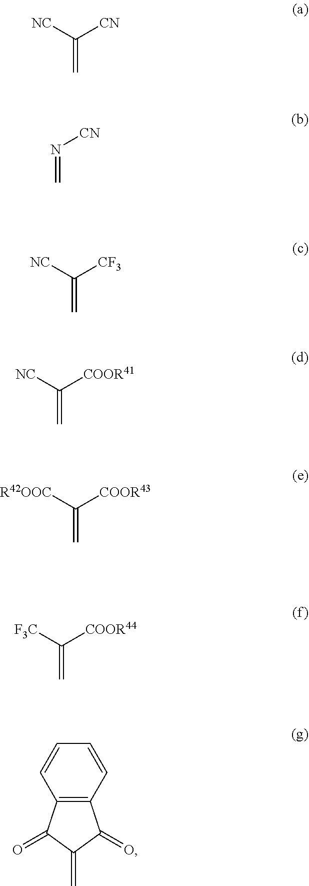
where each of R⁴¹ to R⁴⁴ represents optionally independently a hydrogen atom, a substituted or unsubstituted alkyl group having 1 to 20 carbon atoms, a substituted or unsubstituted aryl group having 6 to 50 ring carbon atoms, or a substituted or unsubstituted heterocyclic group having 5 to 50 ring atoms, and R⁴² and R⁴³ are optionally bonded to each other to form a ring.

18. The organic electroluminescence device according to claim 15,
wherein the second hole transporting layer comprises a compound of any one of formulae (5) to (7): 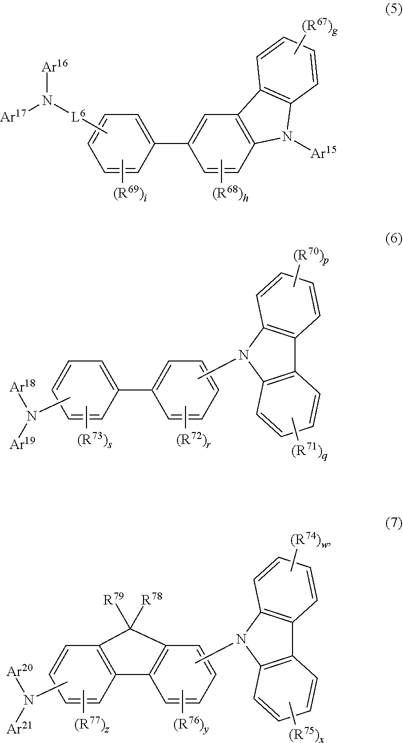
where each of Ar¹⁵ to Ar²¹ independently represents a substituted or unsubstituted aryl group having 6 to 50 ring carbon atoms, a substituted or unsubstituted aromatic heterocyclic group having 5 to 50 ring carbon atoms, an aromatic amino group-substituted aryl group having 8 to 50 ring carbon atoms, or an aromatic heterocyclic group-substituted aryl group having 8 to 50 ring carbon atoms;
Ar¹⁶ and Ar¹⁷, Ar¹⁸ and Ar¹⁹, and Ar²⁰ and Ar²¹ are optionally bonded to each other to form a ring;
L⁶ represents a single bond or a substituted or unsubstituted arylene group having 6 to 50 ring carbon atoms, which is optionally substituted with at least one substituent selected from the group consisting of a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms the aryl portion has 6 to 14 ring carbon atoms, an aryl group having 6 to 50 ring carbon atoms, a halogen atom, and a cyano group;
each of R⁶⁷ to R⁷⁷ independently represents a halogen atom, a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, a substituted or unsubstituted aralkyl group having 7 to 20 carbon atoms, a substituted or unsubstituted alkenyl group having 2 to 40 carbon atoms, a substituted or unsubstituted alkylamino group having 1 to 40 carbon atoms, a substituted or unsubstituted aralkylamino group having 7 to 60 carbon atoms, a substituted or unsubstituted alkylsilyl group having 3 to 20 carbon atoms, a substituted or unsubstituted arylsilyl group having 8 to 40 carbon atoms, a substituted or unsubstituted aralkylsilyl group having 8 to 40 carbon atoms, or a substituted or unsubstituted haloalkyl group having 1 to 40 carbon atoms;
each of R⁷⁸ and R⁷⁹ independently represents a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, or a substituted or unsubstituted aralkyl group having 7 to 20 carbon atoms;
each of g, i, p, q, r, s, w, and x independently represents an integer of 0 to 4; and
each of h, y and z independently represents an integer of 0 to 3.

19. The organic electroluminescence device according to claim 16,
wherein the second hole transporting layer comprises a compound of any one of formulae (5) to (7): 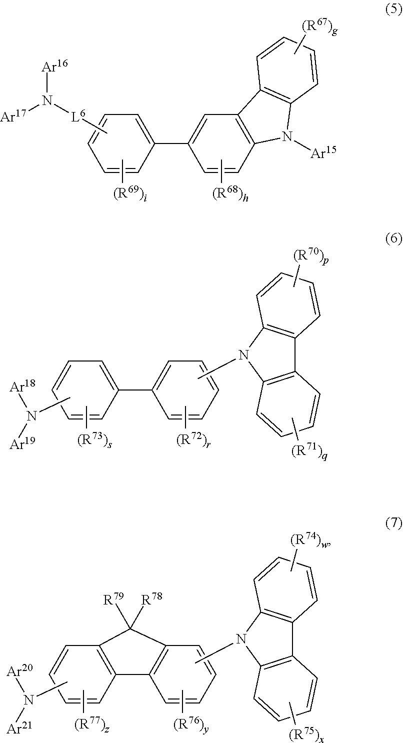
where each of Ar¹⁵ to Ar²¹ independently represents a substituted or unsubstituted aryl group having 6 to 50 ring carbon atoms, a substituted or unsubstituted aromatic heterocyclic group having 5 to 50 ring carbon atoms, an aromatic amino group-substituted aryl group having 8 to 50 ring carbon atoms, or an aromatic heterocyclic group-substituted aryl group having 8 to 50 ring carbon atoms;
Ar¹⁶ and Ar¹⁷, Ar¹⁸ and Ar¹⁹, and Ar²⁰ and Ar²¹ are optionally bonded to each other to form a ring;
L⁶ represents a single bond or a substituted or unsubstituted arylene group having 6 to 50 ring carbon atoms, which is optionally substituted with at least one substituent selected from the group consisting of a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms, the aryl portion has 6 to 14 ring carbon atoms, an aryl group having 6 to 50 ring carbon atoms, a halogen atom, and a cyano group;
each of R⁶⁷ to R⁷⁷ independently represents a halogen atom, a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, a substituted or unsubstituted aralkyl group having 7 to 20 carbon atoms, a substituted or unsubstituted alkenyl group having 2 to 40 carbon atoms, a substituted or unsubstituted alkylamino group having 1 to 40 carbon atoms, a substituted or unsubstituted aralkylamino group having 7 to 60 carbon atoms, a substituted or unsubstituted alkylsilyl group having 3 to 20 carbon atoms, a substituted or unsubstituted arylsilyl group having 8 to 40 carbon atoms, a substituted or unsubstituted aralkylsilyl group having 8 to 40 carbon atoms, or a substituted or unsubstituted haloalkyl group having 1 to 40 carbon atoms;
each of R⁷⁸ and R⁷⁹ independently represents a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, or a substituted or unsubstituted aralkyl group having 7 to 20 carbon atoms;
each of g, i, p, q, r, s, w, and x independently represents an integer of 0 to 4; and
each of h, y and z independently represents an integer of 0 to 3.

20. The organic electroluminescence device according to claim 17,
wherein the second hole transporting layer comprises a compound of any one of formulae (5) to (7): 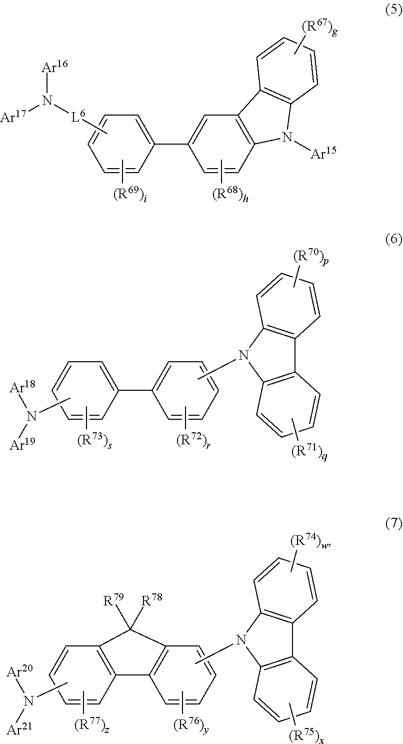
where each of Ar¹⁵ to Ar²¹ independently represents a substituted or unsubstituted aryl group having 6 to 50 ring carbon atoms, a substituted or unsubstituted aromatic heterocyclic group having 5 to 50 ring carbon atoms, an aromatic amino group-substituted aryl group having 8 to 50 ring carbon atoms, or an aromatic heterocyclic group-substituted aryl group having 8 to 50 ring carbon atoms;
Ar¹⁶ and Ar¹⁷, Ar¹⁸ and Ar¹⁹, and Ar²⁰ and Ar²¹ are optionally bonded to each other to form a ring;
L⁶ represents a single bond or a substituted or unsubstituted arylene group having 6 to 50 ring carbon atoms, which is optionally substituted with at least one substituent selected from the group consisting of a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms the aryl portion has 6 to 14 ring carbon atoms, an aryl group having 6 to 50 ring carbon atoms, a halogen atom, and a cyano group;
each of R⁶⁷ to R⁷⁷ independently represents a halogen atom, a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, a substituted or unsubstituted aralkyl group having 7 to 20 carbon atoms, a substituted or unsubstituted alkenyl group having 2 to 40 carbon atoms, a substituted or unsubstituted alkylamino group having 1 to 40 carbon atoms, a substituted or unsubstituted aralkylamino group having 7 to 60 carbon atoms, a substituted or unsubstituted alkylsilyl group having 3 to 20 carbon atoms, a substituted or unsubstituted arylsilyl group having 8 to 40 carbon atoms, a substituted or unsubstituted aralkylsilyl group having 8 to 40 carbon atoms, or a substituted or unsubstituted haloalkyl group having 1 to 40 carbon atoms;
each of R⁷⁸ and R⁷⁹ independently represents a substituted or unsubstituted alkyl group having 1 to 40 carbon atoms, a substituted or unsubstituted heteroaryl group having 5 to 20 ring atoms, a substituted or unsubstituted non-fused aryl group having 6 to 40 ring carbon atoms, a substituted or unsubstituted fused aryl group having 6 to 12 ring carbon atoms, or a substituted or unsubstituted aralkyl group having 7 to 20 carbon atoms;
each of g, i, p, q, r, s, w, and x independently represents an integer of 0 to 4; and
each of h, y and z independently represents an integer of 0 to 3.
